(19) United States
(12) Patent Application Publication
(10) Pub. No.: US 2026/0197953 A1
(43) Pub. Date: Jul. 9, 2026

(54) DISPLAY DEVICE

(71) Applicant: BOE TECHNOLOGY GROUP CO., LTD., Beijing (CN)

(72) Inventors: Penghao GU, Beijing (CN); Yongxiao GAO, Beijing (CN); Ce WANG, Beijing (CN); Shiyou WANG, Beijing (CN); Qiang TANG, Beijing (CN); Lei ZHANG, Beijing (CN); Zhihui WANG, Beijing (CN)

(73) Assignee: BOE TECHNOLOGY GROUP CO., LTD., Beijing (CN)

(21) Appl. No.: 19/555,073

(22) Filed: Mar. 3, 2026

Related U.S. Application Data
(63) Continuation-in-part of application No. 19/014,449, filed on Jan. 9, 2025.
Application No. 19/014,449 is a continuation-in-part of application No. 17/418,938, filed on Jun. 28, 2021, now Pat. No. 12,228,964.

(30) Foreign Application Priority Data
May 28, 2025 (CN) 202510699233.3
Sep. 8, 2025 (CN) 202511279687.1

(51) Int. Cl. H05K 5/02; H05K 5/03; H10K 59/131; H10K 59/80; H10K 102/00

(52) U.S. Cl. CPC H05K 5/0217; H05K 5/03; H10K 59/873; H10K 59/131; H10K 2102/311

(57) ABSTRACT

A display device is provided. The display device includes: a display panel, where the display panel includes: a bendable area including at least a display area of the display panel; a bonding area including a part of a non-display area of the display panel; and a folding area located between the bendable area and the bonding area; and a supporting film, where the supporting film is adhered to a back surface of the display panel, the supporting film includes a first film portion and a second film portion, an orthographic projection of the first film portion on the display panel overlaps with the bendable area, and an orthographic projection of the second film portion on the display panel overlaps with the bonding area, where a material of the first film portion is different from a material of the second film portion.

### CROSS REFERENCE TO RELATED APPLICATION(S)

This application is a continuation-in-part application of U.S. patent application Ser. No. 19/014,449 filed on Jan. 9, 2025, and claims priority to Chinese Patent Application No. 202510699233.3 filed on May 28, 2025, and Chinese Patent Application No. 202511279687.1 filed on Sep. 8, 2025. The U.S. patent application Ser. No. 19/014,449 is a continuation-in-part application of U.S. patent application Ser. No. 17/418,938 filed on Jun. 28, 2021, the U.S. patent application Ser. No. 17/418,938 is a Section 371 National Stage Application of International Application No. PCT/CN2020/141044, filed on Dec. 29, 2020, entitled “DISPLAY DEVICE, SUPPORTING FILM FOR DISPLAY DEVICE AND ELECTRONIC APPARATUS”, the PCT Application No. PCT/CN2020/141044 claims priority to Chinese Application No. 202010114130.3 filed on Feb. 24, 2020, the contents of which are incorporated herein by reference in their entireties.

### TECHNICAL FIELD

The present disclosure relates to a field of display technology, and in particular to a display device.

### BACKGROUND

A display device is a device that may display information such as texts, images, or videos. Examples of display devices include liquid crystal display devices (LCD), organic light emitting diode display devices (OLED), plasma display devices, and the like. In recent years, flexible display devices have attracted more and more attention due to characteristics of bendable, foldable or rollable. The flexible display device may protect and support a flexible display panel by attaching a supporting structure to a bottom of the flexible display panel. Generally, a thickness of the supporting structure is relatively thicker than thicknesses of other single film layers of the flexible display panel. Therefore, flexural recovery performance, flexural strength, and deformability of the supporting structure will directly affect an overall flexural performance of the flexible display device.

Above information disclosed in this part is only used to understand the background of the inventive concept of the present disclosure, and therefore, the above information may include information that does not constitute the prior art.

### SUMMARY

In order to solve at least one aspect of the abovementioned problems, embodiments of the present disclosure provide a display device.

In an aspect, a display device is provided, including: a display panel, the display panel includes: a bendable area, including at least a display area of the display panel; a bonding area, including a part of a non-display area of the display panel; and a folding area located between the bendable area and the bonding area; and a supporting film, the supporting film is adhered to a back surface of the display panel, the supporting film includes a first film portion and a second film portion, an orthographic projection of the first film portion on the display panel overlaps with the bendable area, and an orthographic projection of the second film portion on the display panel overlaps with the bonding area. A material of the first film portion is different from a material of the second film portion; the first film portion includes a first supporting portion, the second film portion includes a second supporting portion, and an elastic modulus of a material of the first supporting portion is greater than an elastic modulus of a material of the second supporting portion; and the first film portion includes an ultra-thin glass material.

According to some exemplary embodiments, the material of the first supporting portion is ultra-thin glass, and the material of the second supporting portion is at least one of polyethylene terephthalate, polyimide, polyurethane, polymethyl methacrylate, silicone, acrylate, polyurethane acrylate, and epoxy resin.

According to some exemplary embodiments, the first film portion further includes a first adhesive portion located in the display area, and the second film portion further includes a second adhesive portion located in the bonding area; and the first supporting portion includes a first supporting sub-portion recessed inward relative to the first adhesive portion, and the first supporting portion is attached to the first adhesive portion; and the second supporting portion is attached to the second adhesive portion.

According to some exemplary embodiments, the first supporting portion further includes a second supporting sub-portion; and the second supporting sub-portion is disposed on a side of the first supporting sub-portion close to the first adhesive portion, and the second supporting sub-portion covers a surface of the first supporting sub-portion close to the first adhesive portion and a side surface of the first supporting sub-portion; or the second supporting sub-portion is disposed on a side of the first supporting sub-portion away from the first adhesive portion, and the second supporting sub-portion covers a surface of the first supporting sub-portion away from the first adhesive portion and a side surface of the first supporting sub-portion; or the second supporting sub-portion is disposed on a side of the first supporting sub-portion close to the first adhesive portion and on a side of the first supporting sub-portion away from the first adhesive portion, and the second supporting sub-portion covers a surface of the first supporting sub-portion close to the first adhesive portion, a surface of the first supporting sub-portion away from the first adhesive portion and a side surface of the first supporting sub-portion.

According to some exemplary embodiments, a material of the second supporting sub-portion is the same as a material of the second supporting portion; and the second supporting sub-portion is located in the display area; or the second supporting sub-portion extends from the display area to the folding area and abuts against the second supporting portion.

According to some exemplary embodiments, the second supporting sub-portion extends from the display area to the folding area, an elastic modulus of the second supporting sub-portion located in the display area is greater than an elastic modulus of the second supporting sub-portion located in the folding area; and the elastic modulus of the second supporting portion is greater than the elastic modulus of the second supporting sub-portion located in the folding area.

According to some exemplary embodiments, the second supporting sub-portion is located in the display area; the supporting film further includes a third film portion; the third film portion includes a third supporting portion and a third adhesive portion, the third supporting portion is located in the folding area and is disposed on a side of the third adhesive portion away from the display panel; two sides of the third supporting portion in an extending direction of the third supporting portion abut against the second supporting sub-portion and the second supporting portion, respectively; and a material of the third supporting portion is different from a material of the second supporting sub-portion.

According to some exemplary embodiments, the display device further includes a third supporting sub-portion; the third supporting sub-portion is located in an inward-recessed space of the first supporting sub-portion relative to the first adhesive portion, and is attached to the first adhesive portion; the display device further includes: an optically clear adhesive layer disposed on a side of the display panel away from the first adhesive portion, and a cover plate disposed on a side of the optically clear adhesive layer away from the display panel; and a gap is provided between the third supporting sub-portion and the first supporting sub-portion; the cover plate includes a light-transmitting portion corresponding to the first supporting sub-portion and a light-shielding portion corresponding to the third supporting sub-portion; and an orthographic projection of the light-shielding portion on the display panel covers an orthographic projection of the gap on the display panel.

According to some exemplary embodiments, the bendable area includes at least one bending region; the bending region is located in the display area; and an area of the bending region is less than an area of the display area; the first supporting sub-portion includes a first sub-portion located in the bending region, and a second sub-portion and a third sub-portion located on two sides of the first sub-portion in an extending direction of the first sub-portion and connected to the first sub-portion; an average thickness of the second sub-portion is the same as an average thickness of the third sub-portion; a minimum thickness of the first sub-portion is less than the average thickness of the second sub-portion.

According to some exemplary embodiments, the first sub-portion includes a first surface close to the first adhesive portion and a fourth surface away from the first adhesive portion, the second sub-portion includes a second surface close to the first adhesive portion and a fifth surface away from the first adhesive portion, and the third sub-portion includes a third surface close to the first adhesive portion and a sixth surface away from the first adhesive portion; the first surface, the second surface and the third surface are coplanar; or the fourth surface, the fifth surface and the sixth surface are coplanar; or an extension plane of the second surface and an extension plane of the third surface are coplanar, and an extension plane of the fifth surface and an extension plane of the sixth surface are coplanar, and both the first surface and the fourth surface are located between the extension plane of the second surface and the extension plane of the fifth surface.

According to some exemplary embodiments, the bendable area includes a plurality of bending regions spaced apart from each other; and shortest distances from the first sub-portions of two adjacent bending regions to the first adhesive portion are different.

According to some exemplary embodiments, the bendable area includes at least one bending region; the bending region is located in the display area; and an area of the bending region is less than an area of the display area; the first supporting sub-portion includes a plurality of third grooves located in the bending region; an orientation of the third grooves is a direction away from the first adhesive portion; or the orientation of the third grooves is a direction towards the first adhesive portion; or the orientation of the third grooves includes both a direction away from the first adhesive portion and a direction towards the first adhesive portion; and the plurality of third grooves are arranged side by side in a second direction, and depths of the plurality of third grooves increase sequentially towards a center of the bending region in the second direction.

According to some exemplary embodiments, the bendable area includes a rollable area; the rollable area is located in the display area; and an area of the rollable area is less than an area of the display area; the first supporting sub-portion includes a first sub-portion located in the rollable area, and a second sub-portion connected to the first sub-portion and located on a side of the first sub-portion close to the folding area; and an average thickness of the second sub-portion is greater than a minimum thickness of the first sub-portion.

According to some exemplary embodiments, the first sub-portion includes a first surface close to the first adhesive portion and a fourth surface away from the first adhesive portion, and the second sub-portion includes a second surface close to the first adhesive portion and a fifth surface away from the first adhesive portion; the fourth surface and the fifth surface are coplanar; the second surface of the second sub-portion contacts the first adhesive portion; and the first supporting portion further includes a second supporting sub-portion disposed between an extension plane of the second surface and the first surface, and the second supporting sub-portion abuts against a side surface of the second sub-portion close to the first sub-portion.

According to some exemplary embodiments, the supporting film further includes a fourth supporting portion disposed on a side of the second supporting portion away from the second adhesive portion; and a sum of an average thickness of the second supporting portion and an average thickness of the fourth supporting portion is the same as a maximum thickness of the first supporting portion.

According to some exemplary embodiments, the display panel includes a first portion provided with the display area, and a second portion provided with the folding area and the bonding area, the first portion includes a display surface and a non-display surface opposite to each other, and the second portion is bent to a side close to the non-display surface; the first film portion includes a first adhesive portion located in the display area, and the second film portion includes a second adhesive portion located in the bonding area; the first adhesive portion is connected to the non-display surface; the second adhesive portion is disposed on a side of the second portion close to the first portion, and the second adhesive portion is connected to the second portion; the first supporting portion is disposed on a side of the first adhesive portion away from the first portion, and the first supporting portion is connected to the first adhesive portion; the second supporting portion is disposed on a side of the second adhesive portion close to the first portion, and the second supporting portion is connected to the second adhesive portion; the first portion includes a first boundary and a second boundary opposite to each other in a first direction, and a third boundary and a fourth boundary opposite to each other in a second direction, the first direction intersects the second direction; and the third boundary is farther from the second portion than the fourth boundary; the first supporting portion includes a fifth boundary and a sixth boundary opposite to each other in the first direction, and a seventh boundary and an eighth boundary opposite to each other in the second direction; and the seventh boundary is farther from the second portion than the eighth boundary; and in the first direction, the fifth boundary extends beyond an outer side of the first boundary, and the sixth boundary extends beyond an outer side of the second boundary; and in the second direction, the seventh boundary extends beyond an outer side of the third boundary.

According to some exemplary embodiments, a junction between the first boundary and the third boundary has a first corner, and a junction between the second boundary and the third boundary has a second corner; a junction between the fifth boundary and the seventh boundary has a third corner, and a junction between the sixth boundary and the seventh boundary has a fourth corner; an outer boundary of the third corner extends beyond an outer boundary of the first corner, and an outer boundary of the fourth corner extends beyond an outer boundary of the second corner; and in the first direction, the eighth boundary is flush with the fourth boundary.

According to some exemplary embodiments, the display panel further includes a light-transmitting hole disposed in the display area; and the first supporting portion includes a through hole, and an outer boundary of an orthographic projection of the through hole on the display panel extends beyond an outer boundary of the light-transmitting hole.

According to some exemplary embodiments, a sum of a thickness of the first adhesive portion and a thickness of the first supporting portion is equal to a sum of a thickness of the second adhesive portion and a thickness of the second supporting portion; and an elastic modulus of the first adhesive portion is less than an elastic modulus of the second adhesive portion.

According to some exemplary embodiments, the display device further includes a supporting member disposed on a side of the first supporting portion away from the first adhesive portion and connected to the first supporting portion.

### BRIEF DESCRIPTION OF THE DRAWINGS

Through following description of the present disclosure with reference to drawings, other purposes and advantages of the present disclosure will be apparent and may facilitate a comprehensive understanding of the present disclosure.

FIG. 1 is a perspective view of a display device according to some exemplary embodiments of the present disclosure;

FIG. 2 is a plan view of a display device according to some exemplary embodiments of the present disclosure;

FIG. 3 is a cross-sectional view of the display device taken along line AA′ in FIG. 2 according to some exemplary embodiments of the present disclosure;

FIG. 4 is an enlarged view of part I in FIG. 3 of the display device according to some exemplary embodiments of the present disclosure;

FIG. 5 is a cross-sectional view of a pixel structure of a display panel of a display device according to some exemplary embodiments of the present disclosure;

FIG. 6 is a cross-sectional view of a display device in a state where a non-display area is folded around an axis in a folding area according to some exemplary embodiments of the present disclosure;

FIG. 7 is a partial enlarged view of the display device at part II of FIG. 6 according to some exemplary embodiments of the present disclosure;

FIG. 8 is a cross-sectional view of a display device in a state where a non-display area is folded around an axis in a folding area according to some other exemplary embodiments of the present disclosure;

FIG. 9 is a cross-sectional view of a supporting film according to some exemplary embodiments of the present disclosure;

FIGS. 10A to 10F respectively illustrate cross-sectional views of a supporting film after some steps of a manufacturing method of a supporting film are performed according to some exemplary embodiments of the present disclosure;

FIG. 11A is a cross-sectional view of a supporting film according to some other exemplary embodiments of the present disclosure;

FIG. 11B is a schematic diagram of a display device before bending according to some exemplary embodiments of the present disclosure;

FIGS. 12A to 12G respectively illustrate schematic diagrams of a supporting film after some steps of a manufacturing method of the supporting film are performed according to some exemplary embodiments of the present disclosure;

FIG. 13 is a schematic diagram of a display device before bending according to some exemplary embodiments of the present disclosure;

FIGS. 14A to 14C respectively illustrate cross-sectional views of a supporting film after some steps of a manufacturing method of the supporting film are performed according to some exemplary embodiments of the present disclosure;

FIG. 15 is a schematic diagram of a display device before bending according to some exemplary embodiments of the present disclosure;

FIG. 16 is a plan view of a supporting film according to some exemplary embodiments of the present disclosure;

FIG. 17 is a cross-sectional view of a supporting film according to some exemplary embodiments of the present disclosure;

FIGS. 18 to 21 respectively illustrate schematic diagrams of a display device before bending according to some exemplary embodiments of the present disclosure;

FIG. 22 is a partial cross-sectional view of a supporting film in the related art;

FIG. 23 is a partial cross-sectional view of a supporting film according to some exemplary embodiments of the present disclosure;

FIGS. 24 and 25 respectively illustrate schematic diagrams of a display device before bending according to some exemplary embodiments of the present disclosure;

FIG. 26 is a cross-sectional view of a supporting film according to some exemplary embodiments of the present disclosure;

FIG. 27 is a schematic diagram of a display device before bending according to some exemplary embodiments of the present disclosure;

FIG. 28 is a cross-sectional view of a supporting film according to some exemplary embodiments of the present disclosure;

FIG. 29 is a schematic diagram of a display device before bending according to some exemplary embodiments of the present disclosure;

FIG. 30 is a cross-sectional view of a supporting film according to some exemplary embodiments of the present disclosure;

FIG. 31 is a schematic diagram of a display device before bending according to some exemplary embodiments of the present disclosure;

FIGS. 32 and 33 respectively illustrate cross-sectional views of a supporting film according to some exemplary embodiments of the present disclosure;

FIGS. 34 to 42 respectively illustrate schematic diagrams of a display device before bending according to some exemplary embodiments of the present disclosure;

FIG. 43A is a schematic top view of a structure on a back side of a display device according to an embodiment of the present disclosure;

FIG. 43B is a schematic cross-sectional view of a structure taken along section line AA in FIG. 43A;

FIG. 43C is a schematic cross-sectional view of a display device according to an embodiment of the present disclosure, in which a bonding area of a display panel is bent;

FIG. 44A is another schematic cross-sectional view of a structure taken along section line AA in FIG. 43A;

FIG. 44B is a schematic cross-sectional view of a structure of a first supporting layer taken along section line AA in FIG. 43A according to an embodiment of the present disclosure;

FIG. 45A is a schematic top view of a structure on a back side of a display device according to an embodiment of the present disclosure;

FIG. 45B is another schematic cross-sectional view of a display device according to an embodiment of the present disclosure, in which a bonding area of a display panel is bent;

FIG. 46 is a schematic diagram of a manufacturing process of a display device according to an embodiment of the present disclosure;

FIG. 47 is a structural diagram of a display device provided by an embodiment of the present disclosure;

FIG. 48 is a partial cross-sectional view of the display device in FIG. 47 taken along section line A-A′;

FIG. 49 is a partial enlarged view at part M of some film layers of a display module in FIG. 47;

FIG. 50 is a structural diagram of a supporting film provided by an embodiment of the present disclosure;

FIG. 51 is a top view of some film layers of the supporting film in FIG. 50;

FIG. 52 is a flowchart of a manufacturing method of a display module provided by the present disclosure;

FIGS. 53 to 64 are step diagrams of the manufacturing method in FIG. 52;

FIG. 65 is a step diagram of adhering a first supporting portion in step S4 of FIG. 52;

FIG. 66 is another step diagram of adhering a first supporting portion in step S4 of FIG. 52;

FIG. 67 is another step diagram of adhering a first supporting portion in step S4 of FIG. 52;

FIG. 68 is a flowchart of another manufacturing method of a display module provided by the present disclosure;

FIGS. 69 and 70 are step diagrams of the manufacturing method in FIG. 68;

FIG. 71 is a step diagram of attaching a first supporting portion in step S4 of FIG. 68;

FIG. 72 is another step diagram of adhering the first supporting portion in step S4 of FIG. 68;

FIG. 73 is another step diagram of adhering the first supporting portion in step S4 of FIG. 68; and

FIG. 74 is another step diagram of adhering the first supporting portion in step S4 of FIG. 68.

It should be noted that, for clarity, in the drawings used to describe the embodiments of the present disclosure, sizes of layers, structures or regions may be enlarged or reduced, that is, the drawings are not drawn according to actual scale.

### DETAILED DESCRIPTION OF EMBODIMENTS

In following description, for purpose of explanation, many specific details are set forth to provide a comprehensive understanding of various exemplary embodiments. However, it is obvious that the various exemplary embodiments may be implemented without these specific details or with one or more equivalent arrangements. In other cases, well-known structures and devices are shown in block diagram form to avoid unnecessarily obscuring the various exemplary embodiments. In addition, the various exemplary embodiments may be different, but are not necessary to be exclusive. For example, without departing from an inventive concept, specific shapes, configurations, and characteristics of the exemplary embodiment may be used or implemented in another exemplary embodiment.

In the drawings, for purpose of clarity and/or description, a size and a relative size of an element may be enlarged. In this way, the size and the relative size of each element are not necessary to be limited to those shown in the drawings. When the exemplary embodiments may be implemented differently, specific process sequence may be performed differently from the sequence described. For example, two consecutively described processes may be performed substantially simultaneously or in a sequence opposite to the described sequence. In addition, the same reference numerals indicate the same elements.

When an element is described as being “on”, “connected to” or “coupled to” another element, the element may be directly on the another element, directly connected to the another element or directly coupled to the another element, or an intermediate element may be present. However, when an element is described as being “directly on”, “directly connected to” or “directly coupled to” another element, there is no intermediate element. Other terms and/or expressions used to describe the relationship between elements should be interpreted in a similar manner, for example, “between” and “directly between”, “adjacent” and “directly adjacent”, “on” and “directly on” etc. In addition, the term “connect” may refer to a physical connection, an electrical connection, a communication connection, and/or a fluid connection. In addition, X axis, Y axis, and Z axis are not limited to the three axes of the Cartesian coordinate system, and may be interpreted in a broader meaning. For example, the X axis, the Y axis, and the Z axis may be perpendicular to each other, or may represent different directions that are not perpendicular to each other. For the purpose of the present disclosure, “at least one of X, Y, and Z” and “at least one selected from a group consisting of X, Y, and Z” may be interpreted as only X, only Y, only Z, or any combination of two or more of X, Y, and Z such as XYZ, XYY, YZ, and ZZ. As shown in the present disclosure, the term “and/or” includes any and all combinations of one or more of the related items listed.

It should understood that although terms “first”, “second”, etc. may be used to describe various elements, the elements should not be limited by the terms. The terms are used to distinguish one element from another one element. For example, a first element may be referred to as a second element, and similarly, a second element may be referred to as a first element.

For the purpose of description, spatially relative terms such as “below”, “under”, “underneath”, “down”, “above”, “up”, “on”, “higher”, “side” (for example, in “sidewall”) and the like may be used in the present disclosure to describe relationship between one element and another (or some other) elements as shown in the drawings. In addition to orientations depicted in the drawings, the spatially relative terms are also intended to contain different orientations of an apparatus in use, operation, and/or manufacture. For example, if the apparatus in the drawings is turned over, elements described as “below” or “under” other elements or features will then be oriented “above” or “on” the other elements or features. Therefore, the exemplary term “below” may contain two orientations of above and below. In addition, the apparatus may be otherwise positioned (for example, rotated by 90 degrees or in other orientations), so that the spatially relative terms in the present disclosure are explained accordingly.

The terms used in the present disclosure is for purpose of describing specific embodiments and are not intended to be limiting. As used herein, unless otherwise clearly indicated, a singular form “a”, “an” and “the” is also intended to include a plural form. Moreover, when the term “include” is used in this specification, the term indicates a presence of stated features, wholes, steps, operations, elements, components, and/or groups thereof, but does not exclude a presence or addition of one or more other features, other wholes, other steps, other operations, other elements, other components and/or groups thereof. It is also noted that, as used in the present disclosure, the terms “substantially”, “about” and other similar terms are used as approximate terms rather than degree terms. Thus, the terms “substantially”, “about” and other similar terms are used to describe an inherent deviation of a measured value, a calculated value and/or a provided value that those of ordinary skill in the art would recognize.

Unless otherwise defined, all terms (including technical and scientific terms) used in the present disclosure have the same meanings as commonly understood by those skilled in the art (the present disclosure is a part thereof).

Those skilled in the art should understand that, during an elastic deformation stage of a material, a stress and a strain become proportional (that is, in accordance with Hooke's law), and a proportional coefficient may be called elastic modulus. The “elastic modulus” is a physical quantity that describes elasticity of materials and is a general term. An expression method of the elastic modulus may be “Young's modulus”, “bulk modulus” and so on.

“Bending strength” refers to a maximum stress that a material may withstand when the material breaks or reaches a specified bending moment under a bending load, and the stress is a maximum normal stress during bending. The bending strength reflects an ability of a material to resist bending and is used to measure a bending performance of a material.

“Creep” refers to a phenomenon that a strain of a solid material increasing with time going under a condition that the stress is kept constant. The creep is different from a plastic deformation. The plastic deformation usually occurs after a stress exceeds an elastic limit. However, as long as a stress acts for a long time, the creep may also occur even if a stress is smaller than a force applied by an elastic limit.

“Breaking Elongation” refers to a relative elongation of a material at break, that is, a ratio of an elongation of a material at the break to an initial length of the material, which is expressed as a percentage. The breaking elongation is an index that characterizes softness performance and elasticity performance of materials.

“Breaking strength” refers to a ratio of a tensile force of a material at break to a cross-sectional area of the break.

“Light transmittance” or “transmittance” refers to an ability of light to pass through a medium, and is a percentage of a luminous flux that passes through a transparent or semi-transparent body to an incident luminous flux.

“Haze” refers to a percentage of a transmitted light intensity that deviates from an incident light at an angle of more than 2.5° to a total transmitted light intensity. The greater the haze, the lower a gloss and a transparency of the film, especially an image quality.

“100K R3 dynamic bending” means 100,000 times of dynamic bending tests with a bending radius of 3 mm. In this field, the dynamic bending tests may be used to test a dynamic bending performance.

Hereinafter, the exemplary embodiments of the present disclosure will be described with reference to the drawings.

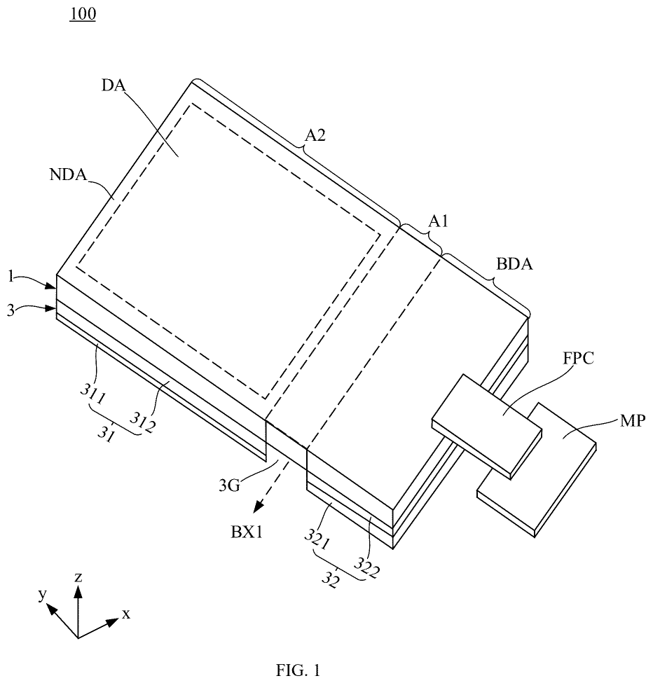

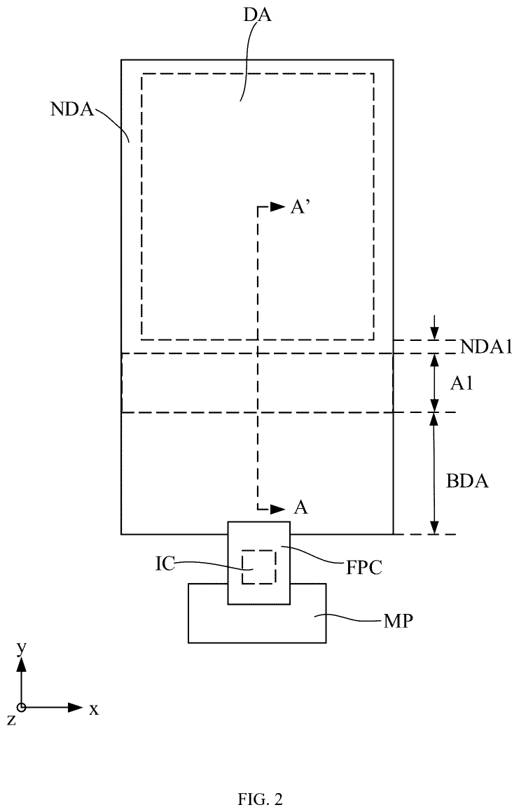

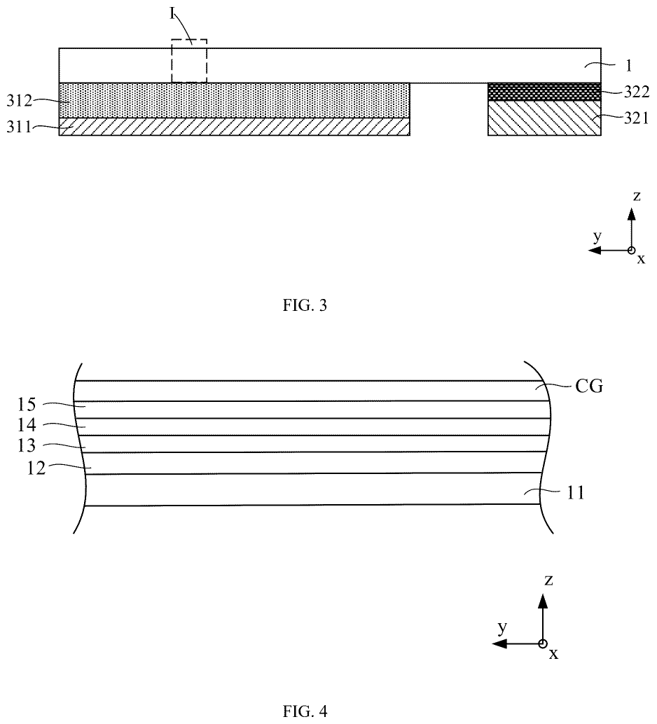

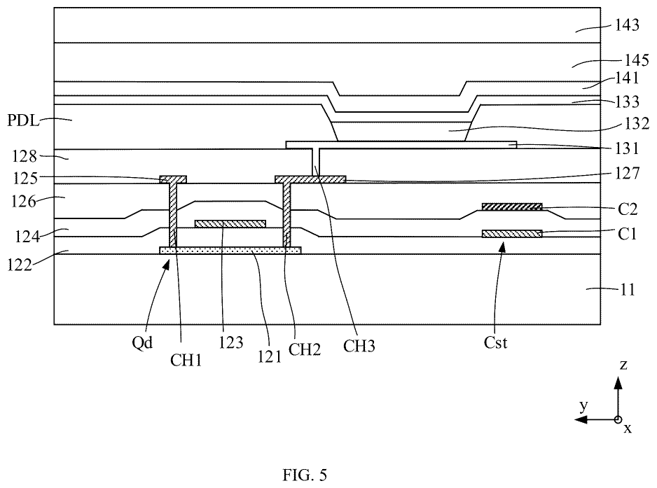

FIG. 1 is a perspective view of a display device according to some exemplary embodiments of the present disclosure. FIG. 2 is a plan view of a display device according to some exemplary embodiments of the present disclosure. FIG. 3 is a cross-sectional view of the display device taken along line AA′ in FIG. 2 according to some exemplary embodiments of the present disclosure. FIG. 4 is an enlarged view of part I in FIG. 3 of the display device according to some exemplary embodiments of the present disclosure.

Referring to FIGS. 1 and 2, a display device 100 may be applied to a mobile terminal, for example. An example of the mobile terminal includes a tablet personal computer (PC), a smart phone, a personal digital assistant (PDA), a portable multimedia player, a game console, or a watch-type electronic device, and so on. However, the embodiments of the present disclosure are not intended to limit the type of the mobile terminal to which the display device 100 is applicable. In some exemplary embodiments, the display device 100 may be used not only in a large electronic device such as a television (TV) or an external billboard, but also in a medium or small electronic device such as a PC, a notebook computer, a car navigation device, or a camera, etc.

The display device 100 may have a rectangular shape in a plan view. The display device 100 may have two short sides extending in a first direction x and two long sides extending in a second direction y. The two long sides and the two short sides of the display device 100 may intersect to form right angles or arc shapes. The embodiments of the present disclosure are not intended to limit a planar shape of the display device 100. For example, in other embodiments, the display device 100 may have a circular shape, a polygonal shape, or other shapes in the plan view.

The display device 100 may include a display panel 1 and a supporting film 3.

The display panel 1 may have a display area DA that displays information such as images and a non-display area NDA that does not display information such as images. In some exemplary embodiments, the non-display area NDA may be disposed to be adjacent to the display area DA, for example, surrounding the display area DA.

In some exemplary embodiments, the display panel 1 may be a display panel that includes light emitting elements. For example, the display panel 1 may include an organic light emitting diode (OLED), a quantum dot light emitting diode (QLED), and/or an inorganic material-based micro-LED. For ease of description, it is assumed that the display panel 1 includes an OLED, and the elements of the display panel 1 will be described in more detail below.

Referring to FIGS. 1 to 4, the display panel 1 of the display device 100 may include elements such as a base substrate 11, a driving layer 12, an organic light emitting element layer 13, an encapsulation layer 14, a polarizer 15, a cover plate CG, etc. It should be understood that the display panel 1 may also include other film layers or elements, which are not described exhaustively in the embodiments of the present disclosure.

Unless otherwise specified, terms “upper”, “top”, “top surface” and “upward” as used herein refer to a display side of the display panel 1, that is, one side of the display panel 1 in z-axis direction. And terms “lower”, “bottom”, “bottom surface”, “back” and “downward” as used herein refer to an opposite side of the display panel 1 with respect to the display side, that is, one side of the display panel 1 in a direction opposite to the z-axis direction.

The base substrate 11 provides a bottom surface of the display panel 1. The base substrate 11 may be a flexible substrate, and may include a plastic material with relatively excellent heat resistance and durability, such as polyvinyl ether phthalate, polyethylene naphtha late (PEN), polycarbonate (PC), polyarylate, polyetherimide, polyether sulfone (PES) or polyimide (PI). For ease of description, it is assumed that the base substrate 11 includes PI.

The display panel 1 may include a bonding area BDA, for example, a plurality of electrical connection portions (for example, PAD) may be provided in the bonding area BDA to electrically connect a signal line of the display panel 1 to a driving circuit. In some exemplary embodiments, the bonding area BDA is located in the non-display area NDA. As shown in FIG. 1, the bonding area BDA is located on a side of the non-display area NDA away from the display area DA in a direction y.

In some exemplary embodiments, a driver integrated chip (or circuit) IC may be installed on a flexible PCB (i.e, FPC shown in FIG. 1). The driver integrated chip IC provides driving signals to the display panel 1. In some exemplary embodiments, the driver integrated chip IC may include at least one of a data driver that applies data signals to a data line, a gate driver that applies gate signals to a gate line and a signal controller that controls operations of the data driver and the gate driver. In some exemplary embodiments, the driver integrated chip IC may be installed on the flexible PCB in a chip-on-film (COF) manner. In some exemplary embodiments, the driver integrated chip IC may be installed in the non-display area NDA of the display panel 1.

For example, a main PCB (MP shown in FIG. 1) may be electrically connected to the display panel 1 via the FPC. The main PCB may transmit signals to the driver integrated chip IC or receive signals from the driver integrated chip IC. The main PCB may provide image data, control signals, and power supply voltage to the display panel 1 or the FPC. The main PCB may include active elements and passive elements.

The display panel 1 may also include a folding area A1. In a plan view, the folding area A1 may extend through the non-display area NDA along the first direction x. In some exemplary embodiments, the folding area A1 may be disposed in a part of the non-display area NDA adjacent to the display area DA, such as in a part adjacent to the display area DA in the second direction y. That is, the folding area A1 may be located in the non-display area NDA, for example, between the display area DA and the bonding area BDA.

The folding area A1 may be a part of the non-display area NDA, and the folding area A1 may be spaced apart from the display area DA. Referring to FIG. 2, a part of the non-display area NDA disposed under the display area DA may include a first non-display area NDA1 and the bonding area BDA. The first non-display area NDA1 is adjacent to the display area DA, and the bonding area BDA is farther from the display area DA than the first non-display area NDA1. The folding area A1 may be located between the first non-display area NDA1 and the bonding area BDA. The display panel 1 may be bent or folded along a bending axis BX1 located in the folding area A1, the bending axis BX1 extends in the folding area A1 along the first direction x. With the folding area A1, the bonding area BDA of the display panel 1 may be bent or folded to a back surface of the display panel. Therefore, when the display device 100 is viewed from above, the non-display area NDA may be reduced, and a bezel width of the display device 100 may also be reduced.

It should be noted that in the present disclosure, unless otherwise specified, “bending axis” refers to an imaginary line, rather than a physical axis or physical structure. Generally, a component with a bending axis may be bent or folded around the bending axis.

In the embodiments of the present disclosure, the display panel 1 is a flexible display panel. That is, in addition to the part in the folding area A1 that may be bent or folded, at least a part of the display panel 1 located in the display area DA is flexible, that is, the part of the display panel 1 located in the display area DA may be bent or folded, thereby realizing a flexible display device. For ease of description, an area of the display panel 1 excluding the bonding area BDA and the folding area A1 is referred to as a bendable area A2. The bendable area A2 includes at least the display area DA. The folding area A1 is located between the bendable area A2 and the bonding area BDA in the direction y.

Referring to FIG. 1, the supporting film 3 may be disposed under the display panel 1. In some exemplary embodiments, the supporting film 3 may be adhered to the bottom surface of the display panel 1. The supporting film 3 may support the flexible display panel 1 and may protect the bottom surface of the display panel 1.

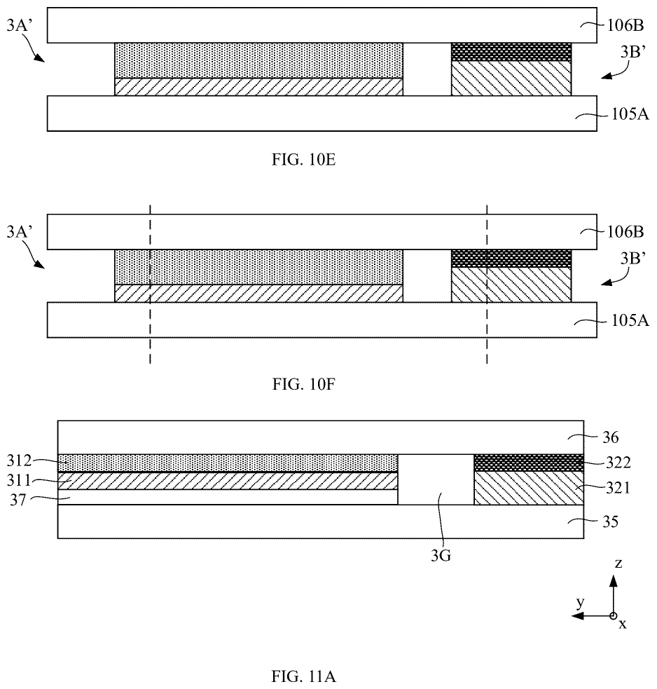

FIG. 9 is a cross-sectional view of a supporting film according to some exemplary embodiments of the present disclosure. With reference to FIGS. 1 to 3 and FIG. 9 in combination, a groove 3G may be defined in the supporting film 3. The groove 3G may be formed to overlap with the folding area A1 of a display panel 1 and may extend along the first direction x. Since the groove 3G is defined in the supporting film 3 to overlap with the folding area A1, the display panel 1 may be bent or folded in the folding area A1.

The supporting film 3 may include a first film portion 31 and a second film portion 32, and the first film portion 31 and the second film portion 32 are separated by the groove 3G. In other words, the supporting film 3 includes the first film portion 31, the groove 3G and the second film portion 32 that are sequentially arranged in the second direction y.

The first film portion 31 may overlap with (for example, coincide) the bendable area A2 of the display panel 1, that is, an orthographic projection of at least the display area DA of the display panel 1 on the supporting film 3 falls within the first film portion 31.

The second film portion 32 may overlap with (for example, coincide) the bonding area BDA of the display panel 1, that is, an orthographic projection of the bonding area BDA of the display panel 1 on the supporting film 3 falls within the second film portion 32.

In the embodiments of the present disclosure, the supporting film 3 adopts a zone-design, that is, the first film portion 31 and the second film portion 32 include different materials or structures. Through such the zone-design, following effects may be achieved: improving a bending performance of the supporting film in the bendable area, such as improving bendability and bending recovery performance, reducing or avoiding creases, etc.; and improving optical performance of the supporting film in the bonding area, for example, increasing a light transmittance.

In the exemplary embodiments of the present disclosure, the first film portion 31 and the second film portion 32 include different materials.

The first film portion 31 includes a first supporting portion 311, and the first supporting portion 311 is made of a material with high elastic modulus. The second film portion 32 includes a second supporting portion 321, and the second supporting portion 321 is made of a material with low elastic modulus. It should be noted that the “high elastic modulus” and the “low elastic modulus” here are relative concepts, which means that the elastic modulus of the material of the first supporting portion 311 is higher than the elastic modulus of the material of the second supporting portion 321. For example, the elastic modulus of the material of the first supporting portion 311 may be 20 to 200 times the elastic modulus of the material of the second supporting portion 321. In this way, the bending performance of the supporting film in the bendable area may be improved, for example, the bending performance and the bending recovery performance may be improved, and the creases may be reduced or avoided.

Optionally, a light transmittance of the second supporting portion 321 may be greater than a light transmittance of the first supporting portion 311. In this way, the optical performance of the supporting film in the bonding area may be improved, for example, the light transmittance may be improved. Therefore, the bonding area may be clearly observed, which is beneficial to grab a bonding mark and observe a crease.

In addition, in conjunction with Table 1 below, in the embodiments of the present disclosure, in addition to considering the elastic modulus and the light transmittance, indicators such as haze, breaking elongation, breaking strength, performance under “100K R3 dynamic bending” test and so on are further considered to be used as a basis for selecting the material of the first supporting portion 311 and the second supporting portion 321.

In some exemplary embodiments, the material of the first supporting portion 311 may include a material with high elastic modulus and low creeping, including but not limited to polyimide (PI) and metal materials such as stainless steel, nickel-iron alloys, copper-zinc alloys, and nickel-titanium alloys, etc.

In some exemplary embodiments, the material of the second supporting portion 321 may include a material with a relatively low elastic modulus and a relatively high light transmittance, including but not limited to, polyethylene terephthalate (PET).

In some exemplary embodiments, a thickness of the first supporting portion 311 may be less than a thickness of the second supporting portion 321. For example, the thickness of the second supporting portion 321 may be 1.3 to 10 times the thickness of the first supporting portion 311. In the embodiments of the present disclosure, since the first supporting portion is made of a material with high elastic modulus and low deformation, a thin first supporting portion may be implemented. Further, the thin first supporting portion may improve the bending performance of the supporting film in the bendable area.

It should be noted that in the present disclosure, the term “thickness” refers to a size of an element, a component or a film layer in a light emitting direction (the third direction z in the drawings).

The first film portion 31 further includes a first adhesive portion 312, and the first adhesive portion 312 includes an adhesive glue such as acrylic glue, which is used to attach the first film portion 31 to the back surface of the flexible display panel 1 to support the display panel 1.

The second film portion 32 further includes a second adhesive portion 322, and the second adhesive portion 322 includes an adhesive glue such as acrylic glue. A material of the first adhesive portion 312 and a material of the second adhesive portion 322 may be the same.

A thickness of the first adhesive portion 312 is greater than a thickness of the second adhesive portion 322. For example, the thickness of the first adhesive portion 312 may be 1.3-10 times the thickness of the second adhesive portion 322. That is, in the above-mentioned bendable area, a thicker adhesive layer may be used to increase a buffer effect of the supporting film in the bendable area, thereby further improving the bending performance of the supporting film in the bendable area.

In the exemplary embodiment of the present disclosure, a sum of the thickness of the first supporting portion 311 and the thickness of the first adhesive portion 312 is equal to a sum of the thickness of the second supporting portion 312 and the thickness of the second adhesive portion 322. In this way, it is beneficial to attach the supporting film to the display panel, thereby meeting attaching requirements.

With reference to Table 2, in the exemplary embodiments of the present disclosure, the thickness of the first supporting portion 311 may be less than the thickness of the first adhesive portion 312, that is, in the bendable area, the supporting film has a structure of a small thickness supporting portion and a large thickness adhesive portion; the thickness of the second supporting portion 321 may be greater than the thickness of the second adhesive portion 322, that is, in the bonding area, the supporting film has a structure of a large thickness supporting portion and a small thickness adhesive portion.

Optionally, in the exemplary embodiments of the present disclosure, the thickness of the first supporting portion 311 may be equal to the thickness of the second adhesive portion 321, and the thickness of the second supporting portion 321 may be equal to the thickness of the first adhesive portion 312.

Referring to FIG. 9, the supporting film 3 may further include a protective film 35 and a release film 36. For example, the protective film 35 is disposed on a side of the first supporting portion 311 away from the first adhesive portion 312, and the protective film 35 is attached to the first supporting portion 311 and the second supporting portion 321. In addition, the protective film 35 covers the first supporting portion 311, the groove 3G and the second supporting film 321 to protect the first supporting portion 311 and the second supporting film 321. The release film 36 is disposed on a side of the first adhesive portion 312 away from the first supporting portion 311, and the release film 36 is attached to the first adhesive portion 312 and the second adhesive portion 322. In addition, the release film 36 covers the first adhesive portion 312, the groove 3G and the second adhesive portion 322 to protect the first adhesive portion 312 and the second adhesive portion 322.

It should be noted that when attaching the supporting film 3 to the display panel 1, the protective film 35 and the release film 36 need to be torn off.

TABLE 1
Examples of material properties of various parts of the supporting film

| | First | First | Second | Second |
|---|---|---|---|---|
| | supporting | adhesive | supporting | adhesive |
| | portion | portion | portion | portion |
| Elastic Modulus | 100~400 Gpa | 1~150 Kpa | 2~5 Gpa | 150~300 Kpa |
| Light | Regardless | — | above 85% | — |
| transmittance | | | | |
| (for example, | | | | |
| for light with a | | | | |
| wavelength of | | | | |
| about 550 nm) | | | | |
| Haze | Regardless | — | below 15% | — |
| Breaking | below 5% | | above 40% | |
| elongation | | | | |
| Breaking strength | 1400 Mpa | | 100 Mpa- | |
| | and above | | 200 Mpa | |
| 100K R3 dynamic | OK | | OK | |
| bending | | | | |

TABLE 2
Examples of material properties and thicknesses
of various parts of the supporting film

| | First | | First | | Second | | Second | |
|---|---|---|---|---|---|---|---|---|
| | supporting | | adhesive | | supporting | | adhesive | |
| | portion | | portion | | portion | | portion | |
| Elastic Modulus | 100~400 | Gpa | 1~150 | Kpa | 2~5 | Gpa | 150~300 | Kpa |
| thickness | 10~30 | μm | 40~100 | μm | 40~100 | μm | 10-30 | μm |
| Example 1 | 15 | μm | 40 | μm | 40 | μm | 15 | μm |
| Example 2 | 20 | μm | 50 | μm | 50 | μm | 20 | μm |
| Example 3 | 25 | μm | 60 | μm | 70 | μm | 15 | μm |

Referring to FIGS. 3 and 4 in combination, the display panel 1 may include the base substrate 11, the driving layer 12, the organic light emitting element layer 13, the encapsulation layer 14, the polarizer 15 and the cover plate CG.

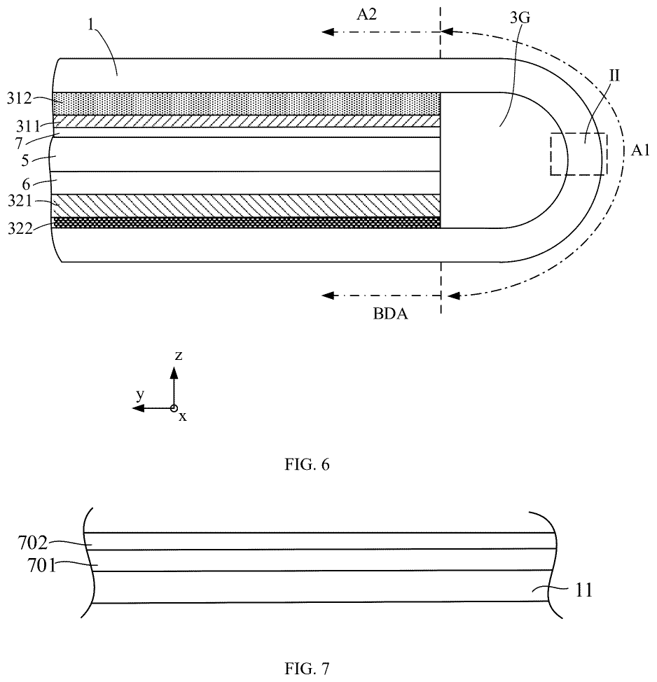

The driving layer 12 may include elements for providing signals to the organic light emitting element layer 13. The driving layer 12 may include various signal lines, for example, a scan line, a data line, a power line, and an emission line. The driving layer 12 may include a plurality of transistors and a plurality of capacitors. A transistor may include a switching transistor and a driving transistor Qd (referring to FIG. 5). Each pixel of the display panel 1 may include a corresponding switching transistor and a corresponding driving transistor Qd.

FIG. 5 is a cross-sectional view of a pixel structure of a display panel of a display device according to some exemplary embodiments of the present disclosure.

Exemplarily, FIG. 5 illustrates the driving transistor Qd of the driving layer 12. The driving transistor Qd includes an active layer 121, a gate electrode 123, a source electrode 125 and a drain electrode 127.

The active layer 121 may be disposed on the base substrate 11. The driving layer 12 may further include a first insulating layer 122 between the active layer 121 and the gate electrode 123. The first insulating layer 122 may insulate the active layer 121 and the gate electrode 123 from each other. The driving layer 12 may further include a gate insulating layer 124 and a second insulating layer 126. The gate insulating layer 124 is disposed between the gate electrode 123 and the source electrode 125 and between the gate electrode 123 and the drain electrode 127. The second insulating layer 126 is disposed on a side of the gate insulating layer 124 away from the base substrate 11. The source electrode 125 and the drain electrode 127 may be electrically connected to the active layer 121 via contact holes CH1 and CH2 formed in the first insulating layer 122, the gate insulating layer 124 and the second insulating layer 126, respectively.

The driving layer 12 may further include a passivation film 128 that is disposed on the source electrode 125 and the drain electrode 127.

Although not specifically shown in FIG. 5, the switching transistor may have substantially the same or the like structure as the driving transistor Qd, but the exemplary embodiments are not limited thereto. That is, alternatively, the switching transistor and the driving transistor Qd may have different structures. For example, an active layer of the switching transistor and the active layer 121 of the driving transistor Qd may be located in different layers.

In some exemplary embodiments, the driving layer 12 may be disposed not only in the display area DA, but also in the non-display area NDA. For example, the driving layer 12 may further include a plurality of wirings electrically connected to the driving integrated circuit (IC), and the plurality of wirings may be located in the non-display area NDA.

It should be understood that the driving layer 12 may further include a capacitor Cst. Referring to FIG. 5, the capacitor Cst includes a first electrode plate C1 and a second electrode plate C2 that are disposed oppositely and at intervals. For example, the first electrode plate C1 and the gate electrode 123 may be located on the same layer, and the second electrode plate C2 may be located on a side of the gate insulating layer 124 away from the base substrate 11. For example, both the first electrode plate C1 and the second electrode plate C2 may be made of the same material as the gate electrode 123.

The organic light emitting element layer 13 may include an organic light emitting element as an emission element. The organic light emitting element may be a top emission-type, and the organic light emitting element may emit light in an upward direction, that is, in the z-axis direction.

Referring to FIG. 5, the organic light emitting element may include a first electrode 131, an organic layer 132 and a second electrode 133.

The first electrode 131 is disposed on the passivation film 128. The first electrode 131 is electrically connected to the drain electrode 127 via a contact hole CH3 formed in the passivation film 128. The first electrode 131 may be a pixel electrode or an anode.

The organic layer 132 may include an organic emission layer formed of a low-molecular organic material or a polymer organic material. The organic emission layer may emit light based on a voltage difference between the first electrode 131 and the second electrode 133. Although not shown, the organic layer 132 may further include at least one of a hole transportation layer (HTL), a hole injection layer (HIL), an electron transportation layer (ETL) and an electron injection layer (EIL). Therefore, holes from the first electrode 131 and n electrons from the second electrode 133 may be injected into the organic layer 132. In the organic emission layer, the holes and the electrons may be combined to generate an exciton, and as the exciton transits from an excited state to a ground state, light may be emitted.

The second electrode 133 may be disposed on the organic layer 132. The second electrode 133 may be a common electrode or a cathode.

The organic light emitting element layer 13 may further include a pixel defining layer PDL disposed on the passivation film 128.

In the exemplary embodiments of the present disclosure, the organic light emitting element layer 13 may be disposed only in the display area DA of the display panel 1 and not in the non-display area NDA.

The encapsulation layer 14 may be disposed on the organic light emitting element layer 13. The encapsulation layer 14 may protect the organic light emitting element layer 13 from external moisture and air.

In some exemplary embodiments, the encapsulation layer 14 may be formed as a thin film encapsulation layer, and the encapsulation layer 14 may include at least one organic film and at least one inorganic film. For example, the encapsulation layer 14 may include a first inorganic film 141 on the second electrode 133, an organic film 145 on the first inorganic film 141 and a second inorganic film 143 on the organic film 145. In this case, the encapsulation layer may effectively prevent moisture and air from permeating into an inside of the display panel 1 from an outside of the display panel 1.

As an example, the encapsulation layer 14 may not completely cover the non-display area NDA of the display panel 1. For example, the encapsulation layer 14 may be disposed in the bendable area A2, but not in the folding area A1 and the bonding area BDA.

Referring to FIGS. 3 to 5, the polarizer 15 is disposed on a side of the encapsulation layer 14 away from the base substrate 11 to polarize light emitted by the organic light emitting element. It should be understood that the display panel according to the embodiments of the present disclosure may further include other types of optical film layers and is not limited to the polarizer.

As an example, the polarizer 15 may be disposed only in the display area DA of the display panel 1 and not in the non-display area NDA.

The cover plate CG is attached to the polarizer 15 via an optically clear adhesive layer. For example, the cover plate CG may cover an entire upper surface of the display panel 1, that is, the cover plate covers the display area DA and the non-display area NDA of the display panel 1.

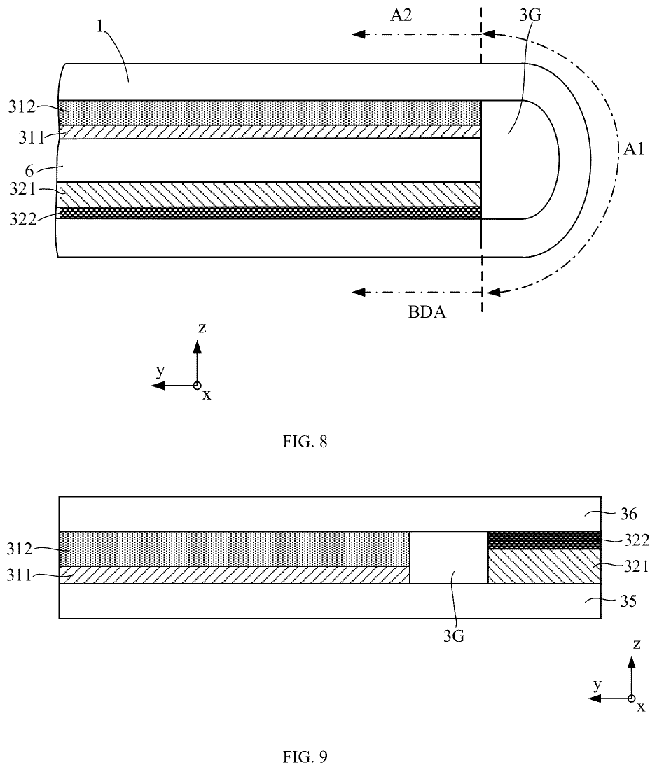

FIG. 6 is a cross-sectional view of a display device in a state where a non-display area is folded around an axis in a folding area according to some exemplary embodiments of the present disclosure.

Referring to FIG. 6, the display panel 1 may be bent or folded in a downward direction along the bending axis BX1 (see FIG. 1) extending in the first direction x in the folding area A1. Since the groove 3G overlapping with the folding area A1 is defined in the supporting film 3, the display panel 1 may be easily bent.

Since a part of the non-display area NDA of the display panel 1 is bent or folded to the back surface of the display panel 1, the non-display area NDA of the display device 100 as viewed from outside may be reduced, so that the bezel width of the display device 100 may be reduced.

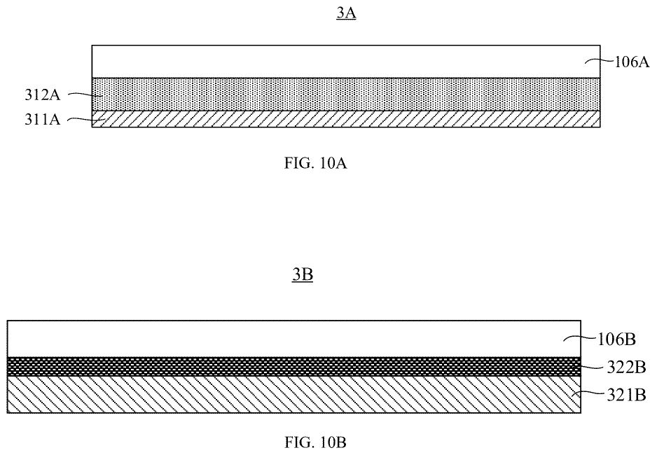

FIG. 7 is a partial enlarged view at part II of FIG. 6 of a display device according to some exemplary embodiments of the present disclosure. Referring to FIGS. 6 and 7 in combination, in the folding area A1, the display device 100 may include a wiring layer 701 and a protective layer 702. Wiring in the wiring layer 701 may electrically connect a circuit in the display area DA with the driving integrated circuit, and the protective layer 702 may protect the wiring.

Referring back to FIG. 6, the first film portion 31 of the supporting film 3 is disposed under the display panel 1 to support the display panel 1. For example, the first adhesive portion 312 of the first film portion 31 is disposed between the first supporting portion 311 and the display panel 1 to attach the first supporting portion 311 to the display panel 1. The second film portion 32 of the supporting film 3 is folded to the back surface of the display panel 1. In this way, in the folded state of FIG. 6, the second supporting portion 321 is closer to the bendable area A2 of the display panel 1 than the second adhesive portion 322, that is, that is, the second supporting portion 321 is on the second adhesive portion 322.

The display device 100 may include a supporting member 5, for example, the supporting member 5 may be a metal supporting member. The supporting member 5 is sandwiched between the first film portion 31 and the second film portion 32 of the supporting film 3 to support the flexible display panel 1.

Specifically, the display device 100 may further include a third adhesive portion 6, for example, the third adhesive portion 6 may be double-sided tape, foam tape, or the like. The third adhesive portion 6 is disposed between the second supporting portion 321 and the supporting member 5 to attach the supporting member 5 and the second supporting portion 321. An upper surface of the third adhesive portion 6 directly contacts a lower surface of the supporting member 5, and a lower surface of the third adhesive portion 6 directly contacts an upper surface of the second supporting portion 321.

The display device 100 may further include a fourth adhesive portion 7, for example, the fourth adhesive portion 7 may include an optical adhesive. The fourth adhesive portion 7 is disposed between the first supporting portion 311 and the supporting member 5 to attach the supporting member 5 and the first supporting portion 311. An upper surface of the fourth adhesive portion 7 directly contacts a lower surface of the first supporting portion 311, and a lower surface of the fourth adhesive portion 7 directly contacts an upper surface of the supporting member 5.

By providing the supporting member with higher strength and elastic modulus, it may be ensured that the display device has good resilience performance after being bent during use, and creases may be reduced or even avoided.

In the embodiments of the present disclosure, the first supporting portion 311 is made of a material with high elastic modulus such as nickel-iron alloy, copper-zinc alloy, nickel-titanium alloy, that is, the first supporting portion 311 itself has high strength and high elastic modulus. In this way, a thickness of the supporting member 5 may be reduced or, only a single-layer supporting member is needed to achieve purposes of improving resilience performance and reducing creases.

Since the thickness of the supporting member is reduced, a folding radius in the folding area A1 is reduced in the folded state shown in FIG. 6. In this way, the bezel width of the display device 100 may be further reduced.

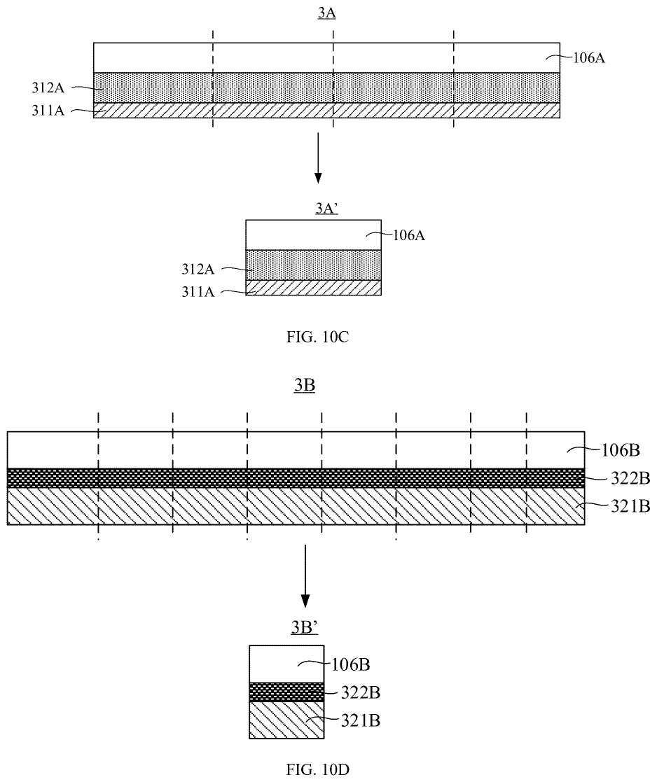

FIG. 8 is a cross-sectional view of a display device in a state where a non-display area is folded around an axis in a folding area according to some other exemplary embodiments of the present disclosure. Referring to FIGS. 6 and 8 in combination, in the embodiment of FIG. 8, the supporting member 5 is eliminated, that is, the first supporting portion 311 and the second supporting portion 321 of the supporting film 3 are directly attached to each other.

Specifically, the display device 100 may include a third adhesive portion 6, for example, the third adhesive portion 6 may be double-sided tape, foam tape, or the like. The third adhesive portion 6 is disposed between the second supporting portion 321 and the first supporting portion 311 to attach the second supporting portion 321 and the first supporting portion 311. An upper surface of the third adhesive portion 6 directly contacts a lower surface of the first supporting portion 311, and a lower surface of the third adhesive portion 6 directly contacts an upper surface of the second supporting portion 321, that is, no supporting member is provided between the first supporting portion 311 and the second supporting portion 321.

In the embodiments of the present disclosure, the first supporting portion 311 is made of a material with high elastic modulus such as nickel-iron alloy, copper-zinc alloy, nickel-titanium alloy, that is, the first supporting portion 311 itself has high strength and high elastic modulus. In this way, through the first supporting portion itself, purposes of improving resilience performance and reducing creases may be achieved, so that additional supporting members may be omitted.

Since the supporting member is omitted, in the folded state shown in FIG. 8, the folding radius in the folding area A1 is further reduced, so that the bezel width of the display device 100 may be further reduced.

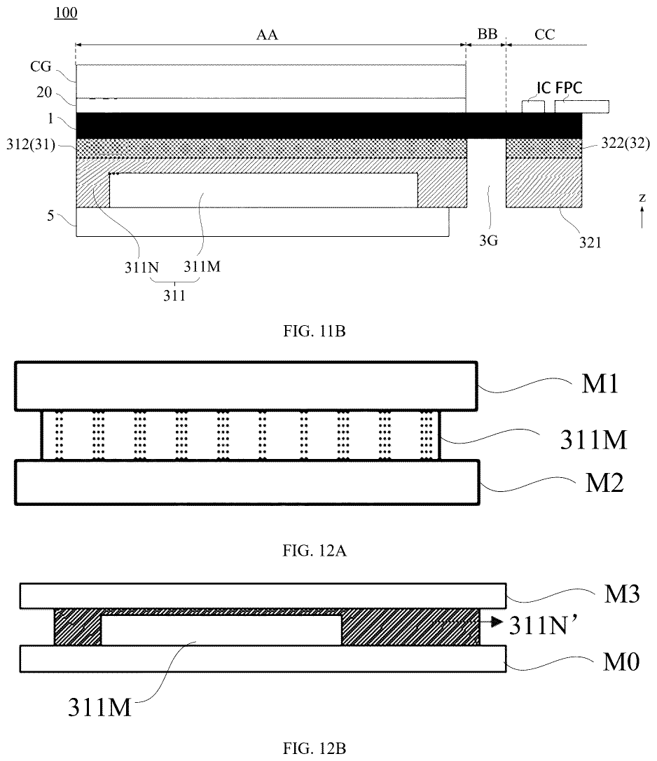

FIGS. 10A to 10F respectively illustrate cross-sectional views of a supporting film after some steps of a manufacturing method of a supporting film are performed according to some exemplary embodiments of the present disclosure. The manufacturing method of the supporting film according to some exemplary embodiments of the present disclosure may be performed according to following steps.

Referring to FIGS. 10A and 10B, a first supporting film master-sheet 3A and a second supporting film master-sheet 3B are respectively formed. For example, the first supporting film master-sheet 3A may include a release film 106A, a first adhesive portion 312A and a first supporting portion 311A that are sequentially stacked. The second supporting film master-sheet 3B may include a release film 106B, a second adhesive portion 322B and a second supporting portion 321B that are sequentially stacked. It should be noted that sizes of the first supporting film master-sheet 3A and the second supporting film master-sheet 3B are relatively large, and they may be made into a plurality of supporting films as shown in FIG. 9.

It should be understood that a material and a thickness of the release film, the supporting portion and the adhesive portion may be referred to the above description, and will not be repeated here.

Referring to FIGS. 10C and 10D, the first supporting film master-sheet 3A and the second supporting film master-sheet 3B are cut, respectively. For example, the first supporting film master-sheet 3A and the second supporting film master-sheet 3B are cut along dashed lines in FIG. 10C and FIG. 10D to form a plurality of small-sized first supporting film sub-sheets 3A′ and a plurality of small-sized second supporting film sub-sheets 3B′.

Referring to FIG. 10E, a release film on the first supporting film sub-sheet 3A′ and a release film on the second supporting film sub-sheet 3B′ are respectively torn off, and the first supporting film sub-sheet 3A′ and the second supporting film sub-sheet 3B′ without the release films are attached to the same release film 106B and the same protective film 105A at predetermined intervals.

Referring to FIG. 10F, the structure shown in FIG. 10E is cut according to a predetermined size, for example, cut according to dashed lines in FIG. 10F to form the supporting film 3 shown in FIG. 9.

Through such the manufacturing method, a supporting film with zone-design may be formed.

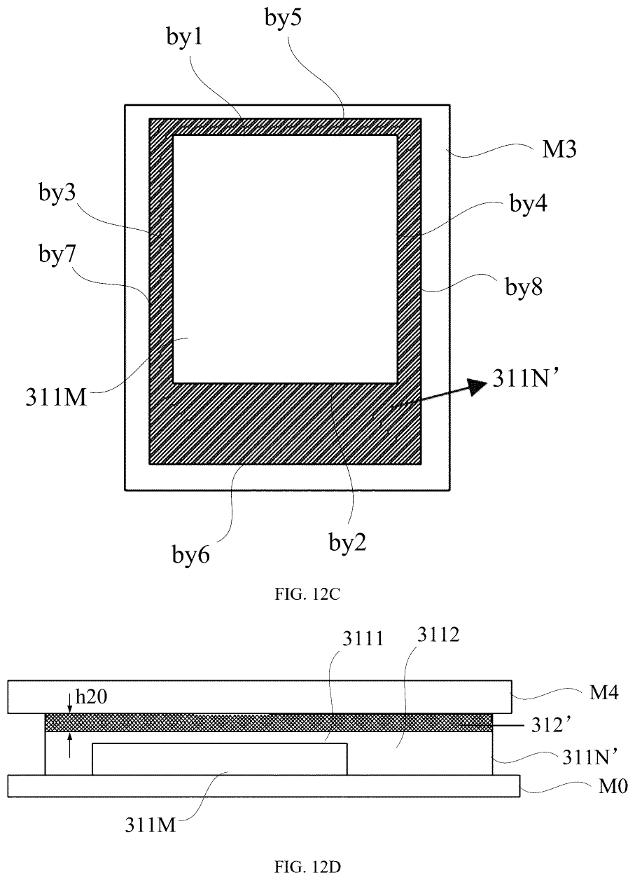

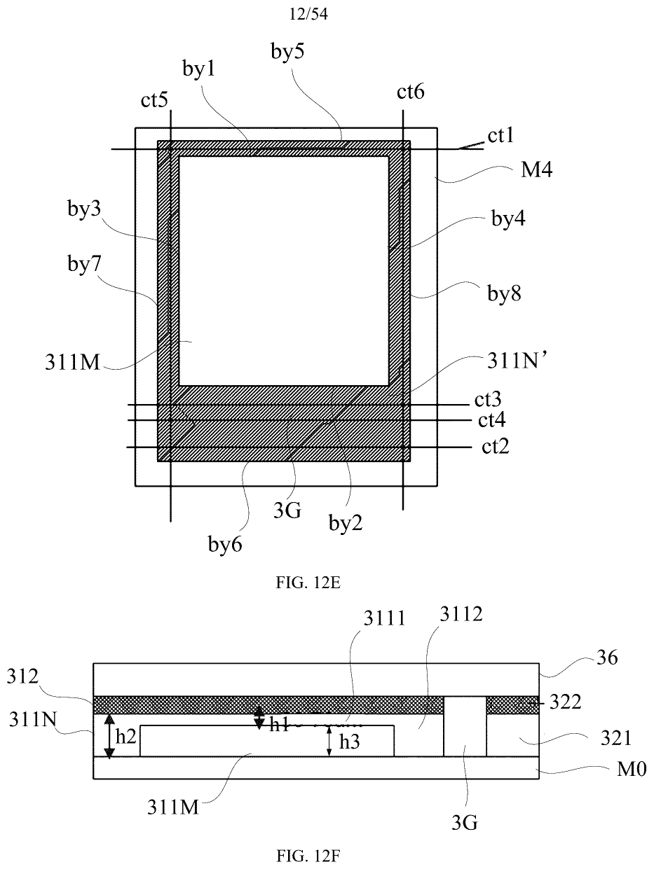

FIG. 11A is a cross-sectional view of a supporting film according to some other exemplary embodiments of the present disclosure.

The supporting film in FIG. 11A is similar to the supporting film in FIG. 9, with the distinguishing part with respect to FIG. 9 being at least the first adhesive portion 312 and the second adhesive portion 322. For the sake of simplicity, the distinguishing part will be mainly described in detail below.

Referring to FIG. 11A, similar to FIG. 9, the supporting film also includes the first supporting portion 311, the second supporting portion 321, the first adhesive portion 312 and the second adhesive portion 322. In addition, the supporting film may further include the protective film 35 and the release film 36. The distinguishing part with respect to FIG. 9 is that the thickness of the first adhesive portion 312 is substantially equal to the thickness of the second adhesive portion 322.

In some embodiments of the present disclosure, the thickness of the first adhesive portion 312 and the thickness of the second adhesive portion 322 are within a range of 20-30 μm, for example, the thickness of the first adhesive portion 312 and the thickness of the second adhesive portion 322 may be 25 μm, respectively. The thickness of the first supporting portion 311 is within a range of 15-25 μm, for example, the thickness of the first supporting portion may be 20 μm. The thickness of the second supporting portion is within a range of 45-55 μm, for example, the thickness of the second supporting portion 321 may be 50 μm.

Referring to FIG. 11A, the supporting film further includes another protective film 37 located on a side of the first supporting portion 311 away from the first adhesive portion 312. As shown in FIG. 11A, the protective film 37 is located between the protective film 35 and the first supporting portion 311, and an orthographic projection of the protective film 37 on the display panel 1 overlaps at least partially with an orthographic projection of the first supporting portion 311 on the display panel 1.

Referring to FIG. 11A, a sum of the thickness of the first adhesive portion 312, the thickness of the first supporting portion 311 and a thickness of the protective film 37 is equal to a sum of the thickness of the second adhesive portion 322 and the thickness of the second supporting portion 321.

In some embodiments of the present disclosure, when attaching the supporting film to the display panel, the protective film 35 and the release film 36 may be removed, while the protective film 37 may be kept. In this way, since the sum of the thickness of the first adhesive portion 312, the thickness of the first supporting portion 311 and the thickness of the protective film 37 is equal to the sum of the thickness of the second adhesive portion 322 and the thickness of the second supporting portion 321, a surface of the protective film 30 on a side away from the first supporting portion 311 is flush with a surface of the second supporting portion 321 away from the second adhesive portion 322.

In some other embodiments of the present disclosure, when attaching the supporting film to the display panel, the protective film 37 may be removed together with the protective film 35 and the release film 36.

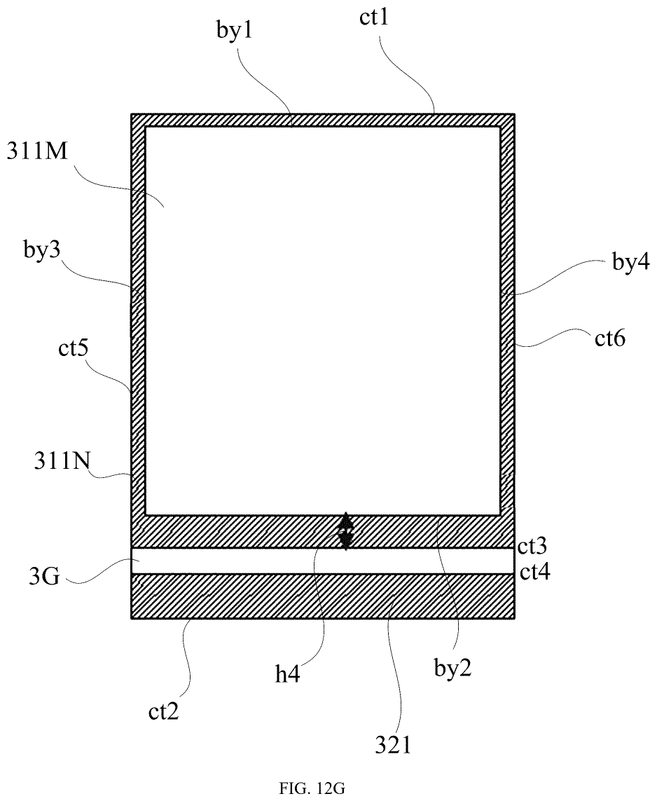

FIG. 11B is a schematic diagram of a display device before bending according to some exemplary embodiments of the present disclosure. FIGS. 12A to 12G respectively illustrate schematic diagrams of a supporting film after some steps of a manufacturing method of the supporting film are performed according to some exemplary embodiments of the present disclosure.

Referring to FIG. 11B, a display device 100 may include a display panel 1 and a supporting film. The supporting film may include a first film portion 31 and a second film portion 32, and the first film portion 31 and the second film portion 32 are separated by a groove 3G. The display panel 1 has a display area AA, a folding area BB, and a bonding area CC. The folding area BB is located between the display area AA and the bonding area CC. An orthographic projection of the first film portion 31 on the display panel 1 may at least partially overlap with the display area AA of the display panel 1. An orthographic projection of the second film portion 32 on the display panel 1 may at least partially overlap with the bonding area CC of the display panel 1.

Exemplarily, the first film portion 31 includes a first supporting portion 311 and a first adhesive portion 312. The first adhesive portion 312 is located within the display area AA, and the first supporting portion 311 is attached to the first adhesive portion 312. The first supporting portion 311 is attached to a back surface of the display panel 1 through the first adhesive portion 312 to support the display panel 1. The first supporting portion 311 may include a first supporting sub-portion 311M and a second supporting sub-portion 311N. The second supporting sub-portion 311N is disposed on a side of the first supporting sub-portion 311M close to the first adhesive portion 312, and covers a surface of the first supporting sub-portion 311M close to the first adhesive portion 312 and a side surface of the first supporting sub-portion 311M. Exemplarily, the first supporting sub-portion 311M is recessed inward with respect to the first adhesive portion 312.

In some embodiments of the present disclosure, the first supporting sub-portion 311M may be made of a material with high elastic modulus (for example, ultra-thin glass or stainless steel). Exemplarily, the first supporting sub-portion 311M may be ultra-thin glass. Any side edge of the first supporting sub-portion 311M is recessed inward by a first distance relative to a corresponding side edge of the first adhesive portion 312. It may be understood that the first supporting sub-portion 311M needs to undergo strengthening treatment to achieve bendability, and cannot be cut after the strengthening treatment. Therefore, when cutting a supporting film master-sheet to form individual supporting film sub-sheets, cutting may be performed in a region of the first adhesive portion 312 that does not overlap with the first supporting sub-portion 311M, thereby avoiding cutting the first supporting sub-portion 311M and preventing the first supporting sub-portion 311M from fracturing during the cutting process.

In some embodiments of the present disclosure, in a light emitting direction (i.e., Z direction) of the display panel 1, a thickness h3 (referring to FIG. 12F) of the first supporting sub-portion 311M may be in a range of 10 μm to 200 μm, preferably in a range of 30 μm to 100 μm, and more preferably in a range of 30 μm to 70 μm. An elastic modulus of the first supporting sub-portion 311M may be in a range of 50 GPa to 150 GPa, preferably in a range of 70 GPa to 120 GPa. The first supporting sub-portion 311M may withstand a 100,000-cycle dynamic bending test with a bending radius of 1 mm (i.e., 100k R1 dynamic bending OK). A breaking elongation of the first supporting sub-portion 311M may be in a range of 5% to 40%, preferably in a range of 5% to 30%. A moisture absorption rate of the first supporting sub-portion 311M may be less than 2%, preferably less than 1%. A compressive stress (CS) of the first supporting sub-portion 311M may be greater than 450 MPa. An ion exchange layer depth (DOL) of the first supporting sub-portion 311M may be greater than 5 μm.

Exemplarily, referring to FIG. 11B, the second supporting sub-portion 311N is located in the display area AA. The second supporting sub-portion 311N may cover the surface of the first supporting sub-portion 311M on a side close to the first adhesive portion 312 and the side surface of the first supporting sub-portion 311M. That is, the second supporting sub-portion 311N may fill a segment step formed due to the inward recession of the first supporting sub-portion 311M, thereby improving the strength of the display device 100.

Exemplarily, the second film portion 32 includes a second supporting portion 321 and a second adhesive portion 322. The second adhesive portion 322 is located in the bonding area CC, and the second supporting portion 321 is attached to the second adhesive portion 322. The second supporting portion 321 is attached to the back surface of the display panel 1 through the second adhesive portion 322 to support the display panel 1. A material of the second adhesive portion 322 may be the same as a material of the first adhesive portion 312. For example, both the second adhesive portion 322 and the first adhesive portion 312 may be pressure-sensitive adhesives. The second adhesive portion 322 and the first adhesive portion 312 may also be manufactured by the same process step.

Exemplarily, the material of the second supporting portion 321 may be the same as the material of the second supporting sub-portion 311N. For example, the materials of both the second supporting portion 321 and the second supporting sub-portion 311N may be polymer materials (such as at least one of polyethylene terephthalate, polyimide, polyurethane, polymethyl methacrylate, silicone, acrylate, polyurethane acrylate, or epoxy resin). The second supporting portion 321 and the second supporting sub-portion 311N may be manufactured by the same process step. For example, both the second supporting portion 321 and the second supporting sub-portion 311N are formed by liquid coating followed by curing. It may be understood that since the second supporting portion 321 and the second supporting sub-portion 311N may be manufactured by the same process step, there is no need to attach other film materials on a side of the second adhesive portion 322 away from the display panel 1, thereby reducing process difficulty.

Exemplarily, the elastic modulus of the second supporting portion 321 and the second supporting sub-portion 311N may be in a range of 10 MPa to 10 GPa, preferably in a range of 30 MPa to 3 GPa. The breaking elongation of the second supporting portion 321 and the second supporting sub-portion 311N may be greater than 10%. The light transmittance of the second supporting portion 321 and the second supporting sub-portion 311N may be greater than or equal to 80%. The haze of the second supporting portion 321 and the second supporting sub-portion 311N may be less than or equal to 5%. In this way, the optical performance of the supporting film in the bonding area CC (referring to FIG. 11B) may be improved, for example, the light transmittance is increased. Therefore, the bonding area CC may be clearly observed, which is beneficial to capture a bonding mark and observe a crease.

Exemplarily, referring to FIG. 11B, the display device 100 may further include a supporting member 5, a cover plate CG, a driver integrated chip IC and an FPC. The supporting member 5 may be located on a side of the first supporting portion 311 away from the first adhesive portion 312. The supporting member 5 may include a metal material (for example, stainless steel). By providing the supporting member 5 with higher strength and elastic modulus, it may be ensured that the display device 100 has good resilience performance after being bent during use, and creases may be reduced or even avoided. The cover plate CG may be attached to a side of the display panel 1 away from the first adhesive portion 312 through an optically clear adhesive layer 20. That is, the optically clear adhesive layer 20 may be disposed on a side of the display panel 1 away from the first adhesive portion 312, and the cover plate CG may be disposed on a side of the optically clear adhesive layer 20 away from the display panel 1. The material of the cover plate CG may be ultra-thin glass.

It may be understood that, since the first supporting portion 311 and the second supporting portion 321 are formed using ultra-thin glass together with polymer materials, the application of polymer materials in the display device 100 may be reduced. Since ultra-thin glass exhibits minimal deformation and excellent resilience during bending, by combining ultra-thin glass with high-rigidity materials such as the cover plate CG and the supporting member 5, creases in the display area AA (referring to FIG. 11B) of the display panel 1 may be effectively reduced, and overall flatness of the display device 100 may be improved.

Exemplarily, the manufacturing process of the supporting film may refer to FIGS. 12A to 12G. First, referring to FIG. 12A, the first supporting sub-portion 311M is provided as a sheet material meeting the above performance requirements, and protective films are disposed on two sides of the first supporting sub-portion 311M. For example, a first protective film M1 is disposed on an upper side of the first supporting sub-portion 311M, and a second protective film M2 is disposed on a lower side of the first supporting sub-portion 311M.

Referring to FIG. 12B, based on the component shown in FIG. 12A, the first protective film M1 is removed, and a carrier film M0 is attached to a side of the first supporting sub-portion 311M away from the second protective film M2. Then, the second protective film M2 is removed, and a polymer material layer 311N′ is formed on a side of the first supporting sub-portion 311M away from the carrier film M0. A polymer material may be coated on the side of the first supporting sub-portion 311M away from the carrier film M0 by processes such as blade coating, slit coating, or dispensing, and then the polymer material is cured to form the polymer material layer 311N′. Then, a third protective film M3 is attached to a side of the polymer material layer 311N′ away from the carrier film M0.

Referring to FIG. 12C, an orthographic projection of the first supporting sub-portion 311M on the carrier film M0 falls within an orthographic projection of the polymer material layer 311N′ on the carrier film M0. Exemplarily, the orthographic projection of the first supporting sub-portion 311M on the carrier film M0 includes a first edge by1, a second edge by2, a third edge by3 and a fourth edge by4. The orthographic projection of the polymer material layer 311N′ on the carrier film M0 includes a fifth edge by5, a sixth edge by6, a seventh edge by7 and an eighth edge by8. The first edge by1 and the fifth edge by5 are disposed close to the same side (e.g., the upper side) of the carrier film M0; the second edge by2 and the sixth edge by6 are disposed on opposite sides of the first edge by1 and the fifth edge by5; the third edge by3 and the seventh edge by7 are disposed adjacent to the first edge by1 and the fifth edge by5 (e.g., disposed close to the left side of the carrier film M0); the fourth edge by4 and the eighth edge by8 are disposed on opposite sides of the third edge by3 and the seventh edge by7. A distance between the first edge by1 and the fifth edge by5, a distance between the third edge by3 and the seventh edge by7, and a distance between the fourth edge by4 and the eighth edge by8 may each be in a range of 200 μm to 500 μm. A distance between the second edge by2 and the sixth edge by6 may be in a range of 1 mm to 5 mm.

Exemplarily, referring to FIG. 12D, the polymer material layer 311N′ may include a first sub-portion 3111 and a second sub-portion 3112. An orthographic projection of the first sub-portion 3111 on the carrier film M0 coincides with the orthographic projection of the first supporting sub-portion 311M on the carrier film M0. A thickness h1 (referring to FIG. 12F) of the first sub-portion 3111 may be in a range of 20 μm to 100 μm, preferably in a range of 30 μm to 70 μm. An orthographic projection of the second sub-portion 3112 on the carrier film M0 does not overlap with the orthographic projection of the first supporting sub-portion 311M on the carrier film M0. A thickness h2 (referring to FIG. 12F) of the second sub-portion 3112 may be greater than 50 μm. The thickness h2 of the second sub-portion 3112 may be equal to a sum of the thickness h1 of the first sub-portion 3111 and the thickness h3 (referring to FIG. 12F) of the first supporting sub-portion 311M.

Referring to FIG. 12D, based on the component shown in FIG. 12B, the third protective film M3 is removed, and an adhesive material layer 312′ is formed on a side of the polymer material layer 311N′ away from the carrier film M0, where a thickness h20 of the adhesive material layer 312′ may be in a range of 10 μm to 30 μm. The adhesive material layer 312′ may be directly attached to the side of the polymer material layer 311N′ away from the carrier film M0, or the adhesive material layer 312′ may be formed by applying adhesive on the side of the polymer material layer 311N′ away from the carrier film M0. The adhesive material layer 312′ may be an acrylic adhesive, and the elastic modulus of the adhesive material layer 312′ may be less than 150 kPa. Then, a fourth protective film M4 is attached to a side of the adhesive material layer 312′ away from the carrier film M0.

Referring to FIG. 12E, based on the component shown in FIG. 12D, an outer shape of the supporting film and the groove 3G located on the supporting film are formed using a laser cutting process. Exemplarily, the cutting process may include a first cutting line ct1, a second cutting line ct2, a third cutting line ct3, a fourth cutting line ct4, a fifth cutting line ct5 and a sixth cutting line ct6. With reference to FIGS. 12C and 12E, the first cutting line ct1, the second cutting line ct2, the third cutting line ct3 and the fourth cutting line ct4 may be disposed parallel to the first edge by1; the fifth cutting line ct5 and the sixth cutting line ct6 may be disposed parallel to the third edge by3; the first cutting line ct1 may be located between the first edge by1 and the fifth edge by5; the second cutting line ct2 may be located between the second edge by2 and the sixth edge by6; the third cutting line ct3 and the fourth cutting line ct4 may be located between the second cutting line ct2 and the second edge by2, and a region between the third cutting line ct3 and the fourth cutting line ct4 is the region where the groove 3G is located; the fifth cutting line ct5 may be located between the third edge by3 and the seventh edge by7; the sixth cutting line ct6 may be located between the fourth edge by4 and the eighth edge by8.

It may be understood that since the precision of the supporting film is determined solely by the laser cutting and is independent of the preceding coating and attaching processes, the supporting film formed using the above process flow has extremely high precision. The precision of the groove 3G (i.e., a deviation between an actual groove position and a target groove position) may be less than or equal to 50 μm.

Referring to FIGS. 12F and 12G, based on the component shown in FIG. 12D, after the cutting is completed, the fourth protective film M4 is removed, and then a release film 36 is attached to a side of the first adhesive portion 312 and the second adhesive portion 322 away from the carrier film M0. It may be understood that after the cutting is completed, the first adhesive portion 312 and the second adhesive portion 322 spaced apart from each other are formed in the adhesive material layer 312′, and the second supporting sub-portion 311N and the second supporting portion 321 spaced apart from each other are formed in the polymer material layer 311N′. The release film 36 covers the first adhesive portion 312, the groove 3G and the second adhesive portion 322 to protect the first adhesive portion 312 and the second adhesive portion 322. The carrier film M0 covers the first supporting portion 311, the groove 3G and the second supporting portion 321 to protect the first supporting portion 311 and the second supporting portion 321.

Exemplarily, with reference to FIGS. 12C, 12E and 12G, the first cutting line ct1, the second cutting line ct2, the fifth cutting line ct5 and the sixth cutting line ct6 correspond to edges of the polymer material layer 311N′. The third cutting line ct3 and the fourth cutting line ct4 correspond to edges of the groove 3G. The third cutting line ct3 may be located between the fourth cutting line ct4 and the second edge by2. A distance between the first cutting line ct1 and the first edge by1, a distance between the fifth cutting line ct5 and the third edge by3, and a distance between the sixth cutting line ct6 and the fourth edge by4 may each be in a range of 100 μm to 300 μm. A distance h4 between the second edge by2 and the third cutting line ct3 may be in a range of 100 μm to 500 μm, preferably in a range of 200 μm to 300 μm.

Exemplarily, peel forces of the various protective films used in the above process flow need to satisfy: the carrier film M0>the second protective film M2>the first protective film M1, the carrier film M0>the third protective film M3, the carrier film M0>the fourth protective film M4, and the carrier film M0>the release film 36. The peel force of the carrier film M0 may be in a range of 30~50 gram-force per inch (gf/inch).

It should be noted that when attaching the supporting film to the display panel 1, the carrier film M0 and the release film 36 need to be torn off.

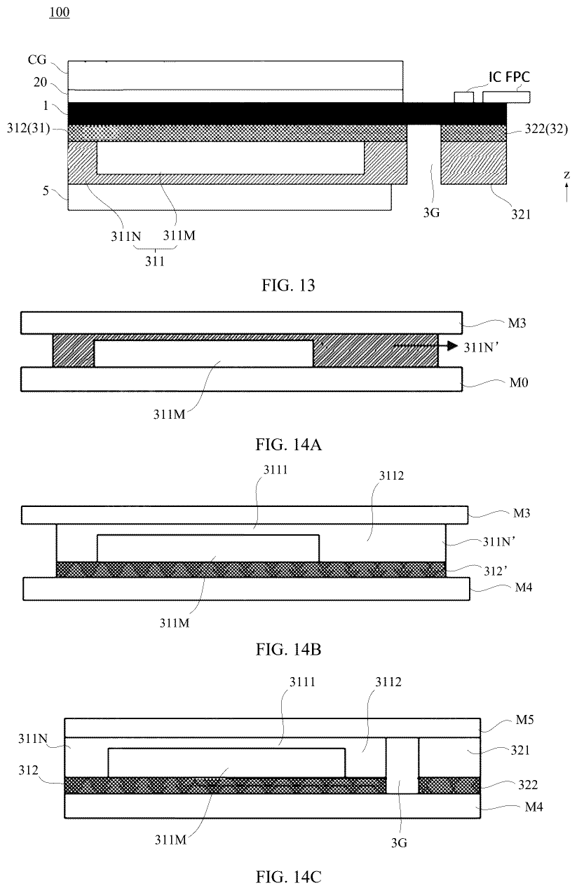

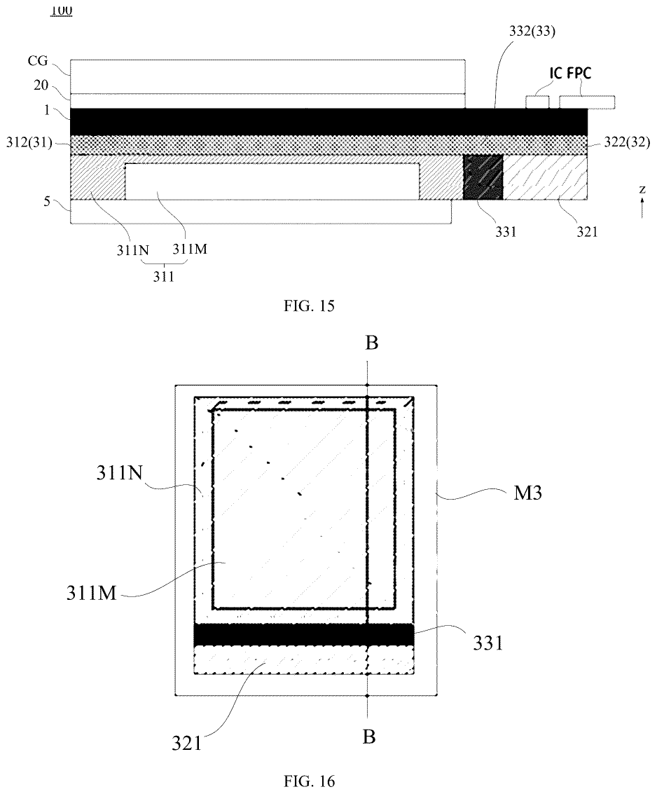

FIG. 13 is a schematic diagram of a display device before bending according to some exemplary embodiments of the present disclosure. FIGS. 14A to 14C respectively illustrate cross-sectional views of a supporting film after some steps of a manufacturing method of the supporting film are performed according to some exemplary embodiments of the present disclosure.

Referring to FIG. 13, in some embodiments of the present disclosure, the first supporting portion 311 may include a first supporting sub-portion 311M and a second supporting sub-portion 311N. The second supporting sub-portion 311N is disposed on a side of the first supporting sub-portion 311M away from the first adhesive portion 312, and covers a surface of the first supporting sub-portion 311M away from the first adhesive portion 312 and a side surface of the first supporting sub-portion 311M.

Exemplarily, the second supporting sub-portion 311N may cover the surface of the first supporting sub-portion 311M on a side away from the first adhesive portion 312 and the side surface of the first supporting sub-portion 311M. That is, the second supporting sub-portion 311N may fill the segment step formed due to the inward recession of the first supporting sub-portion 311M, thereby improving the strength of the display device 100.

Exemplarily, the manufacturing process of the supporting film may refer to FIGS. 14A to 14C. The manufacturing process of the components shown in FIG. 14A may refer to the relevant description of FIGS. 12A to 12B, which will not be repeated here. Referring to FIG. 14B, based on the component shown in FIG. 14A, the carrier film M0 may be removed first, then an adhesive material layer 312′ is formed on a side of the first supporting sub-portion 311M away from the polymer material layer 311N′, and a fourth protective film M4 is then attached to a side of the adhesive material layer 312′ away from the first supporting sub-portion 311M.

Referring to FIG. 14C, based on the components shown in FIG. 14B, the laser cutting process is performed. Specific cutting flow may refer to FIG. 12E and related description, which will not be repeated here. After the cutting is completed, the third protective film M3 is removed, and then a fifth protective film M5 is attached to a side of the first supporting portion 311 and the second supporting portion 321 away from the fourth protective film M4. It should be noted that when attaching the supporting film to the display panel 1, the fourth protective film M4 and the fifth protective film M5 need to be torn off.

It may be understood that, because the adhesive application surfaces are different, the adhesion selection for the protective films used in the manufacturing process is different. The peel forces of the various protective films should satisfy: the fifth protective film M5>the fourth protective film M4>the third protective film M3>the carrier film M0.

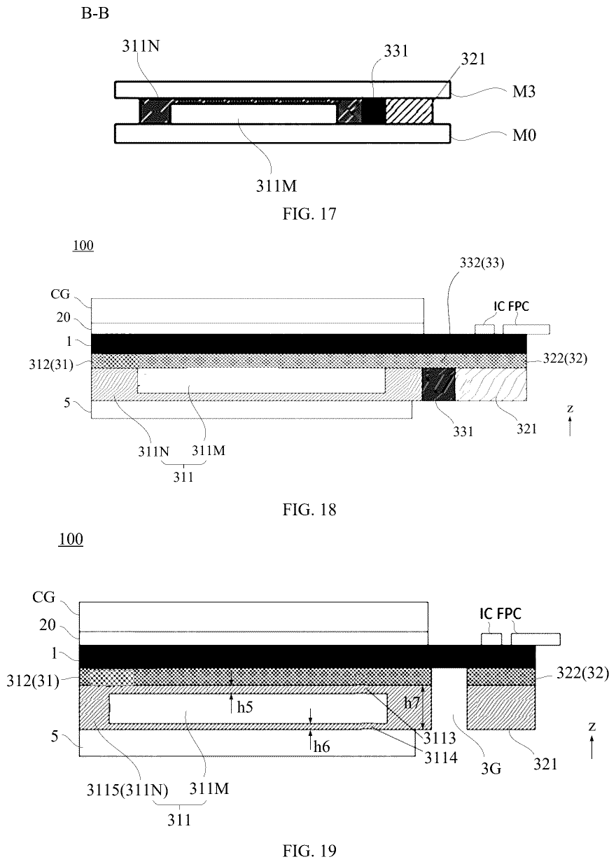

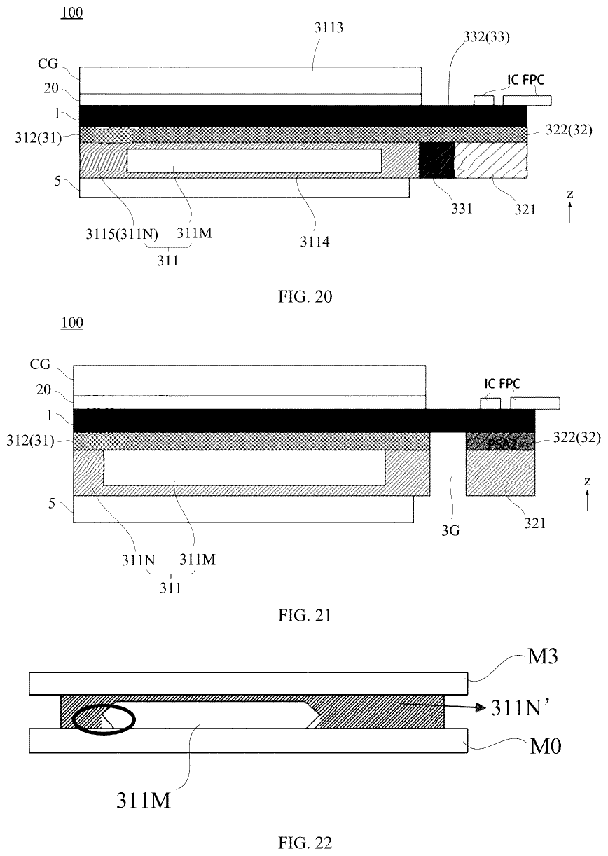

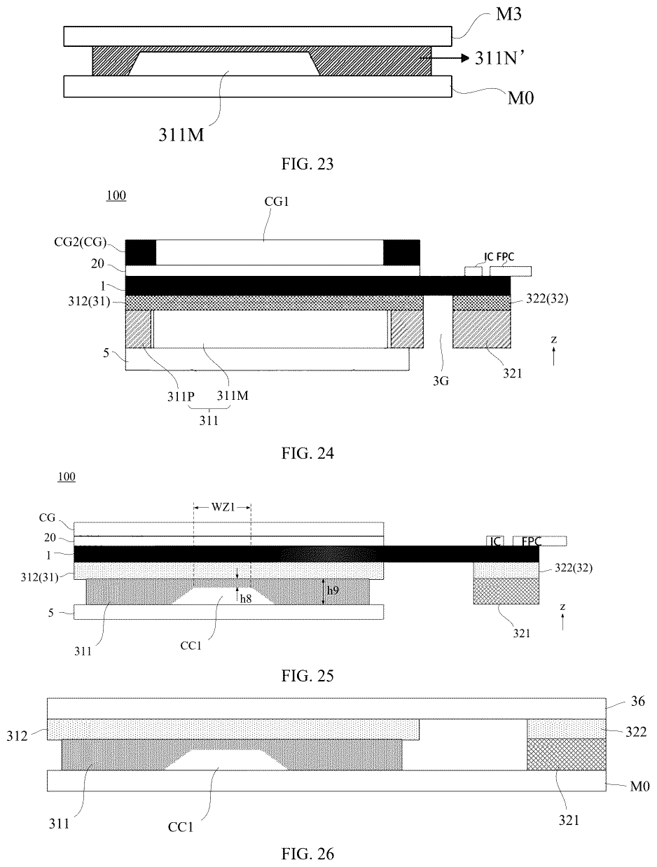

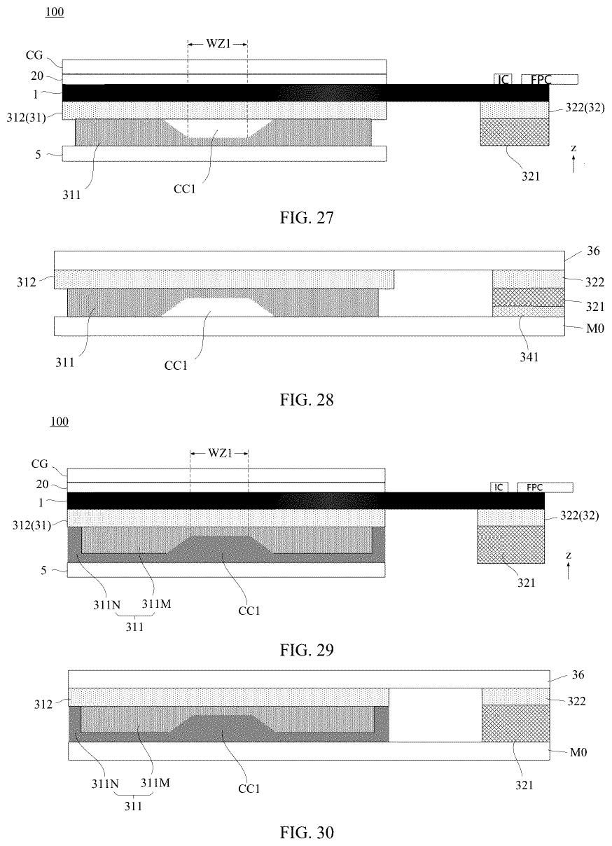

FIG. 15 is a schematic diagram of a display device before bending according to some exemplary embodiments of the present disclosure. FIG. 16 is a plan view of a supporting film according to some exemplary embodiments of the present disclosure. FIG. 17 is a cross-sectional view of a supporting film according to some exemplary embodiments of the present disclosure. For example, FIG. 17 is a cross-sectional view of the supporting film taken along line BB in FIG. 16. FIG. 18 is a schematic diagram of a display device before bending according to some exemplary embodiments of the present disclosure.

Referring to FIG. 11B and FIGS. 15 to 18, the supporting film may further include a third film portion 33, and the third film portion 33 may be located between the first film portion 31 and the second film portion 32. An orthographic projection of the third film portion 33 on the display panel 1 may at least partially overlap with the folding area BB of the display panel 1.

Exemplarily, the third film portion 33 includes a third supporting portion 331 and a third adhesive portion 332. The third supporting portion 331 is located in the folding area BB, and the third supporting portion 331 is disposed on a side of the third adhesive portion 332 away from the display panel 1, that is, the third supporting portion 331 is attached to the back surface of the display panel 1 through the third adhesive portion 332 to support the display panel 1. Two sides of the third supporting portion 331 in an extending direction thereof abut against the second supporting sub-portion 311N and the second supporting portion 321, respectively. The third adhesive portion 332, the second adhesive portion 322 and the first adhesive portion 312 may be made of the same material such as the pressure-sensitive adhesive. The third adhesive portion 332, the second adhesive portion 322 and the first adhesive portion 312 may be disposed continuously, that is, the third adhesive portion 332, the second adhesive portion 322 and the first adhesive portion 312 may be manufactured by the same process step, eliminating the need to form the groove 3G as shown in FIG. 11B.

In some embodiments, the second supporting sub-portion 311N and the second supporting portion 321 may have the same performance.

In some embodiments, the elastic modulus of the second supporting sub-portion 311N may be in a range of 100 MPa to 3 GPa. The breaking elongation of the second supporting sub-portion 311N may be greater than 10%. The elastic modulus of the second supporting portion 321 may be in a range of 1~10 GPa, preferably in a range of 2~5 GPa. The light transmittance of the second supporting portion 321 may be greater than 85% (for example, the light transmittance for light with a wavelength of 550 nm is greater than 85%) to facilitate automated optical inspection (AOI) and some process observations. The haze of the second supporting portion 321 may be less than 5%. The breaking elongation of the second supporting portion 321 may be greater than 50%. The elastic modulus of the third supporting portion 331 may be in a range of 10 kPa to 10 MPa. The breaking elongation of the third supporting portion 331 may be greater than 200%.

Exemplarily, the second supporting sub-portion 311N, the second supporting portion 321 and the third supporting portion 331 may be manufactured using the same material but with different curing rates to achieve different performance, such as different elastic moduli. The second supporting sub-portion 311N, the second supporting portion 321 and the third supporting portion 331 may also be manufactured using different materials to achieve different performance. For example, the material of the third supporting portion 331 is different from that of the second supporting sub-portion 311N.

It may be understood that when the second supporting sub-portion 311N, the second supporting portion 321 and the third supporting portion 331 are manufactured using the same material but with different curing rates, the groove 3G (referring to FIG. 11B) may not need to be cut in the laser cutting process, thereby simplifying the cutting process. The third supporting portion 331 with low modulus and high elongation may be bent directly, thereby improving the strength of the folding area BB (referring to FIG. 11B) and improving the reliability of the display device 100.

Exemplarily, with reference to FIGS. 11B and 15, when the second supporting sub-portion 311N, the second supporting portion 321 and the third supporting portion 331 are manufactured using the same material, the third supporting portion 331 may be an extension portion of the second supporting sub-portion 311N. That is, the second supporting sub-portion 311N may extend from the display area AA to the folding area BB and abut against the second supporting portion 321. Herein, the elastic modulus of the second supporting sub-portion 311N located in the display area AA is greater than the elastic modulus of the second supporting sub-portion 311N (i.e., the third supporting portion 331) located in the folding area BB; the elastic modulus of the second supporting portion 321 is greater than the elastic modulus of the second supporting sub-portion 311N (i.e., the third supporting portion 331) located in the folding area BB.

In some embodiments of the present disclosure, referring to FIG. 15, the first supporting sub-portion 311M may be located on a side of the second supporting sub-portion 311N away from the first adhesive portion 312. Referring to FIG. 18, the first supporting sub-portion 311M may also be located on a side of the second supporting sub-portion 311N close to the first adhesive portion 312.

FIGS. 19 and 20 respectively illustrate schematic diagrams of a display device before bending according to some exemplary embodiments of the present disclosure.

Referring to FIGS. 19 and 20, the first supporting portion 311 may include a first supporting sub-portion 311M and a second supporting sub-portion 311N. The second supporting sub-portion 311N is disposed on a side of the first supporting sub-portion 311M close to the first adhesive portion 312 and on a side of the first supporting sub-portion 311M away from the first adhesive portion 312, and covers a surface of the first supporting sub-portion 311M close to the first adhesive portion 312, a surface of the first supporting sub-portion 311M away from the first adhesive portion 312, and a side surface of the first supporting sub-portion 311M. Exemplarily, the second supporting sub-portion 311N may include a third sub-portion 3113, a fourth sub-portion 3114 and a fifth sub-portion 3115. Exemplarily, an orthographic projection of the third sub-portion 3113 on the display panel 1 and an orthographic projection of the fourth sub-portion 3114 on the display panel 1 coincide with an orthographic projection of the first supporting sub-portion 311M on the display panel 1. The third sub-portion 3113 may be located on a side of the first supporting sub-portion 311M close to the first adhesive portion 312, and the fourth sub-portion 3114 may be located on a side of the first supporting sub-portion 311M away from the first adhesive portion 312. An orthographic projection of the fifth sub-portion 3115 on the display panel 1 does not overlap with the orthographic projection of the first supporting sub-portion 311M on the display panel 1. A thickness h5 of the third sub-portion 3113 and a thickness h6 of the fourth sub-portion 3114 may each be in a range of 10~50 μm. A thickness h7 of the fifth sub-portion 3115 may be greater than 50 μm. The thickness h7 of the fifth sub-portion 3115 may be equal to a sum of the thickness h5 of the third sub-portion 3113, the thickness h6 of the fourth sub-portion 3114 and the thickness h3 (referring to FIG. 12F) of the first supporting sub-portion 311M.

It may be understood that, in such embodiments, the second supporting sub-portion 311N is disposed on both the side of the first supporting sub-portion 311M close to the first adhesive portion 312 and the side of the first supporting sub-portion 311M away from the first adhesive portion 312, which may further reduce the bending stress in the display area AA (referring to FIG. 11B) of the display panel 1.

In some embodiments of the present disclosure, referring to FIG. 19, the supporting film may include only the first film portion 31 and the second film portion 32. Referring to FIG. 20, the supporting film may also include the first film portion 31, the second film portion 32 and the third film portion 33.

FIG. 21 is a schematic diagram of a display device before bending according to some exemplary embodiments of the present disclosure.

Referring to FIG. 21, in some embodiments of the present disclosure, the performance of the second adhesive portion 322 may be different from the performance of the first adhesive portion 312. For example, the elastic modulus of the second adhesive portion 322 may be greater than the elastic modulus of the first adhesive portion 312. Exemplarily, the elastic modulus of the first adhesive portion 312 may be in a range of 1~150 kPa to improve the bending performance in the display area AA (referring to FIG. 11B) of the display panel 1. The elastic modulus of the second adhesive portion 322 may be in a range of 100~500 kPa to facilitate bonding.

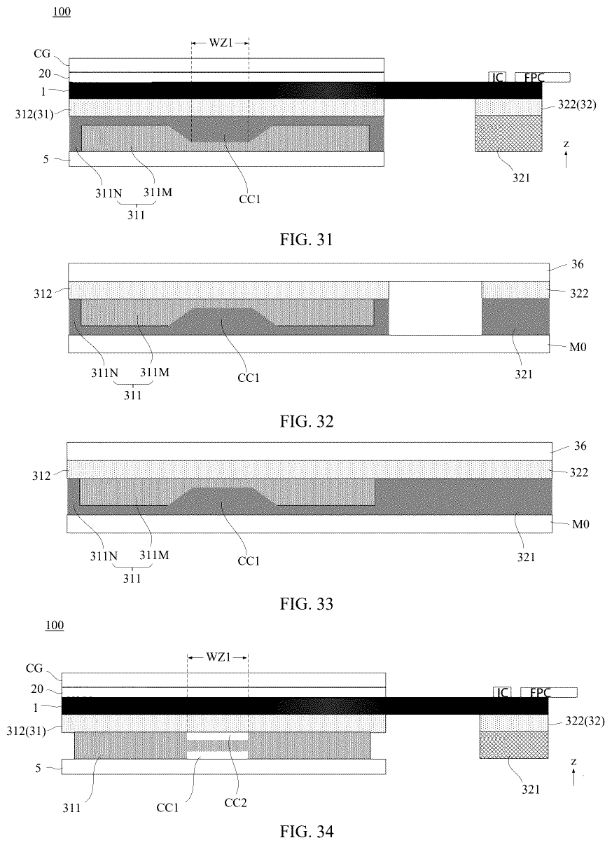

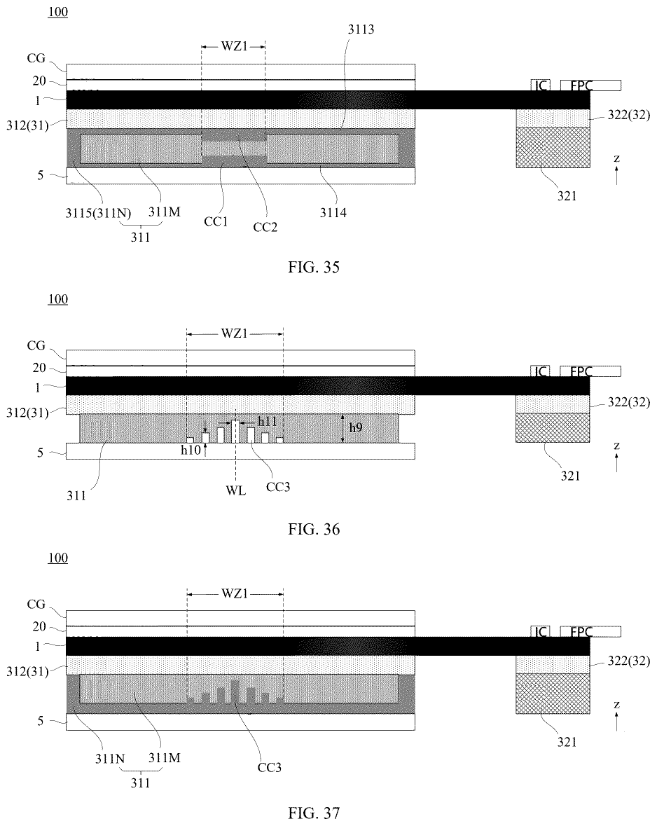

FIG. 22 is a partial cross-sectional view of a supporting film in the related art. FIG. 23 is a partial cross-sectional view of a supporting film according to some exemplary embodiments of the present disclosure.

Referring to FIG. 22, in the related art, a double-sided chamfering (i.e., C-chamfer) process is used to strengthen edges of the first supporting sub-portion 311M. However, when forming the polymer material layer 311N′, a problem of uneven adhesive application at the edge of the first supporting sub-portion 311M may occur.

Referring to FIG. 23, in some embodiments of the present disclosure, in a cross-section taken along a direction from the polymer material layer 311N′ to the first supporting sub-portion 311M, a shape of the first supporting sub-portion 311M may be a trapezoid, where an upper base (i.e., the shorter side) of the trapezoid is disposed close to the polymer material layer 311N′, and a lower base (i.e., the longer side) of the trapezoid is disposed away from the polymer material layer 311N′. That is, in such embodiments, a single-sided chamfering process is used to form the first supporting sub-portion 311M. During polymer material coating, film formation may proceed along a chamfer inclination direction (i.e., a lateral side of the trapezoid) to fill the segment step of the first supporting sub-portion 311M. A film with uniform thickness may be formed at an interface between the polymer material and the first supporting sub-portion 311M, thereby improving the performance of the supporting film.

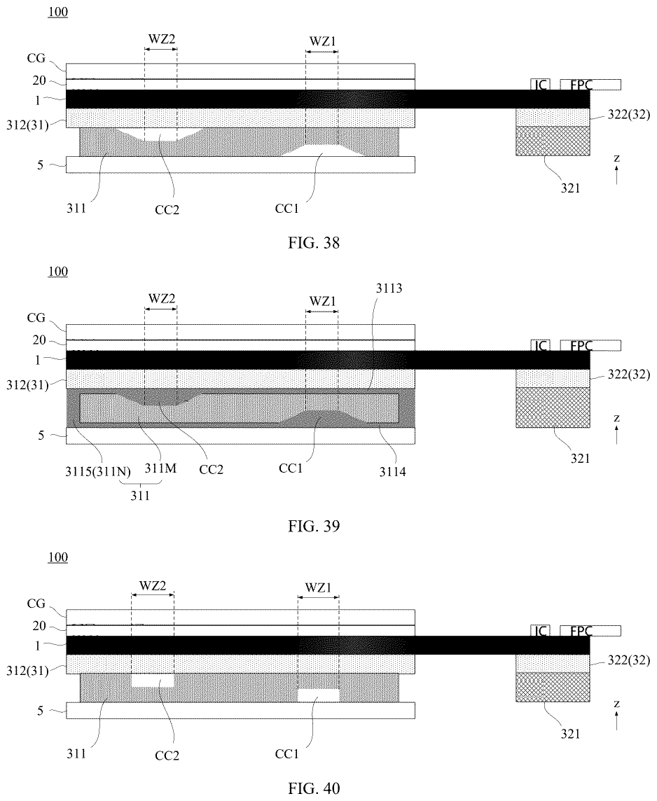

FIG. 24 is a schematic diagram of a display device before bending according to some exemplary embodiments of the present disclosure.

Referring to FIG. 24, in some embodiments of the present disclosure, the cover plate CG may include a light-transmitting portion CG1 and a light-shielding portion CG2 surrounding the light-transmitting portion CG1. The material of the light-shielding portion CG2 may be, for example, ink. The first supporting portion 311 may include a first supporting sub-portion 311M and a third supporting sub-portion 311P. Both the third supporting sub-portion 311P and the first supporting sub-portion 311M are attached to the first adhesive portion 312, and are attached to the display panel 1 through the first adhesive portion 312. The third supporting sub-portion 311P may be located in an inward-recessed space of the first supporting sub-portion 311M relative to the first adhesive portion 312, that is, the third supporting sub-portion 311P may be disposed around the first supporting sub-portion 311M to fill the inward-recessed space of the first supporting sub-portion 311M.

Exemplarily, a gap is formed between the third supporting sub-portion 311P and the first supporting sub-portion 311M. The light-transmitting portion CG1 may be disposed corresponding to the first supporting sub-portion 311M, for example, an orthographic projection of the light-transmitting portion CG1 on the display panel 1 falls within an orthographic projection of the first supporting sub-portion 311M on the display panel 1. The light-shielding portion CG2 may be disposed corresponding to the third supporting sub-portion 311P, for example, an orthographic projection of the third supporting sub-portion 311P on the display panel 1 falls within an orthographic projection of the light-shielding portion CG2 on the display panel 1. The orthographic projection of the light-shielding portion CG2 on the display panel 1 may cover an orthographic projection of the gap on the display panel 1.

Exemplarily, the material of the second supporting portion 321 may be the same as the material of the third supporting sub-portion 311P. For example, the material of the third supporting sub-portion 311P may be PET, PI, or the like. In the light emitting direction (i.e., the Z direction) of the display panel 1, a thickness of the third supporting sub-portion 311P may be greater than or equal to a thickness of the first supporting sub-portion 311M.

It may be understood that, in such embodiments, the interface between the first supporting sub-portion 311M and the third supporting sub-portion 311P (i.e., a region where the aforementioned gap is located) is located within the region where the light-shielding portion CG2 is located, and is invisible from a front viewing angle. Therefore, even if there is a deviation in the attachment of the third supporting sub-portion 311P, resulting in a certain gap between the third supporting sub-portion 311P and the first supporting sub-portion 311M, the display effect of the display device 100 is not affected, such that occurrence of imprinting or optical non-uniformity may be prevented.

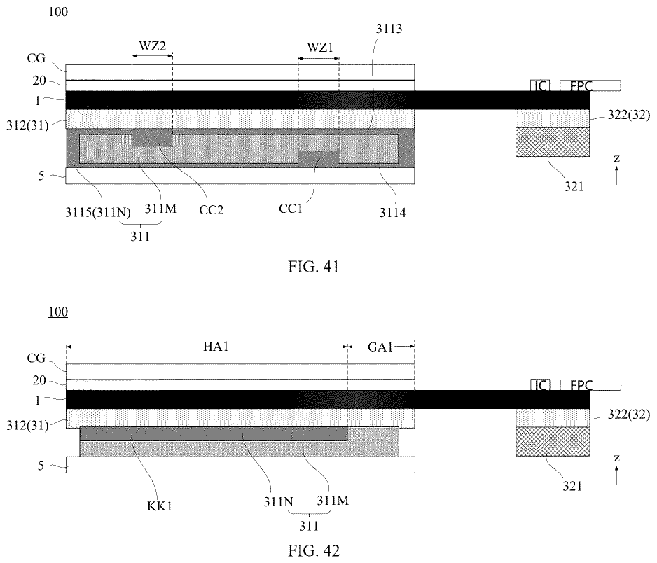

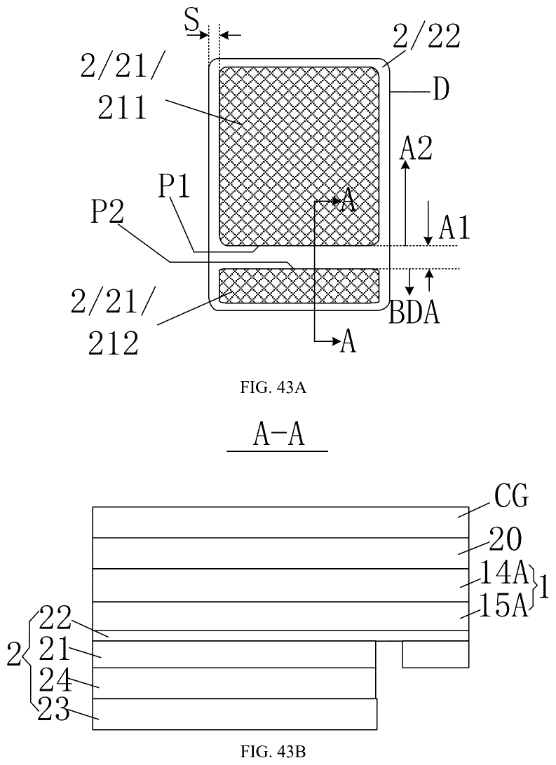

FIG. 25 is a schematic diagram of a display device before bending according to some exemplary embodiments of the present disclosure. FIG. 26 is a cross-sectional view of a supporting film according to some exemplary embodiments of the present disclosure. FIG. 27 is a schematic diagram of a display device before bending according to some exemplary embodiments of the present disclosure.

Referring to FIGS. 25 to 27, the first film portion 31 includes a first supporting portion 311 and a first adhesive portion 312, and the first supporting portion 311 is attached to the back surface of the display panel 1 through the first adhesive portion 312 to support the display panel 1. The second film portion 32 includes a second supporting portion 321 and a second adhesive portion 322, and the second supporting portion 321 is attached to the back surface of the display panel 1 through the second adhesive portion 322 to support the display panel 1. The material of the second adhesive portion 322 may be the same as the material of the first adhesive portion 312. For example, both the second adhesive portion 322 and the first adhesive portion 312 may be pressure-sensitive adhesives.

In some embodiments of the present disclosure, the first supporting portion 311 may be made of a material with high elastic modulus (for example, ultra-thin glass or stainless steel). Exemplarily, the first supporting portion 311 may be ultra-thin glass. Any side edge of the first supporting portion 311 is recessed inward by a first distance relative to a corresponding side edge of the first adhesive portion 312. It may be understood that the first supporting portion 311 needs to undergo strengthening treatment to achieve bendability, and cannot be cut after the strengthening treatment. Therefore, when cutting a supporting film master-sheet to form individual supporting film sub-sheets, cutting may be performed in a region of the first adhesive portion 312 that does not overlap with the first supporting portion 311, thereby avoiding cutting the first supporting portion 311 and preventing the first supporting portion 311 from fracturing during the cutting process. It may be understood that using a material with high elastic modulus to manufacture the first supporting portion 311 may improve the crease recovery performance of the entire display device 100.

In some embodiments of the present disclosure, the elastic modulus of the first supporting portion 311 may be in a range of 50~150 GPa, preferably in a range of 70~120 GPa. The first supporting portion 311 may withstand a 100,000-cycle dynamic bending test with a bending radius of 1 mm (i.e., 100k R1 dynamic bending OK). The breaking elongation of the first supporting portion 311 may be in a range of 5% to 40%, preferably in a range of 5% to 30%. The moisture absorption rate of the first supporting portion 311 may be less than 2%, preferably less than 1%. The compressive stress (CS) of the first supporting portion 311 may be greater than 450 MPa. The ion exchange layer depth (DOL) of the first supporting portion 311 may be greater than 5 μm.

In some embodiments of the present disclosure, the material of the second supporting portion 321 may be a polymer material (for example, polyethylene terephthalate). The light transmittance of the second supporting portion 321 may be greater than or equal to 80%. The haze of the second supporting portion 321 may be less than or equal to 5%. In this way, the optical performance of the supporting film in the bonding area CC (referring to FIG. 11B) may be improved, for example, the light transmittance is increased. Therefore, the bonding area CC may be clearly observed, which is beneficial to capture a bonding mark and observe a crease.

In some embodiments of the present disclosure, the first supporting portion 311 and the second supporting portion 321 may be attached to the back surface of the display panel 1 by a splicing process, thereby eliminating the need to cut the groove 3G (referring to FIG. 11B) in the laser cutting process and simplifying the cutting process.

In some embodiments of the present disclosure, the bendable area includes at least one bending region (for example, a first bending region WZ1). The first bending region WZ1 is located in the display area AA (referring to FIG. 11B), and an area of the first bending region WZ1 is less than an area of the display area AA. That is, the display device 100 may be bent in the first bending region WZ1. A bending direction may be towards the cover plate CG (i.e., inward folding), or the bending direction may be towards the supporting member 5 (i.e., outward folding).

In some embodiments of the present disclosure, the first supporting portion 311 may include a first sub-portion located in the first bending region WZ1, and a second sub-portion and a third sub-portion located on two sides of the first sub-portion in an extending direction of the first sub-portion and connected to the first sub-portion. An average thickness of the second sub-portion is the same as an average thickness h9 of the third sub-portion; a minimum thickness h8 of the first sub-portion is less than the average thickness of the second sub-portion. That is, a thickness h8 of a part of an orthographic projection of the first supporting portion 311 on the display panel 1 that is located within the first bending region WZ1 is less than a thickness h9 of a part of the orthographic projection of the first supporting portion 311 on the display panel 1 that is located outside the first bending region WZ1. In this way, it is possible to both improve the supporting strength of the first supporting portion 311 on the display area AA of the display panel 1 and improve the bending performance of the display device 100 in the first bending region WZ1.

It should be noted that, in such embodiments, the first supporting portion 311 includes only the first supporting sub-portion. Therefore, the first supporting sub-portion is the first supporting portion 311.

In some embodiments of the present disclosure, the thickness h8 of the part of the orthographic projection of the first supporting portion 311 on the display panel 1 that is located within the first bending region WZ1 is thinned relative to the thickness h9 of the part of the orthographic projection of the first supporting portion 311 on the display panel 1 that is located outside the first bending region WZ1. Specifically, the first sub-portion may include a first surface close to the first adhesive portion 312 and a fourth surface away from the first adhesive portion 312, the second sub-portion may include a second surface close to the first adhesive portion 312 and a fifth surface away from the first adhesive portion 312, and the third sub-portion may include a third surface close to the first adhesive portion 312 and a sixth surface away from the first adhesive portion 312. Referring to FIGS. 25 and 26, the first surface, the second surface and the third surface are coplanar. Alternatively, referring to FIG. 27, the fourth surface, the fifth surface and the sixth surface are coplanar.

Exemplarily, the thinning may be achieved by forming a groove on a surface of the first supporting portion 311 on a side away from the first adhesive portion 312, or may be achieved by forming a groove on a surface of the first supporting portion 311 on a side close to the first adhesive portion 312. For example, the first supporting portion 311 includes a first groove CC1. The first groove CC1 is located on a side of the first supporting portion 311 away from the first adhesive portion 312 (referring to FIGS. 25 and 26), or the first groove CC1 is located on a side of the first supporting portion 311 close to the first adhesive portion 312 (referring to FIG. 27). Exemplarily, in the cross-sectional views shown in FIGS. 25 to 27, a shape of the first groove CC1 may be a trapezoid.

In some embodiments of the present disclosure, referring to FIG. 26, the supporting film may be supplied as including a release film 36 and a carrier film M0. The release film 36 may cover the first adhesive portion 312 and the second adhesive portion 322 to protect the first adhesive portion 312 and the second adhesive portion 322. The carrier film M0 may cover the first supporting portion 311 and the second supporting portion 321 to protect the first supporting portion 311 and the second supporting portion 321. It should be noted that when attaching the supporting film to the display panel 1, the release film 36 and the carrier film M0 need to be torn off.

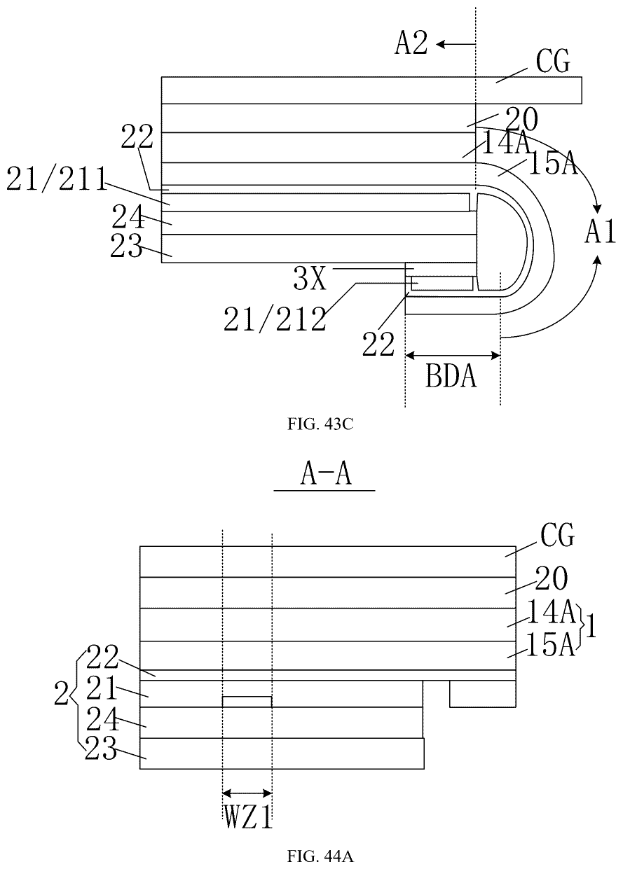

FIG. 28 is a cross-sectional view of a supporting film according to some exemplary embodiments of the present disclosure.

Referring to FIG. 28, in some embodiments of the present disclosure, the supporting film may include a fourth supporting portion 341. The fourth supporting portion 341 may be disposed on a side of the second supporting portion 321 away from the second adhesive portion 322, that is, the fourth supporting portion 341 may be located between the second supporting portion 321 and the carrier film M0. It may be understood that when the thickness of the first supporting portion 311 is greater than the thickness of the second supporting portion 321, the fourth supporting portion 341 may be disposed on a side of the second supporting portion 321 away from the second adhesive portion 322, so that a sum of an average thickness of the second supporting portion 321 and an average thickness of the fourth supporting portion 341 is the same as a maximum thickness of the first supporting portion 311, thereby improving the flatness of the supporting film. Exemplarily, the material of the fourth supporting portion 341 may be a polymer material. The material of the fourth supporting portion 341 may be the same as the material of the second supporting portion 321.

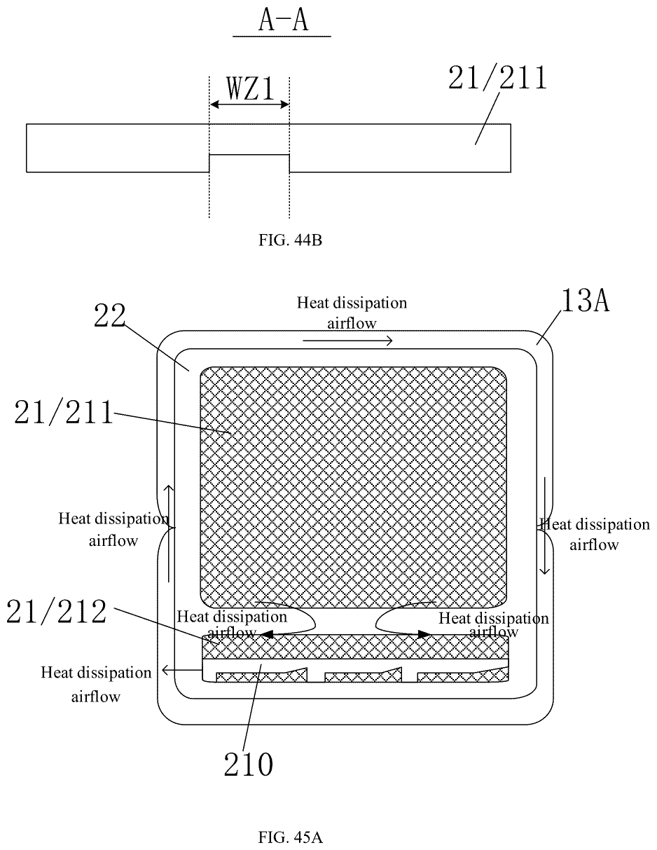

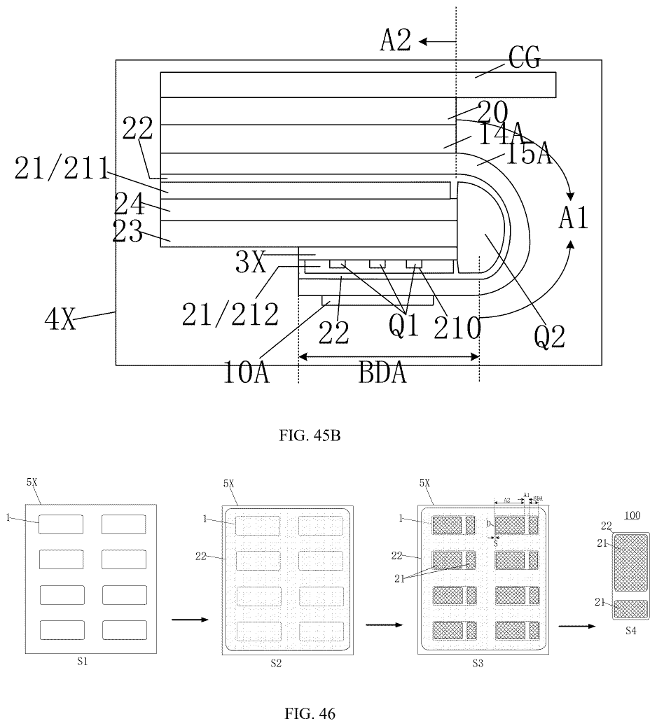

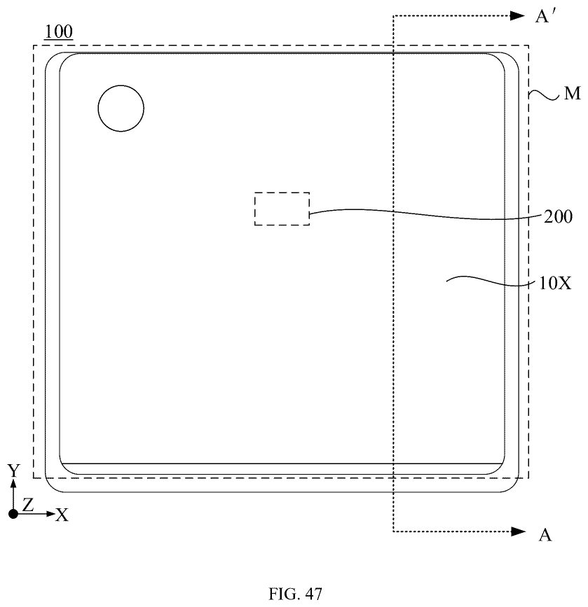

FIG. 29 is a schematic diagram of a display device before bending according to some exemplary embodiments of the present disclosure. FIG. 30 is a cross-sectional view of a supporting film according to some exemplary embodiments of the present disclosure. FIG. 31 is a schematic diagram of a display device before bending according to some exemplary embodiments of the present disclosure.

Referring to FIGS. 29 to 31, in some embodiments of the present disclosure, the first supporting portion 311 may include a first supporting sub-portion 311M and a second supporting sub-portion 311N. The first supporting sub-portion 311M may be made of a material with high elastic modulus (for example, ultra-thin glass or stainless steel). Exemplarily, the first supporting sub-portion 311M may be ultra-thin glass. The first supporting sub-portion 311M includes a first groove CC1. The first groove CC1 may be located on a side of the first supporting sub-portion 311M away from the first adhesive portion 312 (referring to FIGS. 29 and 30), or the first groove CC1 may be located on a side of the first supporting sub-portion 311M close to the first adhesive portion 312 (referring to FIG. 31). The second supporting sub-portion 311N may be located on a side of the first supporting sub-portion 311M close to the first groove CC1.

Exemplarily, the second supporting sub-portion 311N may cover a surface of the first supporting sub-portion 311M on a side close to the first groove CC1 and a side surface of the first supporting sub-portion 311M. That is, the second supporting sub-portion 311N may fill the segment step formed due to the inward recession of the first supporting sub-portion 311M and the thickness step of the first groove CC1, thereby improving the flatness of the display device 100 and avoiding imprinting.

Exemplarily, the material of the second supporting sub-portion 311N may be a polymer material (for example, transparent polyimide, polyurethane, polymethyl methacrylate, silicone, etc.). The second supporting sub-portion 311N may be formed by liquid coating followed by curing. The coating methods may include blade coating, slit coating, dispensing, etc.

Exemplarily, the elastic modulus of the second supporting sub-portion 311N may be in a range of 10 MPa to 10 GPa, preferably in a range of 30 MPa to 3 GPa. The breaking elongation of the second supporting sub-portion 311N may be greater than 10%.

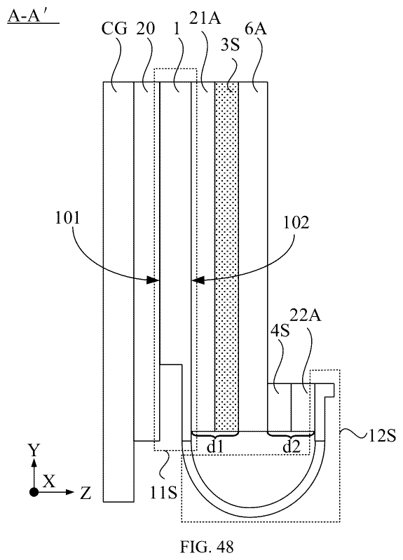

FIGS. 32 and 33 respectively illustrate cross-sectional views of a supporting film according to some exemplary embodiments of the present disclosure.

In some embodiments of the present disclosure, referring to FIG. 32, the material of the second supporting portion 321 may be the same as the material of the second supporting sub-portion 311N. For example, both the second supporting portion 321 and the second supporting sub-portion 311N are made of polymer materials. The second supporting portion 321 and the second supporting sub-portion 311N may be manufactured by the same process step. For example, both the second supporting portion 321 and the second supporting sub-portion 311N are formed by liquid coating followed by curing. It may be understood that since the second supporting portion 321 and the second supporting sub-portion 311N may be manufactured by the same process step, there is no need to attach other film materials on a side of the second adhesive portion 322 away from the display panel 1 (referring to FIG. 11B), thereby reducing process difficulty.

In some embodiments of the present disclosure, referring to FIG. 33, the first adhesive portion 312 and the second adhesive portion 322 may be disposed continuously, and the first supporting portion 311 and the second supporting portion 321 may be disposed continuously. That is, the groove 3G (referring to FIG. 11B) between the first film portion 31 and the second film portion 32 may be omitted. Exemplarily, the supporting film may further include a third film portion 33 (referring to FIGS. 15 to 18), and the third film portion 33 may be located between the first film portion 31 and the second film portion 32. An orthographic projection of the third film portion 33 on the display panel 1 may at least partially overlap with the folding area BB of the display panel 1.

Exemplarily, referring to FIGS. 15 to 18, the third film portion 33 includes a third supporting portion 331 and a third adhesive portion 332. The third supporting portion 331 is attached to the back surface of the display panel 1 through the third adhesive portion 332 to support the display panel 1. The third adhesive portion 332, the second adhesive portion 322 and the first adhesive portion 312 may be made of the same material, such as pressure-sensitive adhesives. The third adhesive portion 332, the second adhesive portion 322 and the first adhesive portion 312 may be disposed continuously, that is, the third adhesive portion 332, the second adhesive portion 322 and the first adhesive portion 312 may be manufactured by the same process step, eliminating the need to form the groove 3G as shown in FIG. 11B.

Exemplarily, referring to FIGS. 15 to 18, the second supporting sub-portion 311N, the second supporting portion 321 and the third supporting portion 331 may be manufactured using the same material but with different curing rates to achieve different performance. The second supporting sub-portion 311N, the second supporting portion 321 and the third supporting portion 331 may also be manufactured using different materials to achieve different performance.

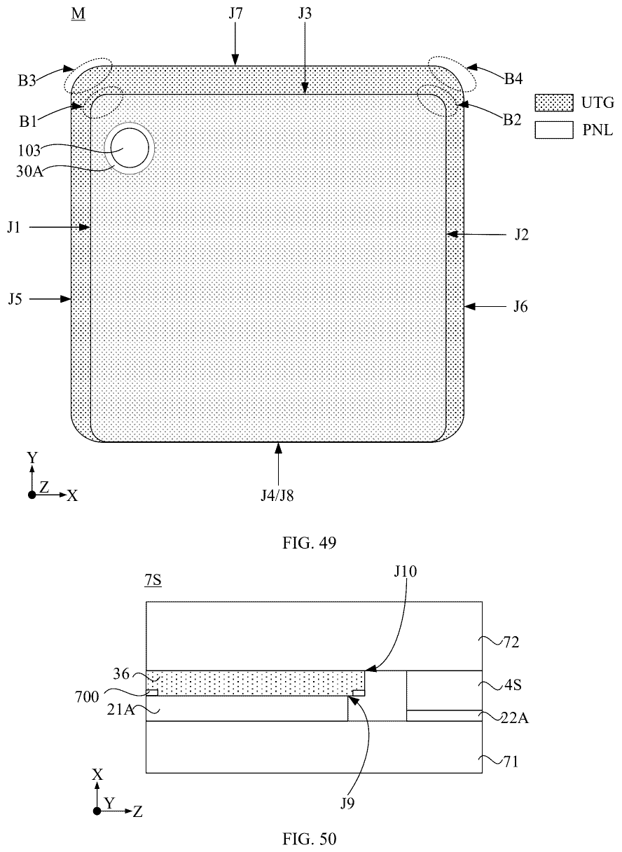

FIGS. 34 and 35 respectively illustrate schematic diagrams of a display device before bending according to some exemplary embodiments of the present disclosure.

Referring to FIG. 34, in some embodiments of the present disclosure, the first supporting portion 311 includes a first sub-portion located in the first bending region WZ1, and a second sub-portion and a third sub-portion located on two sides of the first sub-portion an extending direction of the first sub-portion and connected to the first sub-portion. The first sub-portion includes a first surface close to the first adhesive portion 312 and a fourth surface away from the first adhesive portion 312, the second sub-portion includes a second surface close to the first adhesive portion 312 and a fifth surface away from the first adhesive portion 312, and the third sub-portion includes a third surface close to the first adhesive portion 312 and a sixth surface away from the first adhesive portion 312. An extension plane of the second surface and an extension plane of the third surface are coplanar, and an extension plane of the fifth surface and an extension plane of the sixth surface are coplanar. Both the first surface and the fourth surface are located between the extension plane of the second surface and the extension plane of the fifth surface.

Exemplarily, the first supporting portion 311 may include a first groove CC1 and a second groove CC2. The first groove CC1 may be located on a side of the first supporting portion 311 away from the first adhesive portion 312, and the second groove CC2 may be located on a side of the first supporting portion 311 close to the first adhesive portion 312. An orthographic projection of the first groove CC1 on the first adhesive portion 312 at least partially overlaps with an orthographic projection of the second groove CC2 on the first adhesive portion 312. By providing the first groove CC1 and the second groove CC2 on the first supporting portion 311, the bending performance of the display device 100 in the first bending region WZ1 may be further improved.

Referring to FIG. 35, in some embodiments of the present disclosure, the first supporting portion 311 may include a first supporting sub-portion 311M and a second supporting sub-portion 311N. The first supporting sub-portion 311M may include a first groove CC1 and a second groove CC2. The first groove CC1 may be located on a side of the first supporting sub-portion 311M away from the first adhesive portion 312, and the second groove CC2 may be located on a side of the first supporting sub-portion 311M close to the first adhesive portion 312. An orthographic projection of the first groove CC1 on the first adhesive portion 312 at least partially overlaps with an orthographic projection of the second groove CC2 on the first adhesive portion 312.

The second supporting sub-portion 311N may include a third sub-portion 3113, a fourth sub-portion 3114 and a fifth sub-portion 3115. Exemplarily, an orthographic projection of the third sub-portion 3113 on the display panel 1 and an orthographic projection of the fourth sub-portion 3114 on the display panel 1 both coincide with an orthographic projection of the first supporting sub-portion 311M on the display panel 1. The third sub-portion 3113 may be located on a side of the first supporting sub-portion 311M close to the first adhesive portion 312, and the fourth sub-portion 3114 may be located on a side of the first supporting sub-portion 311M away from the first adhesive portion 312. An orthographic projection of the fifth sub-portion 3115 on the display panel 1 does not overlap with the orthographic projection of the first supporting sub-portion 311M on the display panel 1. That is, the third sub-portion 3113 may fill the thickness step of the second groove CC2, the fourth sub-portion 3114 may fill the thickness step of the first groove CC1, and the fifth sub-portion 3115 may fill the segment step formed due to the inward recession of the first supporting sub-portion 311M, thereby improving the flatness of the display device 100.

In some embodiments of the present disclosure, in the cross-sectional views shown in FIGS. 34 and 35, a shape of the first groove CC1 and a shape of the second groove CC2 may both be rectangles.

FIGS. 36 and 37 respectively illustrate schematic diagrams of a display device before bending according to some exemplary embodiments of the present disclosure.

Referring to FIG. 36, in some embodiments of the present disclosure, the first supporting portion 311 may include a plurality of third grooves CC3 located in the first bending region WZ1. An orientation of the third grooves CC3 may be a direction away from the first adhesive portion 312, that is, the plurality of third grooves CC3 may be located on a side of the first supporting portion 311 away from the first adhesive portion 312. In other embodiments, the orientation of the third grooves CC3 may be a direction towards the first adhesive portion 312, that is, the plurality of third grooves CC3 may be located on a side of the first supporting portion 311 close to the first adhesive portion 312. Alternatively, the first supporting portion 311 may include at least two first bending regions WZ1, and the orientations of the third grooves CC3 in the two first bending regions WZ1 may be opposite to each other.

Exemplarily, the plurality of third grooves CC3 are arranged side by side in a second direction y (referring to FIG. 1), and depths h10 of the plurality of third grooves CC3 increase sequentially in the second direction y towards a center of the first bending region WZ1. For example, referring to FIG. 36, the depths h10 of the plurality of third grooves CC3 gradually decrease from the middle (for example, a bending center line WL of the first bending region WZ1) towards the two sides (for example, a side away from the second supporting portion 321 and a side close to the second supporting portion 321). A difference in depth between two adjacent third grooves CC3 may be in a range of 5~20 μm. The depth h10 of the third groove CC3 may be less than the maximum thickness h9 of the first supporting portion 311. In the second direction y, a width h11 of the third groove CC3 may be in a range of 0.5~3 mm. The plurality of third grooves CC3 may be arranged symmetrically left and right with the bending center line WL as the axis of symmetry.

Referring to FIG. 37, in some embodiments of the present disclosure, the first supporting portion 311 may include a first supporting sub-portion 311M and a second supporting sub-portion 311N. The first supporting sub-portion 311M may include a plurality of third grooves CC3, and the plurality of third grooves CC3 may be located on a side of the first supporting sub-portion 311M away from the first adhesive portion 312. The second supporting sub-portion 311N may be located on a side of the first supporting sub-portion 311M away from the first adhesive portion 312, and at least a portion of the second supporting sub-portion 311N is located within the plurality of third grooves CC3. That is, the second supporting sub-portion 311N may fill the thickness steps of the plurality of third grooves CC3 and fill the segment step formed due to the inward recession of the first supporting sub-portion 311M, thereby improving the flatness of the display device 100.

In some embodiments of the present disclosure, in the cross-sectional views shown in FIGS. 36 and 37, a shape of the third groove CC3 may be a rectangle.

FIGS. 38 to 41 respectively illustrate schematic diagrams of a display device before bending according to some exemplary embodiments of the present disclosure.

Referring to FIGS. 38 and 40, in some embodiments of the present disclosure, the first supporting portion 311 may include a first groove CC1 and a second groove CC2. The first groove CC1 may be located on a side of the first supporting portion 311 away from the first adhesive portion 312, and the second groove CC2 may be located on a side of the first supporting portion 311 close to the first adhesive portion 312. An orthographic projection of the first groove CC1 on the first adhesive portion 312 does not overlap with an orthographic projection of the second groove CC2 on the first adhesive portion 312.

Exemplarily, the display panel 1 may include a plurality of bending regions spaced apart from each other (for example, including a first bending region WZ1 and a second bending region WZ2). The first sub-portions of two adjacent bending regions may have different shortest distances to the first adhesive portion 312. For example, referring to FIG. 38, the first sub-portion of the first bending region WZ1 is attached to the first adhesive portion 312, that is, the shortest distance from the first sub-portion of the first bending region WZ1 to the first adhesive portion 312 may be 0; the shortest distance from the first sub-portion of the second bending region WZ2 to the first adhesive portion 312 may be greater than 0.

Exemplarily, an orthographic projection of the first groove CC1 on the display panel 1 may at least partially overlap with the first bending region WZ1, and an orthographic projection of the second groove CC2 on the display panel 1 may at least partially overlap with the second bending region WZ2. That is, the display device 100 may be a triple-fold display. In other embodiments, the display panel 1 may include more than two bending regions to achieve a multi-fold display, which is not limited in embodiments of the present disclosure.

Referring to FIGS. 39 and 41, in some embodiments of the present disclosure, the first supporting portion 311 may include a first supporting sub-portion 311M and a second supporting sub-portion 311N. The first supporting sub-portion 311M may include a first groove CC1 and a second groove CC2. The first groove CC1 may be located on a side of the first supporting sub-portion 311M away from the first adhesive portion 312, and the second groove CC2 may be located on a side of the first supporting sub-portion 311M close to the first adhesive portion 312. An orthographic projection of the first groove CC1 on the first adhesive portion 312 does not overlap with an orthographic projection of the second groove CC2 on the first adhesive portion 312.

The second supporting sub-portion 311N may include a third sub-portion 3113, a fourth sub-portion 3114 and a fifth sub-portion 3115. Exemplarily, an orthographic projection of the third sub-portion 3113 on the display panel 1 and an orthographic projection of the fourth sub-portion 3114 on the display panel 1 both coincide with an orthographic projection of the first supporting sub-portion 311M on the display panel 1. The third sub-portion 3113 may be located on a side of the first supporting sub-portion 311M close to the first adhesive portion 312, and the fourth sub-portion 3114 may be located on a side of the first supporting sub-portion 311M away from the first adhesive portion 312. An orthographic projection of the fifth sub-portion 3115 on the display panel 1 does not overlap with the orthographic projection of the first supporting sub-portion 311M on the display panel 1. That is, the third sub-portion 3113 may fill the thickness step of the second groove CC2, the fourth sub-portion 3114 may fill the thickness step of the first groove CC1, and the fifth sub-portion 3115 may fill the segment step formed due to the inward recession of the first supporting sub-portion 311M, thereby improving the flatness of the display device 100.

In some embodiments of the present disclosure, in the cross-sectional views shown in FIGS. 38 to 41, a shape of the first groove CC1 and a shape of the second groove CC2 may be trapezoids (referring to FIGS. 38 and 39) or rectangles (referring to FIGS. 40 and 41).

FIG. 42 is a schematic diagram of a display device before bending according to some exemplary embodiments of the present disclosure.

Referring to FIG. 42, in some embodiments of the present disclosure, the display panel 1 may include a fixed display area GA1 located in the display area AA and a rollable area HA1, and an area of the rollable area HA1 is less than the area of the display area AA. The first supporting portion 311 may include a first supporting sub-portion 311M and a second supporting sub-portion 311N. The first supporting sub-portion 311M includes a first sub-portion located in the rollable area HA1, and a second sub-portion connected to the first sub-portion and located on a side of the first sub-portion close to the folding area BB. The second sub-portion is located in the fixed display area GA1. The average thickness of the second sub-portion may be greater than the minimum thickness of the first sub-portion. In such embodiments, by thinning the first supporting sub-portion 311M located in the rollable area HA1, a rolling capability of the rollable area HA1 is improved, and a post-rolling recovery capability is enhanced, thereby achieving a low roll-crease effect when the entire display device is rolled.

Exemplarily, the first sub-portion includes a first surface close to the first adhesive portion 312 and a fourth surface away from the first adhesive portion 312, and the second sub-portion includes a second surface close to the first adhesive portion 312 and a fifth surface away from the first adhesive portion 312. The fourth surface and the fifth surface are coplanar. The second surface of the second sub-portion contacts the first adhesive portion 312. The second supporting sub-portion 311N may be disposed between an extension plane of the second surface and the first surface, and abuts against a side surface of the second sub-portion close to the first sub-portion.

Exemplarily, the first supporting sub-portion 311M may include a first notch KK1, and an orthographic projection of the first notch KK1 on the display panel 1 is located in the rollable area HA1. The first notch KK1 may be located on a side of the first supporting sub-portion 311M close to the first adhesive portion 312, or located on a side of the first supporting sub-portion 311M away from the first adhesive portion 312, or simultaneously located on both the side of the first supporting sub-portion 311M close to the first adhesive portion 312 and the side of the first supporting sub-portion 311M away from the first adhesive portion 312. The second supporting sub-portion 311N may be located in the first notch KK1.

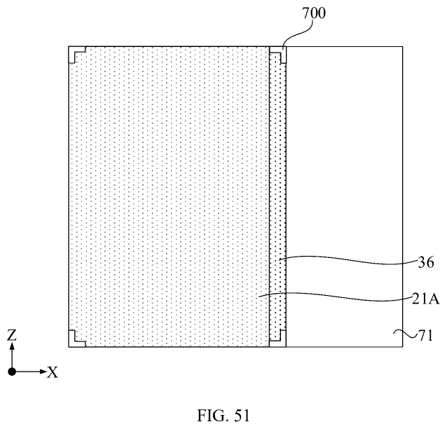

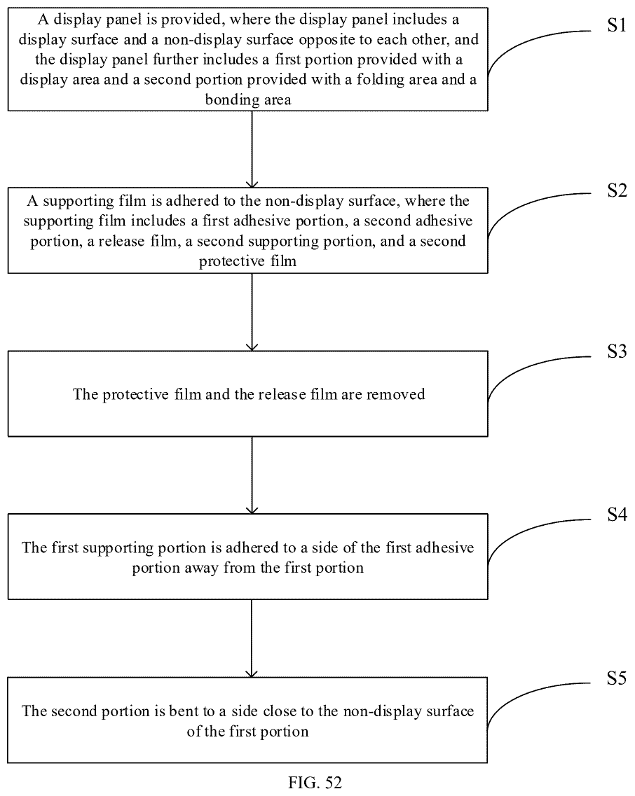

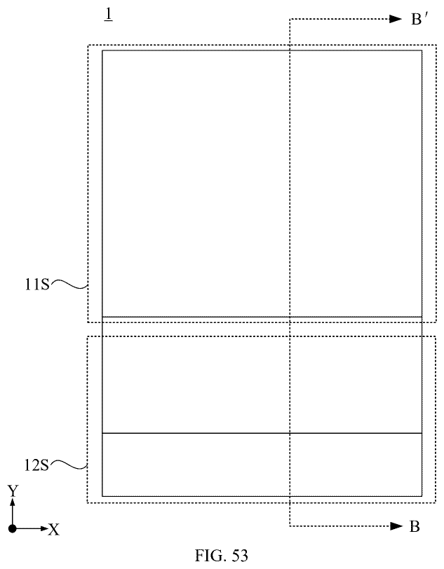

FIG. 43A is a schematic top view of a structure on a back side of a display device according to an embodiment of the present disclosure. FIG. 43B is a schematic cross-sectional view of a structure taken along section line AA in FIG. 43A. FIG. 43C is a schematic cross-sectional view of a display device according to an embodiment of the present disclosure, in which a bonding area of a display panel is bent.

Referring to FIGS. 43A, 43B and 43C, in some embodiments of the present disclosure, the display device includes a display panel 1. The display panel 1 includes a bendable area A2, a folding area A1 and a bonding area BDA, and the folding area A1 is located between the bendable area A2 and the bonding area BDA. A supporting film 2 located on a back side of the display panel 1 is further included. The supporting film 2 includes a first supporting layer 21 and a first adhesive layer 22, and the first adhesive layer 22 and the first supporting layer 21 are sequentially stacked in a direction away from the display panel 1. An orthographic projection of the first supporting layer 21 on the display panel 1 is located in the bendable area A2 and the bonding area BDA. The first adhesive layer 22 covers the back side of the display panel 1; and the first adhesive layer 22 wraps side edge surfaces of the first supporting layer 21.

The folding area A1 may be bent so that the bonding area BDA is located on a back side of the bendable area A2 and is attached and fixed to the back side of the bendable area A2, thereby reducing a bezel width of the entire display device. The bonding area BDA of the display panel 1 is used for bonding connection with a flexible printed circuit board (e.g., FPC, not shown in the drawing), and the flexible printed circuit board is electrically connected to a peripheral circuit board (not shown in the drawing) located on the back side of the display panel 1, thereby enabling the peripheral circuit board to provide a display signal (including a display image signal and a display driving signal) to the display panel 1 via the flexible printed circuit board.

In such embodiments, the display panel 1 includes a display layer 14A and a substrate 15A. The substrate 15A includes a PI substrate and a circuit layer. The display layer 14A includes an OLED display device.

In some embodiments, the elastic modulus of the first supporting layer 21 is greater than or equal to 70 GPa. The first adhesive layer 22 is made of a photo-curable or thermally curable organic polymer material; and the first adhesive layer 22 has a non-tacky surface after curing. The elastic modulus of the first adhesive layer 22 is less than or equal to 1 MPa. A thickness of the first adhesive layer 22 is in a range of 10~20 μm, and the light transmittance of the first adhesive layer 22 is greater than 89%.

In some embodiments, a thickness of the first supporting layer 21 is in a range of 30~50 μm, and the first supporting layer 21 includes ultra-thin glass. The material of the first adhesive layer 22 includes a UV-curable material, such as polyurethane composite acrylate polymer material.

In such embodiments, compared to the polyester films in the related art, the use of the first supporting layer 21 may enhance the supporting strength for the bendable area A2 and the bonding area BDA, and improve or avoid occurrence of unrecoverable creep when the entire display device is folded, thereby achieving the low crease effect when the entire display device is folded. Meanwhile, when the folding area A1 is bent, the bonding area BDA is bent to the back side of the bendable area A2 of the display panel 1, and the first supporting layer 21 may improve the supporting strength for devices in the bonding area BDA, thereby improving or avoiding imprinting that may appear on the display side of the bendable area A2 corresponding to the bonding area BDA caused by compressive deformation of the devices in the bonding area BDA. Additionally, the overall drop performance is improved. By enabling the first adhesive layer 22 to wrap the side edge surfaces of the first supporting layer 21, the first adhesive layer 22 may protect the edges of the first supporting layer 21 and enhance the impact resistance of the edges of the first supporting layer 21. Thus, when cutting a display mother board to form individual display devices, integrated cutting of the display device may be achieved, and the edges of the first supporting layer 21 are less likely to fracture during the cutting process.

In some embodiments, referring to FIG. 43A, any side edge of the first supporting layer 21 is recessed inward by a first distance S relative to a corresponding side edge of the first adhesive layer 22. Since the first supporting layer 21 needs to undergo strengthening treatment to achieve bendability, and cannot be cut after the strengthening treatment. Therefore, when cutting the display mother board to form individual display devices, the cutting may be performed in a region of the first adhesive portion 312 that does not overlap with the first supporting portion 311. Thus, during the process of cutting the display mother board, it is possible to cut only the region covered by the first adhesive layer 22 and avoid cutting the first supporting layer 21, thereby preventing the first supporting layer 21 from fracturing during the cutting process.

In some embodiments, the first distance S is in a range of 0.05~0.2 mm.

In some embodiments, referring to FIG. 43A, an orthographic projection of a side edge of the first supporting layer 21 located in the bendable area A2 close to the folding area A1 on the display panel 1 coincides with a bending start boundary P1 of the folding area A1 close to the bendable area A2. An orthographic projection of a side edge of the first supporting layer 21 located in the bonding area BDA close to the folding area A1 on the display panel 1 coincides with a bending end boundary P2 of the folding area A1 close to the bonding area BDA.

Herein, a side boundary of the folding area A1 close to the bendable area A2 is the bending start boundary P1 of the folding area A1. A side boundary of the folding area A1 close to the bonding area BDA is the bending end boundary P2 of the folding area A1. The first supporting layer 21 does not cover the folding area A1, which may ensure good bending performance of the folding area A1. Compared with the related art where no supporting film layer is provided on the back side of the bending area of the display panel to ensure the bending performance of the bending area of the display panel, the first adhesive layer 22 covering the back side of the folding area A1 may provide support and reinforcement for the folding area A1. Thus, on one hand, good bending performance of the folding area A1 is ensured, and on the other hand, impact resistance and overall drop performance of the bent folding area A1 are also ensured.

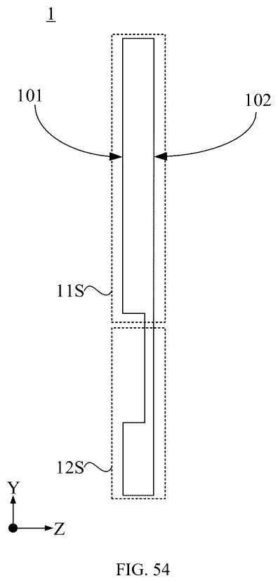

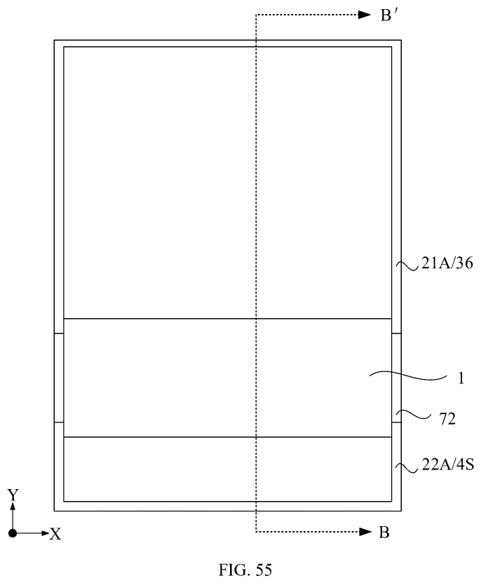

FIG. 44A is another schematic cross-sectional view of a structure taken along section line AA in FIG. 43A. FIG. 44B is a schematic cross-sectional view of a structure of a first supporting layer taken along section line AA in FIG. 43A according to an embodiment of the present disclosure.

Referring to FIGS. 44A and 44B, in some embodiments, the display panel 1 further includes a first bending region WZ1. The first bending region WZ1 is located in the bendable area A2, and the area of the first bending region WZ1 is less than the area of the bendable area A2. A thickness of a portion of the first supporting layer 21 of which an orthographic projection on the display panel 1 is located within the first bending zone WZ1 is less than a thickness of a portion of the first supporting layer 21 of which an orthographic projection on the display panel 1 is located outside the first bending zone WZ1.

Herein, the first bending region WZ1 is a foldable bending region of the entire display device, that is, the display device is a foldable display device. By configuring the thickness of the portion of the orthographic projection of the first supporting layer 21 on the display panel 1 that is located within the first bending zone WZ1 to be less than the thickness of the portion of the orthographic projection of the first supporting layer 21 on the display panel 1 that is located outside the first bending zone WZ1, on one hand, it is ensured that the portion of the first supporting layer 21 of which the orthographic projection on the display panel 1 is located outside the first bending zone WZ1 has sufficient supporting strength for the bendable area A2 of the display panel 1; on the other hand, it is also ensured that the first bending zone WZ1 achieves an ultra-small bending radius.

In some embodiments, the thickness of the portion of the first supporting layer 21 of which the orthographic projection on the display panel 1 is located within the first bending zone WZ1 is in a range of 10~20 μm. Such a thickness enables an ultra-small bending radius for the first bending zone WZ1, for example, a bending radius of the first bending zone WZ1 may reach 1 cm. The thickness of the portion of the first supporting layer 21 of which the orthographic projection on the display panel 1 is located outside the first bending zone WZ1 is in a range of 30~50 μm. This portion of the first supporting layer 21 may provide sufficient supporting strength for the portion of the bendable area A2 outside the first bending zone WZ1.

In some embodiments, the thickness of the portion of the first supporting layer 21 of which the orthographic projection on the display panel 1 is located within the first bending zone WZ1 is thinned relative to the thickness of the portion of the first supporting layer 21 of which the orthographic projection on the display panel 1 is located outside the first bending zone WZ1. The thinning may be achieved by forming a groove on a surface of the first supporting layer 21 on a side away from the first adhesive layer 22, or may be achieved by forming a groove on a surface of the first supporting layer 21 on a side close to the first adhesive layer 22.

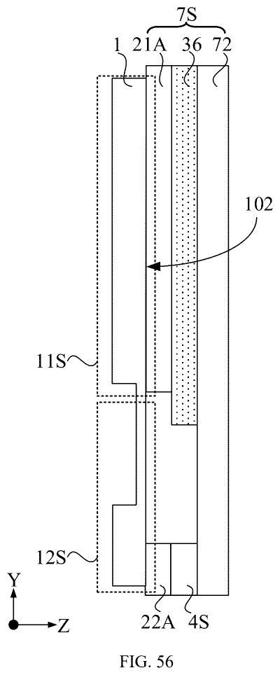

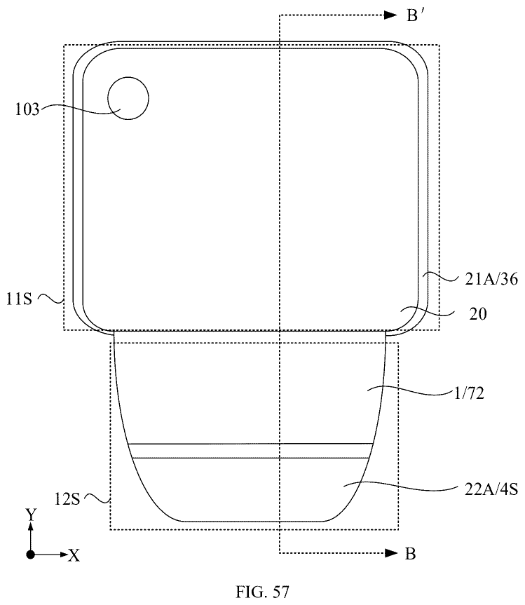

FIG. 45A is a schematic top view of a structure on a back side of a display device according to an embodiment of the present disclosure. FIG. 45B is another schematic cross-sectional view of a display device according to an embodiment of the present disclosure, in which a bonding area of a display panel is bent.

With reference to FIGS. 43C, 45A and 45B, in some embodiments, the folding area A1 is bent towards the back side of the bendable area A2, and the bonding area BDA is located on the back side of the bendable area A2. The display device further includes a second adhesive layer 3X located between a portion of the display panel 1 in the bonding area BDA and a portion of the display panel 1 in the bendable area A2, and the second adhesive layer 3X is attached to the portion of the display panel 1 in the bonding area BDA and the portion of the display panel 1 in the bendable area A2. The first supporting layer 21 includes a first part 211 and a second part 212, the first part 211 is located in the bendable area A2, and the second part 212 is located in the bonding area BDA. The display panel 1 includes a circuit device 10A located on a display side of the display panel 1 and in the bonding area BDA. A plurality of recesses 210 are formed on a surface of the second part 212 on a side close to the first part 211. Orthographic projections of the plurality of recesses 210 on the first part 211 at least partially overlap with an orthographic projection of the circuit device 10A on the first part 211. The recesses 210 and the second adhesive layer 3X are aligned to form air gaps (first air gaps Q1).

In some embodiments, after the folding area A1 is bent, a second air gap Q2 is formed between the folding area A1 and the following side edge surfaces: a side edge surface of the first part 211 close to the folding area A1, a side edge surface of the second part 212 close to the folding area A1, and a side edge surface of the second adhesive layer 3X close to the folding area A1.

In some embodiments, a middle frame 4X will be subsequently provided on the back side of the display panel 1, and the middle frame 4X wraps the entire structure on the back side of the display panel 1. The middle frame 4X is adhered to the back side of the display panel 1 through a heat dissipation frame adhesive 13A, and a heat dissipation groove is generally provided on an exposed outer surface of the middle frame 4X.

In such embodiments, air in the first air gaps Q1 may conduct heat generated by the circuit device 10A during operation to the second adhesive layer 3X, the heat dissipation frame adhesive 13A and the middle frame 4X; and air in the first air gaps Q1 may conduct heat generated by the circuit device 10A during operation to the second adhesive layer 3X, the second air gap Q2, the heat dissipation frame adhesive 13A and the middle frame 4X, thereby forming convection of the heat generated by the circuit device 10A during operation on the back side of the bendable area A2 of the display panel 1. Finally, the heat is conducted to the external environment through the heat dissipation frame adhesive 13A and the middle frame 4X, thereby avoiding the heat generated by the circuit device 10A from being conducted to the portion of the display panel 1 located in the bendable area A2, preventing the heat from affecting the display of the bendable area A2, and ultimately enabling the entire display device to achieve thermal equilibrium.

In some embodiments, referring to FIGS. 43B and 43C, the supporting film 2 further includes a second supporting layer 23 and a third adhesive layer 24, which are located in the bendable area A2 and on a side of the first supporting layer 21 away from the display panel 1. The third adhesive layer 24 and the second supporting layer 23 are stacked sequentially in a direction away from the first supporting layer 21, and orthographic projections of the third adhesive layer 24 and the second supporting layer 23 on the display panel 1 cover the bendable area A2.

The third adhesive layer 24 is made of an adhesive material, and the second supporting layer 23 is made of a metal material. The second supporting layer 23 may further support the bendable area A2 of the display panel 1.

In some embodiments, the display device further includes an optically clear adhesive layer 20 and a cover plate CG. The optically clear adhesive layer 20 and the cover plate CG are stacked sequentially on the display side of the display panel 1.

Compared with the polyester films in the related art, the display device provided by embodiments of the present disclosure, by adopting the first supporting layer 21, may improve the supporting strength for the bendable area A2 and the bonding area BDA, and may improve or avoid unrecoverable creep occurring when the entire display device is folded, thereby achieving a low crease effect when the entire display device is folded. Meanwhile, when the folding area A1 is bent, the bonding area BDA is bent to the back side of the bendable area A2 of the display panel 1, and the first supporting layer 21 may improve the supporting strength for the devices in the bonding area BDA, thereby improving or avoiding imprinting that may appear on the display side of the bendable area A2 corresponding to the bonding area BDA caused by compressive deformation of the devices in the bonding area BDA. Additionally, the overall drop performance of the display device is improved. By enabling the first adhesive layer 22 to wrap the side edge surfaces of the first supporting layer 21, the first adhesive layer 22 may protect the edges of the first supporting layer 21 and enhance the impact resistance of the edges of the first supporting layer 21. Thus, when cutting a display mother board to form individual display devices, integrated cutting of the display device may be achieved, and the edges of the first supporting layer 21 are less likely to fracture during the cutting process.

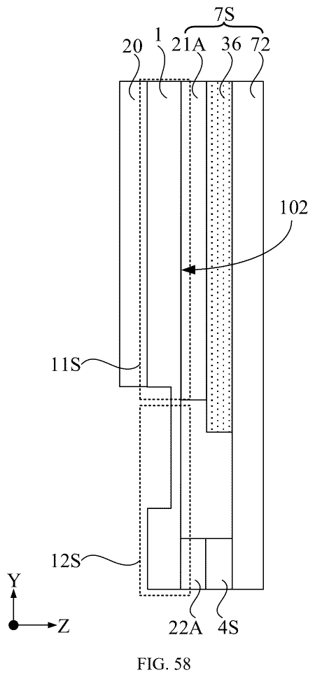

FIG. 46 is a schematic diagram of a manufacturing process of a display device according to an embodiment of the present disclosure.

Based on the above structure of the display device, embodiments of the present disclosure further provide a manufacturing method of a display device. Referring to FIG. 46, the method includes, in step S1, a display mother board 5X is prepared.

The display mother board 5X includes a plurality of display panels 1. The display panel 1 includes a bendable area A2, a folding area A1 and a bonding area BDA. The folding area A1 is located between the bendable area A2 and the bonding area BDA.

In step S2, a supporting film is formed on a back side of the display mother board 5X. Forming the supporting film includes: coating a material of a first adhesive layer 22 on the back side of the display mother board 5X, and performing pre-curing after coating is completed.

In this step, pre-curing the first adhesive layer 22 may reduce the fluidity of the surface of the first adhesive layer 22.

In step S3, a first supporting layer 21 is attached to a side of the first adhesive layer 22 away from the display mother board 5X, and curing is performed.

In this step, when attaching the first supporting layer 21, the first supporting layer 21 is recessed inward relative to a cutting lane D of the display mother board 5X. An edge of the first supporting layer 21 is at a first distance S from the cutting lane D of the display mother board 5X, and the first distance S is in a range of 0.05~0.2 mm.

In step S4, a release film (not shown) is attached to a side of the first supporting layer 21 away from the display mother board 5X, and then the display mother board 5X is cut to form a display device 100.

In this step, since the edges of the first supporting layer 21 are recessed inward relative to the cutting lane D of the display mother board 5X, when cutting the display mother board 5X to form the display device 100, only the first adhesive layer 22 in the supporting film is cut, and the first supporting layer 21 is not cut. Since the first adhesive layer 22 has a non-tacky surface after curing, the cutting may be performed smoothly, and an integrated cutting process for each display device 100 on the display mother board 5X may be achieved. It may both avoid fracturing of the first supporting layer 21 during the cutting process and help reduce the bezel width of the display device 100.

In some embodiments, the manufacturing method of the display device further includes: coating a material of a third adhesive layer on a back side of the first supporting layer in the bendable area of the display device, and performing pre-curing after coating is completed; attaching a second supporting layer to a side of the third adhesive layer away from the display panel, and performing curing. Then, the bonding area of the display panel is bent to the back side of the bendable area, and a second adhesive layer is coated on the back side of the bendable area to adhere the bonding area and the bendable area. Finally, a transparent optically clear adhesive layer is coated on the display side of the display panel, and a cover plate is attached to a side of the transparent optically clear adhesive layer away from the display panel.

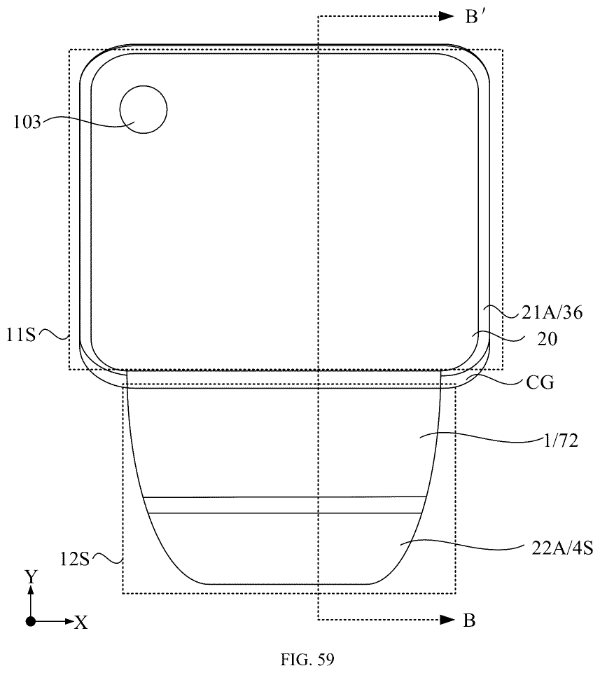

FIG. 47 is a structural diagram of a display device provided by an embodiment of the present disclosure.

Referring to FIG. 47, the display device 100 includes a display module 10X and a controller 200 electrically connected to the display module. The controller 200 may be disposed on a non-display side of the display module 10X and is configured to control a display panel in the display module 10X to display images.

The aforementioned display device may be any device that displays information, whether moving (e.g., video) or fixed (e.g., still images), and whether textual or pictorial.

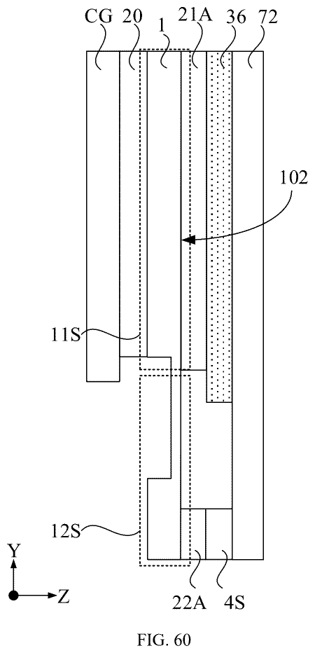

FIG. 48 is a partial cross-sectional view of the display device in FIG. 47 taken along section line A-A′.

Referring to FIG. 48, the display module 10X includes a display panel 1 and a supporting film. The display panel 1 includes a first portion 11S provided with a display area AA (referring to FIG. 11B), and a second portion 12S provided with a folding area BB (referring to FIG. 11B) and a bonding area CC (referring to FIG. 11B). The second portion 12S is located on a side of the first portion 11S. The first portion 11S includes a display surface 101 and a non-display surface 102 opposite to each other. The second portion 12S is bent to a side close to the non-display surface 102 of the first portion 11S. The supporting film includes a first film portion and a second film portion, the first film portion includes a first adhesive portion 21A located in the display area AA, and the second film portion includes a second adhesive portion 22A located in the bonding area CC. The first film portion further includes a first supporting portion 3S, which may be, for example, an Ultra-Thin Glass (UTG) layer. The second film portion further includes a second supporting portion 4S. The display module 10X further includes an optically clear adhesive layer (OCA) 20 disposed on a side of the display panel 1 away from the first supporting portion 3S, and a cover plate CG disposed on a side of the optically clear adhesive layer 20 away from the display panel 1.

The first adhesive portion 21A is connected to the non-display surface 102. The first supporting portion 3S is disposed on a side of the first adhesive portion 21A away from the first portion 11S, and the first supporting portion 3S is connected to the first adhesive portion 21A. Exemplarily, the material of the first adhesive portion 21A may be a pressure sensitive adhesive (PSA). The first supporting portion 3S is adhered to the non-display surface 102 via the first adhesive portion 21A.

Continuing to refer to FIG. 48, the second adhesive portion 22A is disposed on a side of the second portion 12S close to the first portion 11S, and the second adhesive portion 22A is connected to the second portion 12S. The second supporting portion 4S is disposed on a side of the second adhesive portion 22A close to the first portion 11S, and the second supporting portion 4S is connected to the second adhesive portion 22A. Exemplarily, the material of the second adhesive portion 22A may be PSA, and the material of the second supporting portion 4S may be Polyimide (PI). It may be understood that the second supporting portion 4S is adhered to the second portion 12S via the second adhesive portion 22A.

The cover plate CG is adhered to the display surface 101 of the display panel 1 via the optically clear adhesive layer 20, and the cover plate CG is used to protect the display panel 1.

The display module 10X provided by the present disclosure includes the display panel 1, the first adhesive portion 21A and the second adhesive portion 22A, and the first supporting portion 3S and the second supporting portion 4S. The first supporting portion 3S is disposed on a side of the non-display surface 102 of the first portion 11S of the display panel 1, and the first supporting portion 3S is connected to the non-display surface 102 via the first adhesive portion 21A, that is, the first supporting portion 3S is disposed on the back surface of the display panel 1. The second portion 12S of the display panel 1 is bent to a side close to the non-display surface 102, the second adhesive portion 22A is connected to the second portion 12S, the second supporting portion 4S is disposed on a side of the second adhesive portion 22A close to the first portion 11S and is connected to the second adhesive portion 22A, that is, the second supporting portion 4S is adhered to the second portion 12S via the second adhesive portion 22A. Since the first supporting portion 3S has excellent bending performance and impact resistance, by providing the first supporting portion 3S on the back surface of the display panel 1, creases generated by folding the display panel 1 may be effectively reduced, and the impact resistance of the display panel 1 may be improved, thereby enhancing the durability of the display module 10X.

In some embodiments, referring to FIG. 48, the display module 10X further includes a supporting member 6A. The supporting member 6A is disposed on a side of the first supporting portion 3S away from the first adhesive portion 21A and is connected to the first supporting portion 3S. The supporting member 6A and the first supporting portion 3S together support the first portion 11S to improve the impact resistance of the display panel 1. Moreover, the supporting member 6A has good bending performance, enabling the display module 10X to achieve a folding function.

In some embodiments, referring to FIG. 48, a sum d1 of a thickness of the first adhesive portion 21A and a thickness of the first supporting portion 3S is equal to a sum d2 of a thickness of the second adhesive portion 22A and a thickness of the second supporting portion 4S. Before the second portion 12S is bent, the stacked film layer of the first adhesive portion 21A and the first supporting portion 3S and the stacked film layer of the second adhesive portion 22A and the second supporting portion 4S need to be simultaneously attached to the back surface of the display panel 1. By setting d1=d2, the two stacked film layers have consistent thicknesses, thereby ensuring the flatness of film layer attachment.

Exemplarily, d1 and d2 may be set to 65 μm, where the thickness of the first adhesive portion 21A is 35 μm, the thickness of the first supporting portion 3S is 30 μm, the thickness of the second adhesive portion 22A is 15 μm, and the thickness of the second supporting portion 4S is 50 μm.

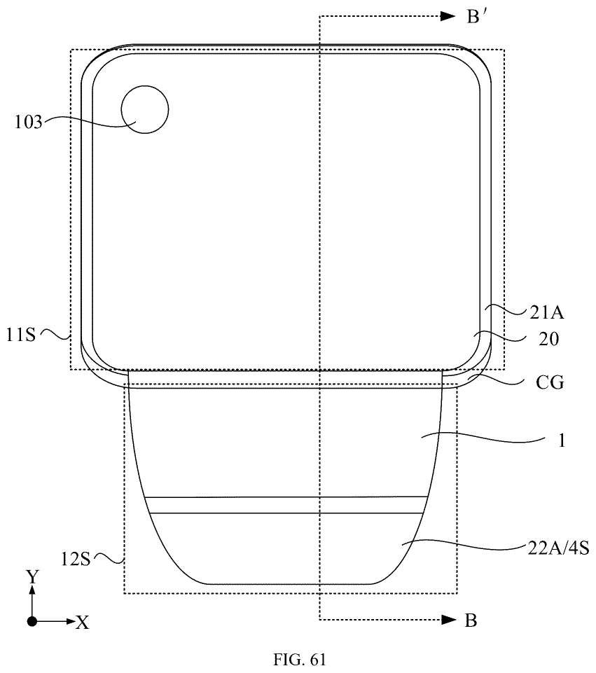

FIG. 49 is a partial enlarged view at part M of some film layers of the display module in FIG. 47.

In some embodiments, referring to FIGS. 47 and 49, the first portion 11S of the display panel 1 includes a first boundary (left boundary) J1 and a second boundary (right boundary) J2 opposite to each other in a first direction X, and a third boundary J3 and a fourth boundary J4 opposite to each other in a second direction Y. The first direction X intersects with the second direction Y. Exemplarily, the first direction X is perpendicular to the second direction Y. The third boundary J3 is farther from the second portion 12S than the fourth boundary J4, that is, in the direction Y, the third boundary J3 (upper boundary) is above the fourth boundary J4 (lower boundary).

The first supporting portion 3S includes a fifth boundary (left boundary) J5 and a sixth boundary (right boundary) J6 opposite to each other in the first direction X, and a seventh boundary J7 and an eighth boundary J8 opposite to each other in the second direction Y. The seventh boundary J7 is farther from the second portion 12S than the eighth boundary J8, that is, in the direction Y, the seventh boundary J7 (upper boundary) is above the eighth boundary J8 (lower boundary).

Continuing to refer to FIGS. 47 and 49, in the first direction X, the fifth boundary J5 extends beyond an outer side of the first boundary J1, and the sixth boundary J6 extends beyond an outer side of the second boundary J2, that is, the left and right boundaries of the first supporting portion 3S respectively extend beyond the left and right boundaries of the first portion 11S. In the second direction Y, the seventh boundary J7 extends beyond an outer side of the third boundary J3, that is, the upper boundary of the first supporting portion 3S extends beyond the upper boundary of the first portion 11S. Exemplarily, the left boundary, the right boundary, and the upper boundary of the first supporting portion 3S extend beyond the left boundary, the right boundary, and the upper boundary of the first portion 11S by at least 0.1 mm, respectively.

By setting the left boundary, the right boundary, and the upper boundary of the first supporting portion 3S to extend beyond the left boundary, the right boundary, and the upper boundary of the first portion 11S, an effective support of the first supporting portion 3S for the display module 10X is achieved. Moreover, a particular margin is provided for the size and position setting of the first portion 11S of the display panel 1, thereby reducing the difficulty of attaching the first supporting portion 3S and the first portion 11S.

In some embodiments, referring to FIGS. 47 and 49, a junction between the first boundary J1 and the third boundary J3 has a first corner (upper-left R-corner) B1, and a junction between the second boundary J2 and the third boundary J3 has a second corner (upper-right corner) B2. A junction between the fifth boundary J5 and the seventh boundary J7 has a third corner (upper-left corner) B3, and a junction between the sixth boundary J6 and the seventh boundary J7 has a fourth corner (upper-right corner) B4.

Exemplarily, the first corner B1, the second corner B2, the third corner B3, and the fourth corner B4 may all be rounded corners, or may all be right angles, or may have other shapes, which is not limited in embodiments of the present disclosure. FIG. 49 shows a case where the first corner B1, the second corner B2, the third corner B3, and the fourth corner B4 are all rounded corners.

An outer boundary of the third corner B3 extends beyond an outer boundary of the first corner B1, and an outer boundary of the fourth corner B4 extends beyond an outer boundary of the second corner B2, that is, the upper-left corner and the upper-right corner of the first supporting portion 3S extend beyond the upper-left corner and the upper-right corner of the first portion 11S, respectively. Such corner setting of the first supporting portion 3S provides a particular margin for the size and position setting of the first portion 11S of the display panel 1, thereby improving the attachment accuracy of the first supporting portion 3S and the first portion 11S. Exemplarily, the outer boundary of the upper-left corner and the outer boundary of the upper-right corner of the first supporting portion 3S extend beyond the outer boundary of the upper-left corner and the outer boundary of the upper-right corner of the first portion 11S by at least 0.1 mm, respectively.

In some embodiments, referring to FIGS. 47 and 49, in the first direction (direction X), the eighth boundary J8 is flush with the fourth boundary J4, that is, the boundary of the first supporting portion 3S does not extend beyond a side of the first portion 11S close to the second portion 12S, so as to facilitate wiring arrangement in this region and to facilitate bending the second portion 12S to the non-display surface 102.

In some embodiments, referring to FIGS. 47 and 49, the display panel 1 further includes a light-transmitting hole 103 disposed in the display area AA (referring to FIG. 11B). The first supporting portion 3S includes a through hole 30A. An outer boundary of an orthographic projection of the through hole 30A on the display panel 1 extends beyond an outer boundary of the light-transmitting hole 103, allowing the through hole 30A to completely expose the light-transmitting hole 103, thereby preventing the first supporting portion 3S from blocking light.

Exemplarily, a shape of the through hole 30A and a shape of the light-transmitting hole 103 may be circles, and the outer boundary of the orthographic projection of the through hole 30A on the display panel 1 extends beyond the outer boundary of the light-transmitting hole 103 by at least 0.1 mm. By setting the outer boundary of the through hole 30A to extend beyond the outer boundary of the light-transmitting hole 103, a particular margin is provided for alignment between the through hole 30A and the light-transmitting hole 103, and the difficulty of attaching the first supporting portion 3S and the first portion 11S is reduced.

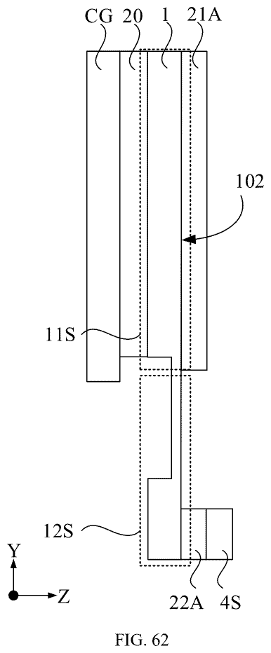

FIG. 50 is a structural diagram of a supporting film provided by an embodiment of the present disclosure.

Referring to FIG. 50, a supporting film 7S includes a first protective film 71, a first adhesive portion 21A, a second adhesive portion 22A, a release film 36, a second supporting portion 4S and a second protective film 72.

The first adhesive portion 21A and the second adhesive portion 22A are disposed on a side of the first protective film 71. Exemplarily, the material of the first adhesive portion 21A and the material of the second adhesive portion 22A may be PSA. The release film 36 is disposed on a side of the first adhesive portion 21A away from the first protective film 71, and the second supporting portion 4S is disposed on a side of the second adhesive portion 22A away from the first protective film 71. Exemplarily, the material of the second supporting portion 4S may be PI. The second protective film 72 covers the release film 36 and the second supporting portion 4S. The first protective film 71 and the second protective film 72 are used to protect the surfaces of the first adhesive portion 21A, the second adhesive portion 22A, the release film 36 and the second supporting portion 4S from contamination or damage.

Herein, a sum of a thickness of the first adhesive portion 21A and a thickness of the release film 36 is equal to a sum of a thickness of the second adhesive portion 22A and a thickness of the second supporting portion 4S, that is, a total thickness of the stacked film layers in the supporting film 7S is consistent, thereby ensuring the flatness of the supporting film 7S during the attaching process. To adapt to the thickness of the release film 36, the thickness of the first adhesive portion 21A is set to be greater than the thickness of the second adhesive portion 22A. The supporting film 7S is attached to a target panel via the first adhesive portion 21A and the second adhesive portion 22A. Since the thickness of the first adhesive portion 21A is greater than the thickness of the second adhesive portion 22A, there is a risk of the first adhesive portion 21A overflowing during the process of attaching the supporting film 7S.

Continuing to refer to FIG. 50, the first adhesive portion 21A includes a ninth boundary (inner boundary) J9 close to the second adhesive portion 22A, and the release film 36 includes a tenth boundary (inner boundary) J10 close to the second supporting portion 4S. The tenth boundary J10 extends beyond an outer side of the ninth boundary J9. It may be understood that the inner boundary of the release film 36 extends outward relative to the inner boundary of the first adhesive portion 21A.

The supporting film 7S provided by the present disclosure includes the first protective film 71, the first adhesive portion 21A and the second adhesive portion 22A, the release film 36 and the second supporting portion 4S, and the second protective film 72. The first adhesive portion 21A and the release film 36 as well as the second adhesive portion 22A and the second supporting portion 4S are disposed between the first protective film 71 and the second protective film 72. The second protective film 72 covers the release film 36 and the second supporting portion 4S to protect the surfaces of the release film 36 and the second supporting portion 4S.

Moreover, the supporting film 7S is attached to a target panel via the first adhesive portion 21A and the second adhesive portion 22A. Since the thickness of the first adhesive portion 21A is greater than the thickness of the second adhesive portion 22A, there may be a risk of the first adhesive portion 21A overflowing during the process of attaching the supporting film 7S. By setting the tenth boundary (inner boundary) J10 of the release film 36 to extend outward relative to the ninth boundary (inner boundary) J9 of the first adhesive portion 21A, and because the first adhesive portion 21A has capillary action, during the process of attaching the supporting film 7S, the first adhesive portion 21A will preferentially extend inward along the outward-extended tenth boundary J10 of the release film 36, thereby avoiding overflow of the first adhesive portion 21A during the attaching process, and further improving the quality and efficiency of the attaching process of the supporting film 7S.

Exemplarily, during the use of the supporting film 7S, after the release film 36 is torn off, a supporting material such as UTG may be placed at the position where the release film 36 was located, so as to enhance the support and the impact resistance of the supporting film 7S. Setting the thickness of the release film 36 to be different from the thickness of the second supporting portion 4S may better adapt to the thickness of UTG.

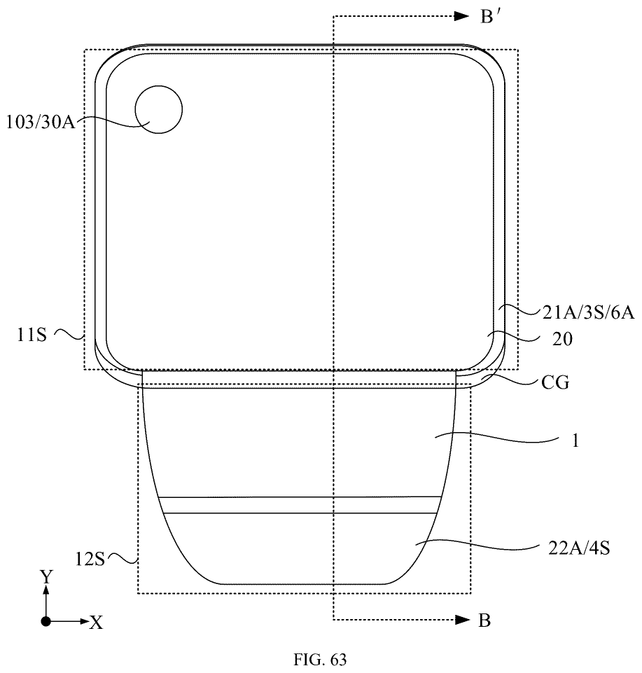

FIG. 51 is a top view of some film layers of the supporting film in FIG. 50.

Exemplarily, referring to FIGS. 50 and 51, the release film 36 includes alignment marks 700, which are disposed at peripheral edges of the release film 36. For example, the alignment marks 700 may be disposed at four corners of the release film 36. During the process of attaching the supporting film 7S to a target panel, a precise attachment of the supporting film 7S to the target panel may be achieved by capturing the alignment marks 700, thereby avoiding direct contact of the capturing apparatus with the first adhesive portion 21A, and reducing the risk of edge capturing difficulty.

Moreover, due to the outward-extended setting of the inner boundary (tenth boundary) J10 of the release film 36, overflow of the first adhesive portion 21A during the attaching process, which could contaminate feature points of the target panel, is avoided, thereby improving the recognition and alignment accuracy of the attaching apparatus for the aforementioned feature points.

In some embodiments, referring to FIG. 50, a peel force between the first protective film 71 and the first adhesive portion 21A is less than a peel force between the release film 36 and the first adhesive portion 21A. Exemplarily, the peel force between the first protective film 71 and the first adhesive portion 21A may be in a range of 0~2 gf/inch (“gf/inch” is the unit of peel force, meaning “gram-force per inch”), and the peel force between the release film 36 and the first adhesive portion 21A may be in a range of 2~4 gf/inch. Furthermore, a peel force between the first protective film 71 and the second adhesive portion 22A is less than a peel force between the second supporting portion 4S and the second adhesive portion 22A. Exemplarily, the peel force between the first protective film 71 and the second adhesive portion 22A may be in a range of 0~2 gf/inch, and the peel force between the second supporting portion 4S and the second adhesive portion 22A may be 1000 gf/inch.

During the attaching process of the supporting film 7S, the first protective film 71 needs to be torn off first, then the second protective film 72 and the release film 36 are torn off. By setting the peel force between the release film 36 and the first adhesive portion 21A to be greater than the peel force between the first protective film 71 and the first adhesive portion 21A, during the process of tearing off the first protective film 71, a reverse release problem is avoided, i.e., the release film 36 is prevented from being accidentally lifted, thereby ensuring smooth progress of attaching.

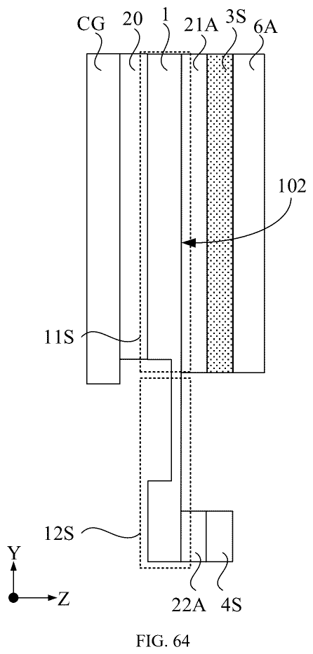

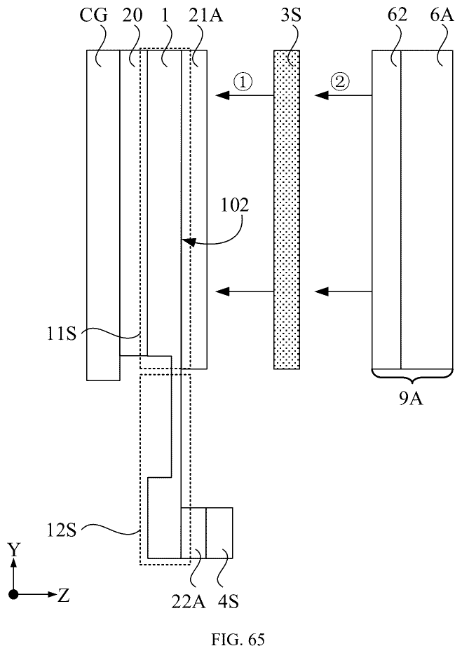

FIG. 52 is a flowchart of a manufacturing method of a display module provided by the present disclosure. FIGS. 53 to 64 are step diagrams of the manufacturing method in FIG. 52, where FIGS. 54, 56, 58, 60, 62, and 64 are partial cross-sectional views taken along section line B-B′ of the display module in FIGS. 53, 55, 57, 59, 61, and 63, respectively.

Referring to FIG. 52, the manufacturing method includes steps S1 to S5 as follows.

In step S1, referring to FIGS. 53 and 54, a display panel 1 is provided. The display panel 1 includes a display surface 101 and a non-display surface 102 opposite to each other. The display panel 1 further includes a first portion 11S provided with a display area, and a second portion 12S provided with a folding area and a bonding area.

In step S2, referring to FIGS. 55 and 56, a supporting film 7S is adhered to the non-display surface 102. The supporting film 7S includes a first adhesive portion 21A connected to the first portion 11S, a second adhesive portion 22A connected to the second portion 12S, a release film 36 disposed on a side of the first adhesive portion 21A away from the first portion 11S, a second supporting portion 4S disposed on a side of the second adhesive portion 22A away from the second portion 12S, and a second protective film 72 covering the release film 36 and the second supporting portion 4S.

Exemplarily, before adhering the supporting film 7S, the manufacturing method further includes steps S201 to S202 as follows.

In step S201, referring to FIG. 50, a supporting film 7S is provided. The supporting film 7S includes a first protective film 71, a first adhesive portion 21A and a second adhesive portion 22A, a release film 36 and a second supporting portion 4S, and a second protective film 72. A peel force between the first protective film 71 and the first adhesive portion 21A is less than a peel force between the release film 36 and the first adhesive portion 21A. Moreover, a peel force between the first protective film 71 and the second adhesive portion 22A is less than a peel force between the second supporting portion 4S and the second adhesive portion 22A.

In step S202, referring to FIGS. 55 and 56, the first protective film 71 is torn off, and the first adhesive portion 21A and the second adhesive portion 22A of the supporting film 7S are adhered to the non-display surface 102. Since the peel force between the release film 36 and the first adhesive portion 21A is set to be greater than the peel force between the first protective film 71 and the first adhesive portion 21A, during the process of tearing off the first protective film 71, a reverse release problem is avoided, i.e., the release film 36 is prevented from being accidentally lifted, thereby ensuring smooth progress of attaching.

Exemplarily, referring to FIGS. 57 and 58, after the supporting film 7S is adhered to the non-display surface 102, the manufacturing method further includes: forming an optically clear adhesive layer 20 on the display surface 101, and cutting the optically clear adhesive layer 20, the display panel 1, the first adhesive portion 21A, the release film 36, and the second protective film 72 to obtain a stacked structure with the shape shown in FIGS. 57 and 58. Exemplarily, the above cutting process may be performed by laser cutting. During the process of cutting the display panel 1, not only the outer contour of the display panel 1 is cut, but also a through light-transmitting hole 103 is formed on the display panel 1 by cutting.

Referring to FIGS. 59 and 60, after laser cutting is performed on the stacked film layers, the manufacturing method further includes: attaching a cover plate CG on a side of the optically clear adhesive layer 20 away from the display panel 1. An orthographic projection of the cover plate CG on the display panel 1 covers the first portion 11S, and the cover plate CG is used to protect the first portion 11S.

In step S3, referring to FIGS. 61 and 62, the second protective film 72 and the release film 36 are removed.

In step S4, referring to FIGS. 63 and 64, the first supporting portion 3S is adhered to a side of the first adhesive portion 21A away from the first portion 11S. Herein, the first supporting portion 3S has a thickness equal to that of the release film 36, and it is equivalent to replacing the release film 36 with the first supporting portion 3S. Exemplarily, a supporting member 6A may be adhered to the first supporting portion 3S via Fluorinated Ethylene Propylene (FEP).

Exemplarily, referring to FIGS. 63 and 64, after the first supporting portion 3S is adhered, the supporting member 6A is adhered to a side of the first supporting portion 3S away from the first portion 11S, thereby improving the support on the back side of the display panel 1.

In some embodiments, referring to FIGS. 63 and 64, before adhering the first supporting portion 3S, the manufacturing method further includes: cutting and tempering the ultra-thin glass (UTG) to form the first supporting portion 3S with a target shape. This endows the first supporting portion 3S with excellent bending performance and impact resistance, thereby ensuring that the first supporting portion 3S may provide effective support. By cutting and tempering the UTG in advance to form the first supporting portion 3S, the process problem that UTG is difficult to be cut at module end is solved, thereby reducing the process complexity of the present disclosure.

Exemplarily, the target shape includes: in the direction Y, the upper boundary of the first supporting portion 3S extends beyond the upper boundary of the display panel 1; in the direction X, the left and right boundaries of the first supporting portion 3S extend beyond the left and right boundaries of the first portion 11S, so as to achieve effective support of the first supporting portion 3S for the first portion 11S, and to provide a particular margin for the size and position setting of the first portion 11S of the display panel 1, thereby reducing the difficulty of attaching the first supporting portion 3S and the first portion 11S. For example, the three boundaries of the first supporting portion 3S extend beyond the corresponding three boundaries of the first portion 11S by at least 0.1 mm.

Moreover, in the direction Y, the lower boundary of the first supporting portion 3S is flush with the lower boundary of the first portion 11S of the display panel 1, that is, the boundary of the first supporting portion 3S does not extend beyond a side of the first portion 11S close to the second portion 12S, so as to facilitate wiring arrangement in this region and facilitate the subsequent step of bending the second portion 12S.

The target shape further includes forming a through hole 30A in the first supporting portion 3S. The outer boundary of an orthographic projection of the through hole 30A on the display panel 1 extends beyond the outer boundary of the light-transmitting hole 103, allowing the through hole 30A to completely expose the light-transmitting hole 103, thereby preventing the first supporting portion 3S from blocking light. For example, the shape of the through hole 30A and the shape of the light-transmitting hole 103 may be circles. The outer boundary of the orthographic projection of the through hole 30A on the display panel 1 extends beyond the outer boundary of the light-transmitting hole 103 by at least 0.1 mm. By setting the outer boundary of the through hole 30A to extend beyond the outer boundary of the light-transmitting hole 103, a particular margin is provided for alignment between the through hole 30A and the light-transmitting hole 103, thereby reducing the difficulty of attaching the first supporting portion 3S and the first portion 11S.

In step S5, referring to FIG. 48, the second portion 12S is bent to a side close to the non-display surface 102 of the first portion 11S to form a display module 10X.

In the manufacturing method provided by the present disclosure, the supporting film 7S is adhered to the non-display surface 102 of the display panel 1. The display panel 1 includes the first portion 11S provided with the display area, and the second portion 12S provided with the folding area and the bonding area. The supporting film 7S includes the first adhesive portion 21A, the second adhesive portion 22A, the release film 36, the second supporting portion 4S, and the second protective film 72. After the second protective film 72 and the release film 36 are removed, the first supporting portion 3S is adhered to a side of the first adhesive portion 21A away from the first portion 11S, and the second portion 12S is bent to a side close to the non-display surface 102 of the first portion 11S, thereby forming the display module 10X. Since the first supporting portion 3S has excellent bending performance and impact resistance, by providing the first supporting portion 3S on the back surface of the first portion 11S, creases generated by folding the first portion 11S may be effectively reduced, and the impact resistance of the display panel 1 may be improved, thereby enhancing the durability of the display module 10X.

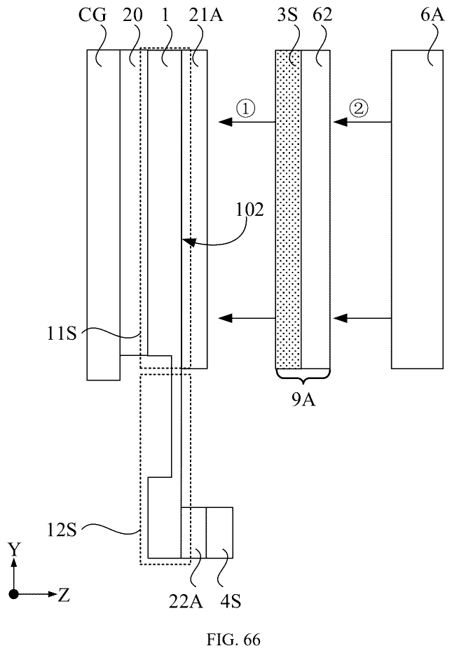

FIG. 65 is a step diagram of adhering the first supporting portion in step S4 of FIG. 52.

In some embodiments, referring to FIG. 65, after adhering the first supporting portion 3S in a first attaching process, the manufacturing method further includes forming a third adhesive layer 62 on a side of the supporting member 6A to form a supporting structure 9A. Exemplarily, the material of the supporting member 6A may be Stainless Steel (SUS), and the material of the third adhesive layer 62 may be FEP. Then, through a second attaching process, the supporting structure 9A is adhered to the first supporting portion 3S, that is, the supporting member 6A is adhered to the first supporting portion 3S via the third adhesive layer 62.

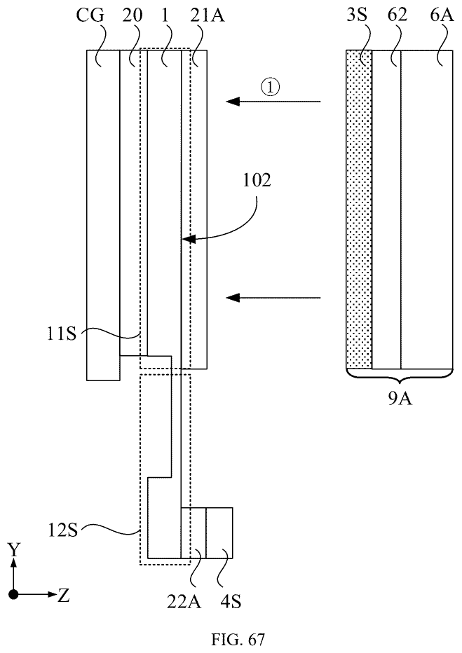

FIG. 66 is another step diagram of adhering the first supporting portion in step S4 of FIG. 52.

In some embodiments, referring to FIG. 66, before adhering the first supporting portion 3S, the manufacturing method further includes forming a third adhesive layer 62 on the first supporting portion 3S to form a supporting structure 9A. A first attaching process involves adhering the supporting structure 9A to the first portion 11S. Then, through a second attaching process, the supporting member 6A is adhered to the third adhesive layer 62. Exemplarily, a material of the supporting member 6A may be SUS, and a material of the third adhesive layer 62 may be FEP.

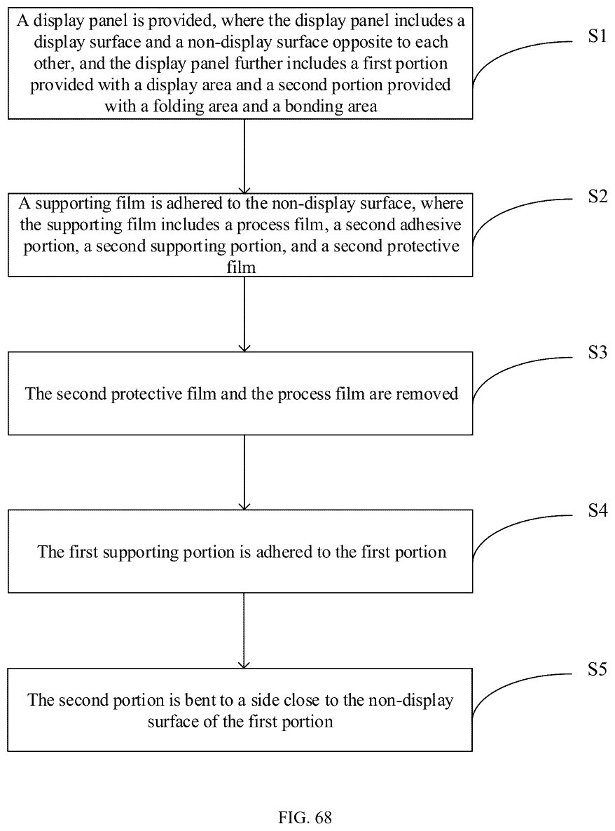

FIG. 67 is another step diagram of adhering the first supporting portion in step S4 of FIG. 52.

In some embodiments, referring to FIG. 67, before adhering the first supporting portion 3S, the manufacturing method further includes: forming a supporting structure 9A. The supporting structure 9A includes a first supporting portion 3S, a third adhesive layer 62, and a supporting member 6A arranged in stack, i.e., the supporting structure 9A is provided as an integrated material and may be fully attached through a single attaching process. Exemplarily, the material of the supporting member 6A may be SUS, and the material of the third adhesive layer 62 may be FEP.

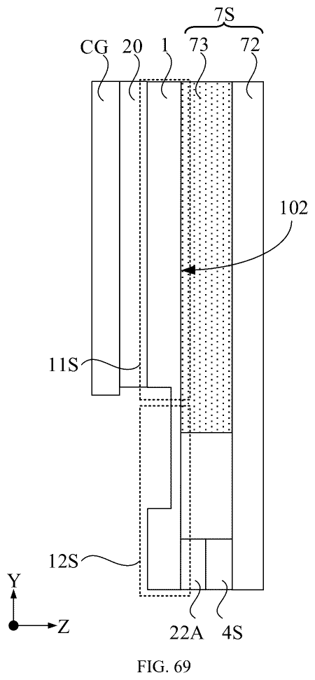

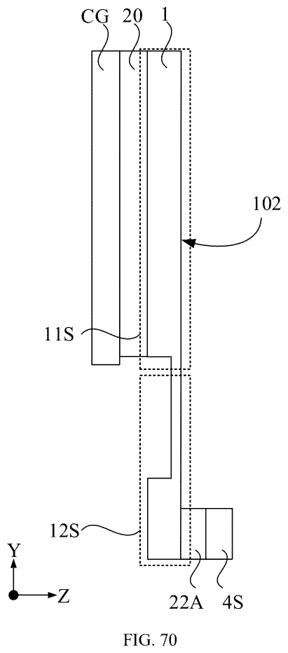

FIG. 68 is a flowchart of another manufacturing method of a display module provided by the present disclosure. FIGS. 69 and 70 are step diagrams of the manufacturing method in FIG. 68.

Referring to FIG. 68, the manufacturing method includes steps S1 to S5 as follows.

In step S1, referring to FIGS. 53 and 54, a display panel 1 is provided. The display panel 1 includes a display surface 101 and a non-display surface 102 opposite to each other. The display panel 1 further includes a first portion 11S provided with a display area, and a second portion 12S provided with a folding area and a bonding area.

In step S2, referring to FIG. 69, a supporting film 7S is adhered to the non-display surface 102. The supporting film 7S includes a process film 73 connected to the first portion 11S, a second adhesive portion 22A connected to the second portion 12S, a second supporting portion 4S disposed on a side of the second adhesive portion 22A away from the second portion 12S, and a second protective film 72 covering the process film 73 and the second supporting portion 4S.

Exemplarily, referring to FIG. 69, after adhering the supporting film 7S, the manufacturing method further includes: forming an optically clear adhesive layer 20 on the display surface 101, and cutting the optically clear adhesive layer 20, the display panel 1, the second adhesive portion 22A, the second supporting portion 4S, the process film 73, and the second protective film 72 to obtain a stacked structure with a target shape. The above cutting process may be performed by laser cutting. After laser cutting is performed on the stacked film layers, a cover plate CG is attached to a side of the optically clear adhesive layer 20 away from the display panel 1. An orthographic projection of the cover plate CG on the display panel 1 covers the first portion 11S, and the cover plate CG is used to protect the first portion 11S.

In step S3, referring to FIG. 70, the second protective film 72 and the process film 73 are removed.

In step S4, referring to FIGS. 63 and 64, the first supporting portion 3S is adhered to the first portion 11S.

Exemplarily, before adhering the first supporting portion 3S, the ultra-thin glass (UTG) is cut and tempered to form the first supporting portion 3S with a target shape. This endows the first supporting portion 3S with excellent bending performance and impact resistance, thereby ensuring that the first supporting portion 3S may provide effective support. By cutting and tempering the UTG in advance to form the first supporting portion 3S, the process problem that UTG is difficult to be cut at module end is solved, thereby reducing the process complexity of the present disclosure.

In step S5, referring to FIG. 48, the second portion 12S is bent to a side close to the non-display surface 102 of the first portion 11S to form the display module 10X.

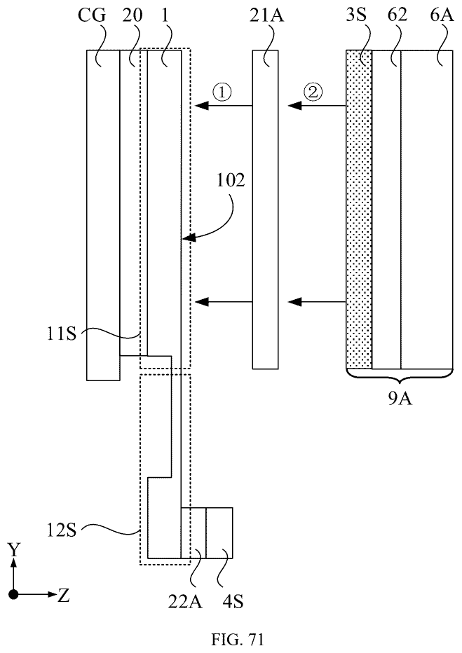

FIG. 71 is a step diagram of adhering the first supporting portion in step S4 of FIG. 68.

In some embodiments, referring to FIG. 71, before adhering the first supporting portion 3S, the manufacturing method further includes: forming a first adhesive portion 21A on the first portion 11S through a first attaching process. The supporting member 6A is adhered to the first supporting portion 3S via the third adhesive layer 62 to form a supporting structure 9A. Exemplarily, the material of the first adhesive portion 21A may be PSA, the material of the supporting member 6A may be SUS, and the material of the third adhesive layer 62 may be FEP. Then, the first supporting portion 3S is adhered through a second attaching process, i.e., the supporting structure 9A is adhered to a side of the first adhesive portion 21A away from the first portion 11S.

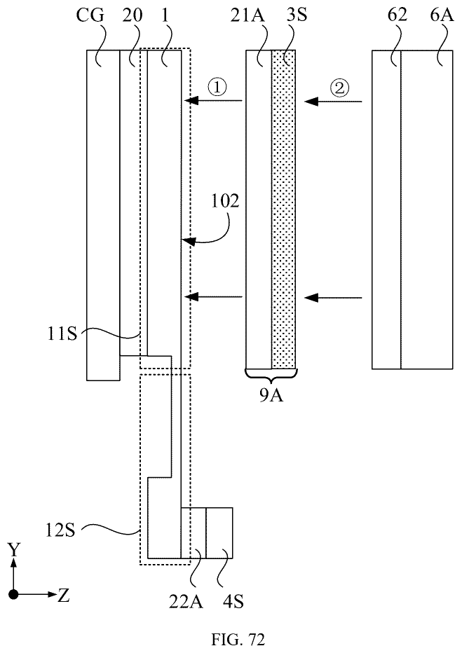

FIG. 72 is another step diagram of adhering the first supporting portion in step S4 of FIG. 68.

In some embodiments, referring to FIG. 72, before adhering the first supporting portion 3S, the manufacturing method further includes: forming a first adhesive portion 21A on the first supporting portion 3S to form a supporting structure 9A. Through a first attaching process, the supporting structure 9A is adhered to the first portion 11S, i.e., the first supporting portion 3S is adhered to the first portion 11S via the first adhesive portion 21A. After adhering the supporting structure 9A, the manufacturing method further includes: forming a third adhesive layer 62 on a side of the supporting member 6A, and adhering the supporting member 6A to the first supporting portion 3S via the third adhesive layer 62 through a second attaching process. Exemplarily, the material of the first adhesive portion 21A may be PSA, the material of the supporting member 6A may be SUS, and the material of the third adhesive layer 62 may be FEP.

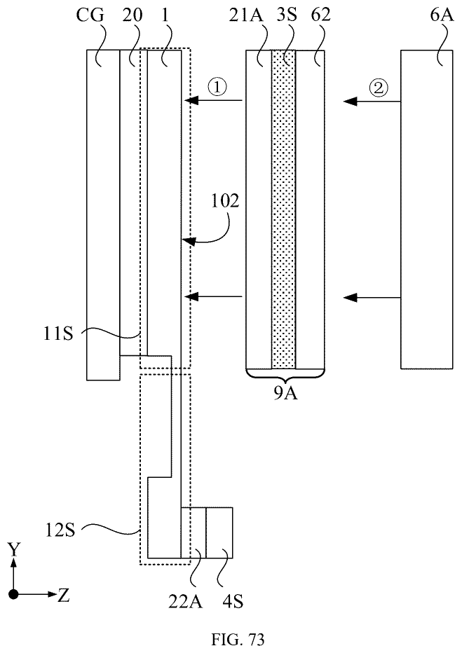

FIG. 73 is another step diagram of adhering the first supporting portion in step S4 of FIG. 68.

In some embodiments, referring to FIG. 73, before adhering the first supporting portion 3S, the manufacturing method further includes: forming a first adhesive portion 21A and a third adhesive layer 62 on two opposite sides of the first supporting portion 3S, respectively, to form a supporting structure 9A. Through a first attaching process, the supporting structure 9A is adhered to the first portion 11S. After adhering the supporting structure 9A, the supporting member 6A is adhered to the third adhesive layer 62 through a second attaching process. Exemplarily, the material of the first adhesive portion 21A may be PSA, the material of the supporting member 6A may be SUS, and the material of the third adhesive layer 62 may be FEP.

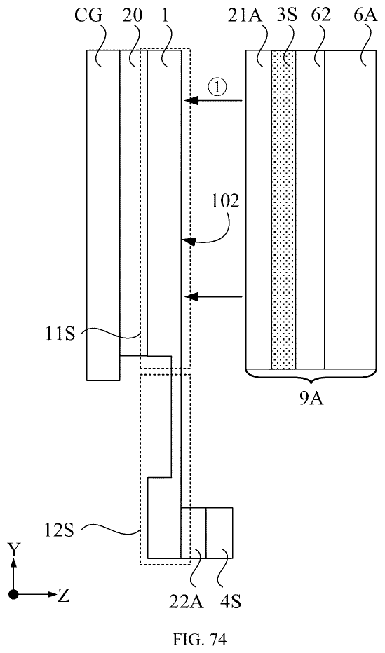

FIG. 74 is another step diagram of adhering the first supporting portion in step S4 of FIG. 68.

In some embodiments, referring to FIG. 74, before adhering the first supporting portion 3S, the manufacturing method further includes: forming a supporting structure 9A. The supporting structure 9A includes a first adhesive portion 21A, a first supporting portion 3S, a third adhesive layer 62, and a supporting member 6A arranged in stack, i.e., the supporting structure 9A is provided as an integrated material and may be fully attached through a single attaching process. Adhering the first supporting portion 3S means adhering the supporting structure 9A including the first supporting portion 3S to the first portion 11S via the first adhesive portion 21A. Exemplarily, the material of the first adhesive portion 21A may be PSA, the material of the supporting member 6A may be SUS, and the material of the third adhesive layer 62 may be FEP.

In some other embodiments of the present disclosure, an electronic apparatus is also provided. The electronic apparatus may be a device including a display function, that is, an apparatus including the above-mentioned display device. For example, the electronic apparatus may be a smart phone, a mobile phone, a video phone, an e-book reader, a desktop computer (PC), a laptop PC, a netbook PC, a personal digital assistant (PDA), a portable multimedia player (PMP), a digital audio player, a mobile medical apparatus, a camera, a wearable device (such as head-mounted apparatus, electronic clothing, electronic bracelet, electronic necklace, electronic accessory, electronic tattoo, or smart watch), etc.

The electronic apparatus according to the embodiments of the present disclosure may be a smart home appliance including a display function. For example, the smart home appliance may be a TV, a digital video disk (DVD) player, a stereo, a refrigerator, an air conditioner, a vacuum cleaner, an oven, a microwave oven, a washing machine, a dryer, an air purifier, a set-top box, a television (TV) box, a game console, an electronic dictionary, an electronic key, a video recorder, an electronic photo frame, etc.

The electronic apparatus according to the embodiments of the present disclosure may be a medical apparatus (for example, a magnetic resonance vascular imaging (MRA) apparatus, a magnetic resonance imaging (MRI) apparatus, a tomography (CT) apparatus, an imaging apparatus, or an ultrasound apparatus), a navigation apparatus, a Global Positioning System (GPS) receiver, an event data recorder (EDR), a flight data recorder (FDR), a car infotainment apparatus, a nautical electronic apparatus (for example, a nautical navigation apparatus, a gyroscope, or a compass), an avionics apparatus, a safety apparatus, an industrial or consumer robot, an automatic teller machine (ATM), a point of sale (POS), etc.

The electronic apparatus according to the embodiments of the present disclosure may be furniture including a display function, a part of a building/structure, an electronic billboard, an electronic signature receiving apparatus, a projector, various measuring apparatuses (for example, a water meter, an electric meter, a gas meter, or an electromagnetic wave measuring equipment) etc. The electronic apparatus according to some embodiments may be any combination of the aforementioned apparatuses. Moreover, the electronic apparatus according to the various embodiments may be a flexible apparatus. In addition, it should be clear to those skilled in the art that electronic apparatus according to the various embodiments of the present disclosure are not limited to above-mentioned apparatuses.

Although some embodiments according to the general inventive concept of the present disclosure have been illustrated and described, those skilled in the art will understand that changes may be made to the embodiments without departing from the principle and spirit of the general inventive concept of the present disclosure, and the scope of the present disclosure is defined by the claims and their equivalents.

What is claimed is:

1. A display device, comprising:
a display panel, wherein the display panel comprises:
a bendable area, comprising at least a display area of the display panel;
a bonding area, comprising a part of a non-display area of the display panel; and
a folding area located between the bendable area and the bonding area; and
a supporting film, wherein the supporting film is adhered to a back surface of the display panel, the supporting film comprises a first film portion and a second film portion, an orthographic projection of the first film portion on the display panel overlaps with the bendable area, and an orthographic projection of the second film portion on the display panel overlaps with the bonding area,
wherein,
a material of the first film portion is different from a material of the second film portion;
the first film portion comprises a first supporting portion, the second film portion comprises a second supporting portion, and an elastic modulus of a material of the first supporting portion is greater than an elastic modulus of a material of the second supporting portion; and
the first film portion comprises an ultra-thin glass material.

2. The display device according to claim 1, wherein the material of the first supporting portion is ultra-thin glass, and the material of the second supporting portion is at least one of polyethylene terephthalate, polyimide, polyurethane, polymethyl methacrylate, silicone, acrylate, polyurethane acrylate, and epoxy resin.

3. The display device according to claim 1, wherein,
the first film portion further comprises a first adhesive portion located in the display area, and the second film portion further comprises a second adhesive portion located in the bonding area; and
the first supporting portion comprises a first supporting sub-portion recessed inward relative to the first adhesive portion, and the first supporting portion is attached to the first adhesive portion; and the second supporting portion is attached to the second adhesive portion.

4. The display device according to claim 3, wherein,
the first supporting portion further comprises a second supporting sub-portion; and
the second supporting sub-portion is disposed on a side of the first supporting sub-portion close to the first adhesive portion, and the second supporting sub-portion covers a surface of the first supporting sub-portion close to the first adhesive portion and a side surface of the first supporting sub-portion; or the second supporting sub-portion is disposed on a side of the first supporting sub-portion away from the first adhesive portion, and the second supporting sub-portion covers a surface of the first supporting sub-portion away from the first adhesive portion and a side surface of the first supporting sub-portion; or the second supporting sub-portion is disposed on a side of the first supporting sub-portion close to the first adhesive portion and on a side of the first supporting sub-portion away from the first adhesive portion, and the second supporting sub-portion covers a surface of the first supporting sub-portion close to the first adhesive portion, a surface of the first supporting sub-portion away from the first adhesive portion and a side surface of the first supporting sub-portion.

5. The display device according to claim 4, wherein,
a material of the second supporting sub-portion is the same as a material of the second supporting portion; and
the second supporting sub-portion is located in the display area; or the second supporting sub-portion extends from the display area to the folding area and abuts against the second supporting portion.

6. The display device according to claim 4, wherein the second supporting sub-portion extends from the display area to the folding area, an elastic modulus of the second supporting sub-portion located in the display area is greater than an elastic modulus of the second supporting sub-portion located in the folding area; and the elastic modulus of the second supporting portion is greater than the elastic modulus of the second supporting sub-portion located in the folding area.

7. The display device according to claim 4, wherein,
the second supporting sub-portion is located in the display area;
the supporting film further comprises a third film portion; the third film portion comprises a third supporting portion and a third adhesive portion, the third supporting portion is located in the folding area and is disposed on a side of the third adhesive portion away from the display panel; two sides of the third supporting portion in an extending direction of the third supporting portion abut against the second supporting sub-portion and the second supporting portion, respectively; and
a material of the third supporting portion is different from a material of the second supporting sub-portion.

8. The display device according to claim 3, wherein,
the display device further comprises a third supporting sub-portion;
the third supporting sub-portion is located in an inward-recessed space of the first supporting sub-portion relative to the first adhesive portion, and is attached to the first adhesive portion;
the display device further comprises: an optically clear adhesive layer disposed on a side of the display panel away from the first adhesive portion, and a cover plate disposed on a side of the optically clear adhesive layer away from the display panel; and
a gap is provided between the third supporting sub-portion and the first supporting sub-portion; the cover plate comprises a light-transmitting portion corresponding to the first supporting sub-portion and a light-shielding portion corresponding to the third supporting sub-portion; and
an orthographic projection of the light-shielding portion on the display panel covers an orthographic projection of the gap on the display panel.

9. The display device according to claim 3, wherein,
the bendable area comprises at least one bending region; the bending region is located in the display area; and an area of the bending region is less than an area of the display area;
the first supporting sub-portion comprises a first sub-portion located in the bending region, and a second sub-portion and a third sub-portion located on two sides of the first sub-portion in an extending direction of the first sub-portion and connected to the first sub-portion;
an average thickness of the second sub-portion is the same as an average thickness of the third sub-portion;
a minimum thickness of the first sub-portion is less than the average thickness of the second sub-portion.

10. The display device according to claim 9, wherein,
the first sub-portion comprises a first surface close to the first adhesive portion and a fourth surface away from the first adhesive portion, the second sub-portion comprises a second surface close to the first adhesive portion and a fifth surface away from the first adhesive portion, and the third sub-portion comprises a third surface close to the first adhesive portion and a sixth surface away from the first adhesive portion;
the first surface, the second surface and the third surface are coplanar; or the fourth surface, the fifth surface and the sixth surface are coplanar; or an extension plane of the second surface and an extension plane of the third surface are coplanar, and an extension plane of the fifth surface and an extension plane of the sixth surface are coplanar, and both the first surface and the fourth surface are located between the extension plane of the second surface and the extension plane of the fifth surface.

11. The display device according to claim 9, wherein,
the bendable area comprises a plurality of bending regions spaced apart from each other; and
shortest distances from the first sub-portions of two adjacent bending regions to the first adhesive portion are different.

12. The display device according to claim 3, wherein,
the bendable area comprises at least one bending region; the bending region is located in the display area; and an area of the bending region is less than an area of the display area;
the first supporting sub-portion comprises a plurality of third grooves located in the bending region;
an orientation of the third grooves is a direction away from the first adhesive portion; or the orientation of the third grooves is a direction towards the first adhesive portion; or the orientation of the third grooves includes both a direction away from the first adhesive portion and a direction towards the first adhesive portion; and
the plurality of third grooves are arranged side by side in a second direction, and depths of the plurality of third grooves increase sequentially towards a center of the bending region in the second direction.

13. The display device according to claim 3, wherein,
the bendable area comprises a rollable area; the rollable area is located in the display area; and an area of the rollable area is less than an area of the display area;
the first supporting sub-portion comprises a first sub-portion located in the rollable area, and a second sub-portion connected to the first sub-portion and located on a side of the first sub-portion close to the folding area; and
an average thickness of the second sub-portion is greater than a minimum thickness of the first sub-portion.

14. The display device according to claim 13, wherein,
the first sub-portion comprises a first surface close to the first adhesive portion and a fourth surface away from the first adhesive portion, and the second sub-portion comprises a second surface close to the first adhesive portion and a fifth surface away from the first adhesive portion;
the fourth surface and the fifth surface are coplanar; the second surface of the second sub-portion contacts the first adhesive portion; and
the first supporting portion further comprises a second supporting sub-portion disposed between an extension plane of the second surface and the first surface, and the second supporting sub-portion abuts against a side surface of the second sub-portion close to the first sub-portion.

15. The display device according to claim 3, wherein,
the supporting film further comprises a fourth supporting portion disposed on a side of the second supporting portion away from the second adhesive portion; and
a sum of an average thickness of the second supporting portion and an average thickness of the fourth supporting portion is the same as a maximum thickness of the first supporting portion.

16. The display device according to claim 1, wherein,
the display panel comprises a first portion provided with the display area, and a second portion provided with the folding area and the bonding area, the first portion comprises a display surface and a non-display surface opposite to each other, and the second portion is bent to a side close to the non-display surface;
the first film portion comprises a first adhesive portion located in the display area, and the second film portion comprises a second adhesive portion located in the bonding area; the first adhesive portion is connected to the non-display surface; the second adhesive portion is disposed on a side of the second portion close to the first portion, and the second adhesive portion is connected to the second portion;
the first supporting portion is disposed on a side of the first adhesive portion away from the first portion, and the first supporting portion is connected to the first adhesive portion; the second supporting portion is disposed on a side of the second adhesive portion close to the first portion, and the second supporting portion is connected to the second adhesive portion;
the first portion comprises a first boundary and a second boundary opposite to each other in a first direction, and a third boundary and a fourth boundary opposite to each other in a second direction, the first direction intersects the second direction; and the third boundary is farther from the second portion than the fourth boundary;
the first supporting portion comprises a fifth boundary and a sixth boundary opposite to each other in the first direction, and a seventh boundary and an eighth boundary opposite to each other in the second direction; and the seventh boundary is farther from the second portion than the eighth boundary; and
in the first direction, the fifth boundary extends beyond an outer side of the first boundary, and the sixth boundary extends beyond an outer side of the second boundary; and in the second direction, the seventh boundary extends beyond an outer side of the third boundary.

17. The display device according to claim 16, wherein,
a junction between the first boundary and the third boundary has a first corner, and a junction between the second boundary and the third boundary has a second corner;
a junction between the fifth boundary and the seventh boundary has a third corner, and a junction between the sixth boundary and the seventh boundary has a fourth corner;
an outer boundary of the third corner extends beyond an outer boundary of the first corner, and an outer boundary of the fourth corner extends beyond an outer boundary of the second corner; and
in the first direction, the eighth boundary is flush with the fourth boundary.

18. The display device according to claim 16, wherein,
the display panel further comprises a light-transmitting hole disposed in the display area; and
the first supporting portion comprises a through hole, and an outer boundary of an orthographic projection of the through hole on the display panel extends beyond an outer boundary of the light-transmitting hole.

19. The display device according to claim 3, wherein,
a sum of a thickness of the first adhesive portion and a thickness of the first supporting portion is equal to a sum of a thickness of the second adhesive portion and a thickness of the second supporting portion; and
an elastic modulus of the first adhesive portion is less than an elastic modulus of the second adhesive portion.

20. The display device according to claim 3, wherein the display device further comprises a supporting member disposed on a side of the first supporting portion away from the first adhesive portion and connected to the first supporting portion.
